(19) United States
(12) Patent Application Publication
(10) Pub. No.: US 2007/0246250 A1
(43) Pub. Date: Oct. 25, 2007

(54) Wiring Board

(76) Inventors: Yoshihiro Tomita, Osaka (JP); Tadashi Nakamura, Osaka (JP)

Correspondence Address: MCDERMOTT WILL & EMERY LLP, 600 13TH STREET, NW, WASHINGTON, DC, 20005-3096, US

(21) Appl. No.: 11/662,269

(22) PCT Filed: Sep. 6, 2005
(86) PCT No.: PCT/JP05/16339

§ 371 Date: Mar. 9, 2007

(30) Foreign Application Priority Data
Sep. 10, 2004 (JP) 2004-263826
Oct. 7, 2004 (JP) 2004-295207
Oct. 14, 2004 (JP) 2004-299973
Mar. 30, 2005 (JP) 2005-097401

(51) Int. Cl. H05K 3/00; H05K 1/00; H05K 3/46

(52) U.S. Cl. 174/258; 29/829; 29/843

(57) ABSTRACT

[PROBLEMS]To provide a multilayer wiring board wherein high density wiring exceeding the application limit of the conventional build up wiring boards is made possible.

[MEANS FOR SOLVING PROBLEMS]A wiring board is provided with a board, which is formed by stacking along a board flat plane direction of a plurality of dielectric layers arranged along a facing direction of the both main surfaces of the board, and an inner conductor pattern arranged on the surface of the dielectric layer. The adjacent dielectric layers are formed so as to interconnect by being continuously and integrally coupled with each other through being connected at the layer edges on one of the board main planes. The connecting portions of the adjacent dielectric layers are alternately provided on one of the board main planes, and the dielectric layers are formed in a shape of one dielectric sheet that is arranged by being bent.

### RELATED APPLICATIONS

This application is the U.S. National Phase under 35 U.S.C. § 371 of International Application No. PCT/JP2005/016339, filed on Sep. 6, 2005, which in turn claims the benefit of Japanese Application No. 2004-263826, filed on Sep. 10, 2004, Japanese Application No. 2004-295207, filed on Oct. 7, 2004, Japanese Application No. 2004-299973, filed on Oct. 14, 2004, and Japanese Application No. 2005-097401, filed on Mar. 30, 2005 the disclosures of which Applications are incorporated by reference herein.

### FIELD OF THE INVENTION

The present invention relates to a wiring board, a method of manufacturing the wiring board, and an electronic component mounting structure, more specifically to a high density wiring board where a highly integrated LSI chip or the like can be mounted.

### BACKGROUND OF THE INVENTION

Based on a higher function and a higher performance of an electronic device in recent years, LSI and peripheral circuits constituting the electronic device have been demanding a larger area, and number of wirings for connecting the LSI chip and peripheral circuits have been increasing in a wiring board to mount these components, which requires a high density of the wirings on the circuit substrate.

Further, as the LSI chip have been increasingly integrated and a signal processing speed has been increasing at the same time, it is demanded that a signal is transmitted at a higher speed on the circuit substrate so that a high performance of the LSI chip can be fully exerted.

In order to achieve a high density of the wirings, it is necessary to reduce the wirings in width so as to make a wiring pitch smaller. Since the micro-fabrication technology has been advanced in recent years, the wirings can be realized now at such a narrow pitch as approximately 40 μm.

Further, number of connection pads has been dramatically increasing as the higher integration of the LSI chip has been advanced, and an LSI chip having a pads with a few hundreds of pins at least is often seen. As a result, the number of the wirings for transmitting the signal between the LSI chips is increasing, and multi-layered interconnection is now indispensable to allow any desired pad of the LSI chip on the circuit substrate to be connected.

FIG. 53 shows an example of a conventional multi-layered wiring board 200.

As shown in FIG. 53, via holes 206 are provided in dielectric layers 205 in the multi-layered substrate 200 so that wirings 203 and 204 formed on wiring layers 201 and 202 are connected to each other, and the wirings 203 and 204 are connected to each other via a conductor 207 formed in the via hole 206. The conductor 207 is conventionally grown by means of the copper plating method to be formed on an inner wall of the via hole 206. A land 208 is provided on the via hole 206 so that the conductor 207 is connected to the wiring 203 formed on the wiring layer 201.

A build-up wiring board is conventionally known at present as an example of the multi-layered wiring board where the wirings can be realized with a highest density. In the latest version of the build-up wiring board, it is realized that a smallest diameter of the via hole is approximately 40 μm and a diameter of the land is approximately 100 μm in consideration of an aligning error generated between the via hole and the land.

However, it is necessary to route the wirings formed on the respective wiring layers while avoiding the lands. Therefore, the presence of the lands in the way of the wirings is a bottleneck in the pursuit of the wiring at high density even if the wiring can be realized at the narrow pitches.

Examples of the technology relating to the high density in the build-up wiring board are recited in the Patent Documents 1-3 and the like.

| | |
|---|---|
| Patent Document 1: | 2002-141668 of the Japanese Patent |
| | Applications Laid-Open |
| Patent Document 2: | 2000-101246 of the Japanese Patent |
| | Applications Laid-Open |
| Patent Document 3: | 2000-36664 of the Japanese Patent |
| | Applications Laid-Open |

### DISCLOSURE OF THE INVENTION

### Problems to be Solved by the Invention

In order to achieve the wiring at high density in the build-up wiring board, it is necessary to reduce the diameters of the via hole and the land, however, an process accuracy of them is inevitably less than that of the wirings. Therefore, there is no option except narrowing the wiring pitch or increasing the number of the wiring layers in order to achieve the wiring at higher density.

In the narrow-pitched wiring layer, however, it is necessary to increase a thickness in order to prevent the increase of a wiring resistance due to the micro-fabrication of the wirings. When the wiring layer that was thus thickened is tried to be micro-fabricated, it is impossible to avoid a formation of a wiring pattern having a high aspect ratio, and the formation of the wiring pattern having the high aspect ratio demands an advanced etching technology.

The increase of the number of the wiring layers means that the wirings are gone through a larger number of via holes, which becomes a cause for deterioration of reliability. As a result, the formation of the via holes demands a technology with higher reliability.

As described above, a few of the hard technologies are required in order to realize the wiring with a higher density in the build-up wiring board. Therefore, the build-up wiring board has a limit when it is adapted as the wiring board provided with the LSI chip that rapidly becomes more highly integrated.

For example, a constitution is assumed where two LSI chips comprising 100×100 (10,000) area array electrodes as external connecting terminals are prepared and then mounted on a circuit substrate to be connected to each other under a state where 20 μm-pitch fine wirings and 100 μm-pitch lands are respectively realized in the wiring as a result of further advancement in the processing technology.

If it is not possible to connect the wirings between the lands in the foregoing case, a build-up wiring board comprising a lamination of at least 50 layers is necessary to realize the interconnection of the 10,000 wirings drawn from the electrodes of the respective LSI chips. Thus, one must say that it is very difficult from the industrial viewpoint to realize the circuit substrate provided with the LSI chips which are so highly integrated by using the build-up wiring board.

The present invention was implemented in consideration of the foregoing problems, and a main object thereof is to provide a multi-layered wiring board capable of achieving a higher wiring density that exceeds the adaptive limitation of the conventional build-up wiring board.

### MEANS FOR SOLVING THE PROBLEMS

In order to solve the foregoing problems, a wiring board according to the present invention comprises a substrate comprising a plurality of dielectric layers provided along a direction where main surfaces of the substrate face each other so as to laminate them along a planar direction of the substrate, and internal conducive patterns provided on surfaces of the dielectric layers. The adjacent dielectric layers are formed so as to interlink in such a manner that layer ends thereof are integrally connected with each other in either of the main surfaces of the substrate. The coupled sections of the adjacent dielectric layers are alternately provided on any of the main surfaces of the substrate, and the plurality of dielectric layers have a shape of a dielectric sheet arranged in a bending manner.

According to the foregoing constitution, the internal conductive patterns formed on the main surfaces of the dielectric layers constitute such wiring pitches at very small intervals that the dielectric sheet is folded alternately, wherein a wiring is formed to be a high density.

According to a preferred embodiment of the present invention, the internal conductive patterns are provided in a band shape along a ridgeline direction of the coupled sections.

According to another preferred embodiment of the present invention, insulating adhesive layers to adhere the adjacent dielectric layers to each other are further provided. It is preferable that the insulating adhesive layer includes thermosetting epoxy resin as its composition. In the case where the insulating adhesive layers to adhere the adjacent dielectric layers to each other are provided, it is preferable that the internal conductive patterns are coated with the insulating adhesive layers.

According to yet another preferred embodiment of the present invention, the adjacent dielectric layers are bonded to each other by pressure. In this case, it is preferable that the dielectric layers consist of thermoplastic polyester or thermoplastic fluorocarbon resin.

According to yet another preferred embodiment of the present invention, the internal conductive patterns are provided on both surfaces of the dielectric layers.

According to yet another preferred embodiment of the present invention, the internal conducive pattern is extended to the coupled section where the surface of the dielectric layer on which the internal conductive pattern is formed is made an outer side of the coupling so as to expose on the main surface of the substrate.

According to yet another preferred embodiment of the present invention, the internal conducive patterns provided on the both surfaces of the dielectric layer are extended to the coupled sections where the surfaces of the dielectric layer on which the internal conductive patterns become an outer side of the coupling so as to expose on either of the main surfaces of the substrate, wherein the internal conductive patterns provided on the both surfaces of the dielectric layer are connected to each other by an inter-layer connecting conductor provided in the dielectric layer so as to penetrate in a thickness direction thereof. In this case, the inter-layer connecting conductor is preferably a metal conductor.

According to yet another preferred embodiment of the present invention, the internal conducive patterns provided on the both surfaces of the dielectric layer are extended to the coupled sections where the surfaces of the dielectric layer on which the internal conductive patterns become an outer side of the coupling so as to expose on the main surfaces of the substrate, and the internal conductive patterns provided on the one surfaces of the dielectric layers are connected to each other so as to constitute a ground wire or a power-supply wire. Further, the internal conductive patterns provided on the one surfaces of the dielectric layers are formed so as to interlink at the coupled section where the internal conductive patterns are extended.

According to yet another preferred embodiment of the present invention, an external connecting electrode abutting an end of the internal conductive pattern exposed on the main surface of the substrate so as to be connected thereto is provided on the main surface of the substrate.

According to yet another preferred embodiment of the present invention, there is a plurality of the internal conductive patterns are exposed on the main surface of the substrate, wherein an external conductive pattern, that abuts so as to connect these exposed internal conductive patterns to each other, is provided on the main surface of the substrate.

According to yet another preferred embodiment of the present invention, the plurality of dielectric layers is formed in such a manner that the dielectric sheet is alternately and continuously folded at predetermined intervals.

According to yet another preferred embodiment of the present invention, a mounting structure comprises the wiring board having the external connecting electrode according to the present invention and an electronic component connected to the external connecting electrode of the wiring board.

The wiring board according to the present invention can be manufactured by means of, for example, the following method. The manufacturing method comprises a first step in which a dielectric sheet is prepared, and mountain-side lines and valley-side lines showing mountains and valleys respectively in observation from one surface of the dielectric sheet are virtually set alternately and in parallel with each other at certain intervals, a second step in which internal conductive patterns provided between the adjacent mountain-side lines and the valley-side lines and having a band shape in parallel with the mountain-side and valley-side lines are formed on at least the one surface of the dielectric sheet, and a third step in which the dielectric sheet is alternately folded along the mountain-side lines and the valley-side lines in such a manner that the mountain-side line forms a mountain shape and the valley-side line forms a valley shape in observation from the one surface so as to form a wiring board whose one main surface is an exposed surface of the mountain shape.

According to a preferred embodiment of the present invention, the dielectric sheets folded and abutting each other are bonded to each other by means of an insulating adhesive in the third step.

According to another preferred embodiment of the present invention, the internal conductive patterns are coated with the insulating adhesive in the third step.

According to yet another preferred embodiment of the present invention, the dielectric sheets folded and abutting each other are bonded by pressure to each other in the third step.

According to yet another preferred embodiment of the present invention, the internal conductive patterns are formed so as to substantially face each other on the both surfaces of the dielectric sheet in the second step. In this case, it is preferable that the second step is implemented after an inter-layer connecting conductor, that connects the opposed internal conductive patterns to each other in the midst of the dielectric sheet, is formed in the dielectric sheet.

According to yet another preferred embodiment of the present invention, the internal conductive pattern is formed so as to extend outside across a substantially entire length thereof beyond the mountain-side line or the valley-side line in the second step.

According to yet another preferred embodiment of the present invention, at least a part of the internal conductive patterns is formed so as to extend outside beyond the mountain-side line or the valley-side line so that the internal conductive pattern is exposed on the main surface of the substrate when the sheet is folded in the second step.

According to yet another preferred embodiment of the present invention, flexion guide grooves are formed along the mountain-side lines and the valley-side lines virtually set on the surface of the dielectric sheet in the first step.

According to yet another preferred embodiment of the present invention, a semi-curable insulating sheet is formed on the surface of the dielectric sheet provided with the internal conductive patterns after the internal conductive patterns are formed on the dielectric sheet, and the formed insulating sheet is removed except for at least the sheet on the internal conductive patterns formed in the band shape in the second step. In this case, it is preferable that the semi-curable insulating sheet is thermally cured so that the folded dielectric sheets are bonded to each other in the third step.

A multi-layered wiring board according to the present invention comprises a core substrate and a wiring board laminated on at least one of main surfaces of the core substrate. The core substrate comprises a core substrate main body comprising a plurality of dielectric layers provided along a direction where the main surfaces of the core substrate face each other so as to laminate one another along a planar direction of the core substrate, and internal conductive patterns provided on surfaces of the dielectric layers. The adjacent dielectric layers are integrally coupled at layer ends thereof to each other on either of the main surfaces of the core substrate. The respective coupled sections of the adjacent dielectric layers are alternately provided on any of the main surfaces of the core substrate, and the plurality of dielectric layers have a shape of a dielectric sheet arranged so as to be bent.

According to the foregoing constitution, the internal conductive patterns formed on the surfaces of the dielectric layers constitute such wiring pitches at very small intervals that the dielectric layers are alternately folded. Therefore, the core substrate consisting of the wirings with a high density can be obtained, and the very reliable multi-layered wiring board with a high density can be obtained only by laminating a small number of wiring boards.

In addition, it is preferable that the wiring boards are provided on the both main surfaces of the core substrate. Further, it is preferable that the internal conductive patterns are provided in a band shape along a ridge-line direction of the coupled sections.

According to a preferred embodiment of the present invention, insulating adhesive layers to adhere the adjacent dielectric layers to each other are provided. In this case, it is preferable that the internal conductive patterns are coated with the insulating adhesive layers. The plurality of dielectric layers constituting the core substrate may be bonded by pressure to each other.

It is preferable that the internal conductive patterns are provided on both surfaces of the dielectric layers. In this case, it is preferable that the internal conductive patterns provided on the one surfaces of the dielectric layers are connected to each other, and the wiring patterns attached to the internal conductive patterns linked to each other via the connecting conductor be connected to a ground terminal or a power-supply terminal.

According to another preferred embodiment of the present invention, the internal conducive pattern is extended to the coupled section where the surface of the dielectric layer, in which the internal conductive pattern is formed, becomes an outer side of the coupling, so as to expose on the main surface of the substrate. In this case, preferably, an external connecting terminal abutting and connected to an exposed end of the internal conductive pattern is provided on the main surface of the core substrate. In this case, it is preferable that there are the plural conductive patterns that are exposed on the main surface of the core substrate, and an external conductive pattern abutting and thereby connecting the exposed internal conductive patterns be provided on the main surface of the core substrate.

According to yet another preferred embodiment of the present invention, the wiring board further comprises wiring patterns provided on an exposed surface thereof and a connecting conductor provided so as to penetrate the wiring board in a thickness direction thereof for connecting the wiring patterns to the exposed end of the internal conductive pattern. In this case, it is preferable that the wiring boards comprising the wiring patterns and the connecting conductors are respectively provided on the both main surfaces of the core substrate. Further, preferably, the internal conductive patterns provided on the both surfaces of the dielectric layer so as to face each other are connected by an inter-layer connecting conductor provided in the dielectric layer so as to penetrate in a thickness direction thereof. In the case where the inter-layer connecting conductor is provided, it is preferable that external connecting terminals abutting and thereby connected to the exposed ends of the internal conductive patterns are provided on the both main surfaces of the core substrate, and the wiring patterns are connected to the external connecting terminals via the connecting conductors.

According to yet another preferred embodiment of the present invention, the internal conductive patterns provided on the one surfaces of the dielectric layers are connected to each other so as to constitute a ground wire or a power-supply wire.

It is preferable that build-up wiring layers formed on the core substrate constitute the wiring board according to the present invention.

In the present invention, it is preferable that a pitch at which the internal conductive pattern is formed is smaller than a pitch at which the wiring pattern is formed.

An interposer according to the present invention comprises a substrate comprising a plurality of dielectric layers provided along a direction where both main surfaces of the substrate face each other so as to laminate one another along a planar direction of the substrate, internal conductive patterns provided on both main surfaces of at least one of the dielectric layers, an inter-layer connecting conductor formed in the dielectric layer provided with the internal conductive patterns so as to penetrate in a thickness direction thereof for abutting and thereby connecting the internal conductive patterns existing on the both surfaces of the dielectric layer to each other, and external connecting terminals provided on the main surfaces of the substrate. The adjacent dielectric layers are formed so as to interlink through integrally coupling with each other at layer ends thereof on either of the both main surfaces of the substrate. The coupled sections of the adjacent dielectric layers are alternately provided on either of the both main surfaces of the substrate, and the plurality of dielectric layers has a shape of a dielectric sheet so as to be bent. Each of the internal conducive patterns constitutes lead electrodes exposed on the main surfaces of the substrate through extending the internal conducive patterns until the coupled sections where the surfaces of the dielectric layer on which the internal conductive patterns is formed are made an outer side of the coupling. The lead electrodes are connected to the external connecting terminals.

In the present invention constituted as described above, the internal conductive patterns formed on the main surfaces of the dielectric layer are provided in such a manner that are incorporated in the interposer as the high-density wirings having such wiring pitches at very small intervals that an dielectric sheet is alternately folded. Thereby, the interposer comprising the high-density wirings can be realized. Further, the lead electrodes provided on the both surfaces of the interposer are connected to each other via the internal conductive patterns formed on the main surfaces of the dielectric layer and the connecting conductor formed in the dielectric layer. Because the lead electrodes are connected to the external connecting terminals formed on the both surfaces of the interposer, the interposer, that is adaptive to an LSI chip comprising narrow-pitch electrode pads, can be realized.

According to yet another preferred embodiment of the present invention, the external connecting terminals provided on one of the main surfaces of the substrate are arranged along a periphery of the relevant main surface, and the external connecting terminals provided on the other main surface of the substrate are arranged on the relevant main surface in a two-dimensional array shape.

According to yet another preferred embodiment of the present invention, the external connecting terminals are arranged on the both main surfaces of the substrate in a two-dimensional array shape. In this case, it is preferable that a distance between the external connecting terminals provided on one of the main surfaces of the substrate is smaller than a distance between the external connecting terminals provided on the other main surface.

According to yet another preferred embodiment of the present invention, insulating adhesive layers to adhere the adjacent dielectric layers to each other are provided. In this case, it is preferable that the insulating adhesive layer includes thermosetting epoxy resin. Further, preferably, the internal conductive patterns are coated with the insulating adhesive layers.

According to yet another preferred embodiment of the present invention, the adjacent dielectric layers are bonded by pressure to each other. In this case, it is preferable that the dielectric layer consists of thermoplastic polyester or thermoplastic fluorocarbon resin.

According to yet another preferred embodiment of the present invention, the internal conductive patterns are provided in a band shape along a ridge-line direction of the coupled sections.

The inter-layer connecting conductor is preferably a metal conductor.

According to yet another preferred embodiment of the present invention, a plurality of lead electrodes is provided on the same main surface of the substrate, and a surface wiring pattern for abutting and thereby connecting these lead electrodes is provided on the main surface of the substrate.

The dielectric layer is preferably formed from thermoplastic fluorocarbon resin or thermosetting epoxy resin.

The dielectric layer may consist of thermoplastic polyester.

A multi-layered wiring board according to the present invention comprises a first core substrate and a second core substrate arranged to laminate on the first core substrate. The first and second core substrates comprise a substrate including a plurality of dielectric layers arranged along a direction where main surfaces of the substrate face each other and laminated on one another along a planar direction of the substrate, and internal conductive patterns provided on surfaces of the dielectric layers. The adjacent dielectric layers are formed so as to interlink by integrally coupling layer ends thereof on any of the main surfaces of the substrate with each other. The coupled sections of the adjacent dielectric layers are alternately provided on either of the main surfaces of the substrate, and the plurality of dielectric layers have a shape of a dielectric sheet arranged so as to be bent. The internal conductive patterns formed in at least one dielectric layer selected from the plurality of dielectric layers constitute lead electrodes by extending until the coupled sections where the surfaces of the dielectric layer, on which are provided on the both surfaces of the dielectric layer in order to form the internal conductive patterns, become an outer side of the coupling, and exposing on the main surface of the substrate. A arranging direction of the dielectric layers in the first core substrate and that in the second core substrate intersect with each other. The first and second core substrates are laminated on each other in such a manner that the main surfaces of the exposed lead electrodes thereof face each other. The lead electrodes of the first core substrate and the second core substrate are connected to each other.

According to a preferred embodiment of the present invention, A arranging direction of the dielectric layers in the first core substrate and that in the second core substrate intersect in orthogonal way with each other.

According to another preferred embodiment of the present invention, the internal conductive patterns of the first core substrate and the internal conductive patterns of the second core substrate are formed in a band shape in a direction where they intersect with each other.

According to yet another preferred embodiment of the present invention, the first and second core substrates have a respective insulating adhesive layer that adheres the adjacent dielectric layers to each other. The internal conductive patterns are coated with the insulating adhesive layers.

According to yet another preferred embodiment of the present invention, an inter-substrate connecting layer is provided between the first and second core substrates. The inter-substrate connecting layer has an inter-layer connecting conductor penetrating in a thickness direction thereof. The lead electrodes of the first core substrate and the second core substrate are connected to each other via the inter-layer connecting conductor.

According to yet another preferred embodiment of the present invention, the internal conductive patterns are provided on the both surfaces of the dielectric layers.

According to yet another preferred embodiment of the present invention, the second core substrate comprises first and second dielectric layers. A first internal conductive pattern is provided on one surface of the first dielectric layer, and a third internal conductive pattern is provided on another surface of the first dielectric layer. A second internal conductive pattern is provided on one surface of the second dielectric layer, and a fourth internal conductive pattern is provided on another surface of the second dielectric layer. The first and second internal conductive patterns constitute first and second lead electrodes respectively by extending until coupled sections where the one surfaces of the first and second dielectric layers are made an outer side of the coupling, and exposing on the main surface of the substrate. The third and fourth internal conductive patterns constitute third and fourth lead electrodes respectively by extending until the coupled sections where the other surfaces of the first and second dielectric layers are made an outer side of the coupling, and exposing on the main surface of the substrate. The first and third internal conductive patterns are connected through an inter-layer connecting conductor provided in the first dielectric layer so as to penetrate in a thickness direction thereof. The second and fourth internal conductive patterns are connected through an inter-layer connecting conductor provided in the second dielectric layer so as to penetrate in a thickness direction thereof. The first core substrate comprises third and fourth dielectric layers. A fifth internal conductive pattern is provided on one surface of the third dielectric layer, and a seventh internal conductive pattern is provided on the other surface of the third dielectric, layer respectively. A sixth internal conductive pattern is provided on one surface of the fourth dielectric layer, and an eighth internal conductive pattern is provided on the other surface of the fourth dielectric layer. The fifth and sixth internal conductive patterns constitute fifth and sixth lead electrodes respectively by extending until the coupled sections where the one surfaces of the third and fourth dielectric layers are made an outer side of the coupling, and exposing on the main surface of the substrate. The seventh and eighth internal conductive patterns constitute seventh and fourth eighth electrodes respectively by extending until the coupled sections where the other surfaces of the third and fourth dielectric layers are made an outer side of the coupling, exposing on the main surface of the substrate. The fifth and seventh internal conductive patterns are connected through an inter-layer connecting conductor provided in the third dielectric layer so as to penetrate in a thickness direction thereof. The sixth and eighth internal conductive patterns are connected through an inter-layer connecting conductor provided in the fourth dielectric layer so as to penetrate in a thickness direction thereof. The second core substrate and the first core substrate are laminated on each other in such a manner that the main surface of the second core substrate where the third and fourth lead electrodes are exposed and the main surface of the first core substrate where the fifth and sixth lead electrodes are exposed, face each other. The third and fifth lead electrodes are connected to each other. The fourth and sixth lead electrodes are connected to each other.

A mounting structure for a semiconductor device according to the present invention comprises the multi-layered wiring board, a first semiconductor device, and a second semiconductor device. The first and second semiconductor devices are mounted on the main surface of the second core substrate on the rear side of the main surface where the third and fourth lead electrodes are exposed. The first semiconductor device is connected to the first lead electrode, while the second semiconductor device is connected to the second lead electrode.

According to a preferred embodiment of the present invention, the first, second, third and fourth internal conductive patterns respectively constitute bus lines that connect the first and second semiconductor devices.

### EFFECT OF THE INVENTION

In the wiring board according to the present invention, a large number of signal wirings can be dragged about without the formation of any micro-fabricated wiring pattern, and the connection number of the via holes where the signal wires go through and the number of the wiring layers can be remarkably reduced. Therefore, the wiring board is not subject to any limitation, such as a limit for the wirings having a narrow-pitch and a high aspect ratio, a limit for reduction of the diameters of the via holes and the lands and a limit for multi-lamination of the wiring layers, in the pursuit of a higher wiring density therein. Therefore, it is possible to realize the wiring board having a high density and high reliability so as to be enough capable of mounting to an electronic device with higher function and performance which will be developed from now.

Further, the wiring boards in which the dielectric sheet is folded alternately in the different directions are laminated, and a part of the internal conductive patterns formed on the respective wiring boards are connected to each other, so that the wiring patterns can be hard-wired in any arbitrary direction. As a result, as it becomes unnecessary to divert the wirings in the multi-layered substrate, bus lines and transmission wires provided in parallel can be formed as buried. Thus, it is possible to realize a wiring structure with a high quality.

In relation to the interposer according to the present invention, it is possible to realize the interposer with high-density wirings where wiring pitches are formed at such very small intervals that the dielectric sheet is alternately folded by the internal conductive patterns formed on the main surfaces of the dielectric layers without the formation of any micro-fabricated wiring pattern. The lead electrodes exposed on the both surfaces of the interposer are connected via the inter-layer connecting conductor (via hole) formed in the dielectric layer. Therefore, the external connecting terminals, that are two-dimensionally provided, can be formed without the multi-layered wirings. As a result, it is possible to realize the interposer comprising the very reliable high-density wirings that is enough adaptive for the LSI chip having the narrow-pitch electrode pads can be realized.

### BRIEF DESCRIPTION OF THE DRAWINGS

FIG. 1A shows a constitution of a wiring board according to a preferred embodiment 1 of the present invention.

FIG. 1B shows a constitution of a packaging shape wherein an electronic component is mounted on the wiring board according to the preferred embodiment 1.

FIG. 2 shows a method of forming the wiring board according to the preferred embodiment 1 in (A), (B), and (C).

FIG. 3 is a sectional view showing the constitution of the wiring board according to the preferred embodiment 1.

FIG. 4 shows a method of forming a wiring board according to a preferred embodiment 2 of the present invention in (A), (B), and (C).

FIG. 5 is a sectional view showing a constitution of the wiring board according to the preferred embodiment 2.

FIG. 6 shows another method of forming the wiring board according to the preferred embodiment 2 in (A), (B), and (C).

FIG. 7 is a sectional view showing the constitution of the wiring board according to the preferred embodiment 2.

FIG. 8 shows a method of forming a wiring board according to a preferred embodiment 3 of the present invention in (A), (B), and (C).

FIG. 9 is a sectional view showing a constitution of the wiring board according to the preferred embodiment 3.

FIG. 10 shows the constitution of the wiring board according to the preferred embodiment 3.

FIG. 11 shows a method of forming a wiring board according to a preferred embodiment 4 of the present invention in (A), (B), and (C).

FIG. 12 is a sectional view showing a constitution of the wiring board according to the preferred embodiment 4.

FIG. 13 shows another method of forming the wiring board according to the preferred embodiment 4 in (A), (B), and (C).

FIG. 14 is a sectional view showing another constitution of the wiring board according to the preferred embodiment 4.

FIG. 15 shows another method of forming a wiring board according to the preferred embodiment 4 in (A), (B), and (C).

FIG. 16 is a sectional view showing yet another constitution of a wiring board according to the preferred embodiment 4.

FIG. 17 shows a method of forming a wiring board according to a preferred embodiment 5 of the present invention in (A), (B), and (C).

FIG. 18 is a sectional view showing a constitution of the wiring board according to the preferred embodiment 5.

FIG. 19 shows a method of forming a dielectric sheet according to a preferred embodiment 6 of the present invention in (A)-(F).

FIG. 20A is a drawing illustrating a method of folding the dielectric sheet according to the preferred embodiment 6.

FIG. 20B is a drawing illustrating the method of folding the dielectric sheet according to the preferred embodiment 6.

FIG. 20C is a drawing illustrating the method of folding the dielectric sheet according to the preferred embodiment 6.

FIG. 21 shows a constitution of a multi-layered wiring board according to a preferred embodiment 7 of the present invention.

FIG. 22 shows a constitution of a core substrate A that is a constituent element of the multi-layered wiring board according to the preferred embodiment 7.

FIG. 23 shows a method of forming the core substrate according to the preferred embodiment 7 in (A), (B), and (C).

FIG. 24 is a sectional view illustrating the constitution of the core substrate according to the preferred embodiment 7.

FIG. 25 is a sectional view illustrating a constitution of a multi-layered wiring board according to a preferred embodiment 8 of the present invention.

FIG. 26 shows a method of forming a core substrate according to the preferred embodiment 8 in (A), (B), and (C).

FIG. 27 shows a constitution of the core substrate according to the preferred embodiment 8.

FIG. 28 shows a constitution of a chip set according to a preferred embodiment 9 of the present invention.

FIG. 29 is a sectional view illustrating a constitution of a multi-layered wiring board according to the preferred embodiment 9.

FIG. 30A is a drawing illustrating a manufacturing process of a multi-layered wiring board according to a preferred embodiment 10 of the present invention.

FIG. 30B is a drawing illustrating the manufacturing process of the multi-layered wiring board according to the preferred embodiment 10.

FIG. 30C is a drawing illustrating the manufacturing process of the multi-layered wiring board according to the preferred embodiment 10.

FIG. 31A is a drawing for describing another manufacturing process of the multi-layered wiring board according to the preferred embodiment 10.

FIG. 31B is a drawing for describing the another manufacturing process of the multi-layered wiring board according to the preferred embodiment 10.

FIG. 31C is a drawing illustrating the another manufacturing process of the multi-layered wiring board according to the preferred embodiment 10.

FIG. 32 is a perspective view illustrating a basic constitution of an interposer according to a preferred embodiment 11 of the present invention.

FIG. 33 is a sectional view showing the constitution of the interposer according to the preferred embodiment 11.

FIG. 34 shows a method of forming a dielectric sheet according to the preferred embodiment 11 in (A), (B), and (C).

FIG. 35 is a sectional view showing the constitution of the interposer according to the preferred embodiment 11.

FIG. 36A is an upper view of CSP in which the interposer according to the preferred embodiment 11 is used.

FIG. 36B is a sectional view of the CSP in which the interposer according to the preferred embodiment 11 is used.

FIG. 36C is a bottom view of the CSP in which the interposer according to the preferred embodiment 11 is used.

FIG. 37 shows a wiring connecting structure in the interposer according to the preferred embodiment 11.

FIG. 38 is a sectional view illustrating a constitution of an extension interposer according to a preferred embodiment 12 of the present invention.

FIG. 39 is a plan view illustrating the constitution of the extension interposer according to the preferred embodiment 12.

FIG. 40 is partly enlarged view of the extension interposer according to the preferred embodiment 12.

FIG. 41 shows a wiring connecting method in the interposer according to the preferred embodiment 12.

FIG. 42 shows an application example of the extension interposer according to the preferred embodiment 12.

FIG. 43 is a perspective view showing a basic constitution of a multi-layered wiring board according to a preferred embodiment 13 of the present invention.

FIG. 44 is a sectional view showing a constitution of a dielectric layer according to the preferred embodiment 13.

FIG. 45 is a perspective view showing the constitution of the multi-layered wiring board according to the preferred embodiment 13.

FIG. 46A is a sectional view showing a first constitution of a lead electrode according to the preferred embodiment 13.

FIG. 46B is a sectional view showing a second constitution of the lead electrode according to the preferred embodiment 13.

FIG. 47 is a perspective view showing the constitution of the multi-layered wiring board according to the preferred embodiment 13.

FIG. 48 is a sectional view showing a constitution of an internal conducive pattern according to the preferred embodiment 13.

FIG. 49 is a plan view showing a wiring connecting relationship in the multi-layered wiring board according to the preferred embodiment 13.

FIG. 50 is a plan view showing a constitution of a multi-layered wiring board on which IC (semiconductor device) is mounted according to the preferred embodiment 13.

FIG. 51 is a perspective view showing a modification example of the multi-layered wiring board according to the preferred embodiment 13.

FIG. 52 is a plan view showing another modification example of the multi-layered wiring board according to the preferred embodiment 13.

FIG. 53 is a sectional view showing a constitution of a conventional build-up wiring board.

### DESCRIPTION OF REFERENCE SYMBOLS

10 dielectric sheet
11 dielectric layer
11a dielectric layer
11b dielectric layer
11c dielectric layer
12, 13 internal conductive pattern
14 coupled section
16 insulating adhesive layer
17 lead electrode
18 lead electrode
19 lead electrode
20 main surface of substrate
21 main surface of substrate
22 via hole (inter-layer connecting conductor)
23 wiring pattern
24 via hole
25 external conductive pattern
26 external connecting electrode
27 insulating layer
28 connecting conductor
30 LSI chip
31 electrode pad
32 external connecting terminal
33 LSI chip
33A LSI chip
33B LSI chip
33C LSI chip
34 external connecting terminal
35 solder ball
36a, 36b internal conductive pattern
37a, 37b internal conductive pattern
38a, 38b internal conductive pattern
40a, 40b lead electrode
41a, 41b lead electrode
42a, 42b lead electrode
43a, 43b lead electrode
44a, 44b lead electrode
45a, 45b lead electrode
50 inter-substrate connecting layer
53 via hole
51 external connecting terminal
52 external connecting terminal
60 bus
70 groove
80 jig
100A wiring board
100B wiring board
100C wiring board
100D wiring board
140 chip-type electronic component
150 packaging shape
100a core substrate
100b core substrate
110A multi-layered wiring board
110B multi-layered wiring board
120A interposer
120B extension interposer
160 second LSI chip
170 third LSI chip
180 printed board

### PREFERRED EMBODIMENTS OF THE INVENTION

Hereinafter, preferred embodiments of the present invention are described referring to the drawings. In the drawings below, constituent elements exerting substantially a same function are shown by same reference symbols in order to simplify the description. The present invention is not limited to the following embodiments.

### Preferred Embodiment 1

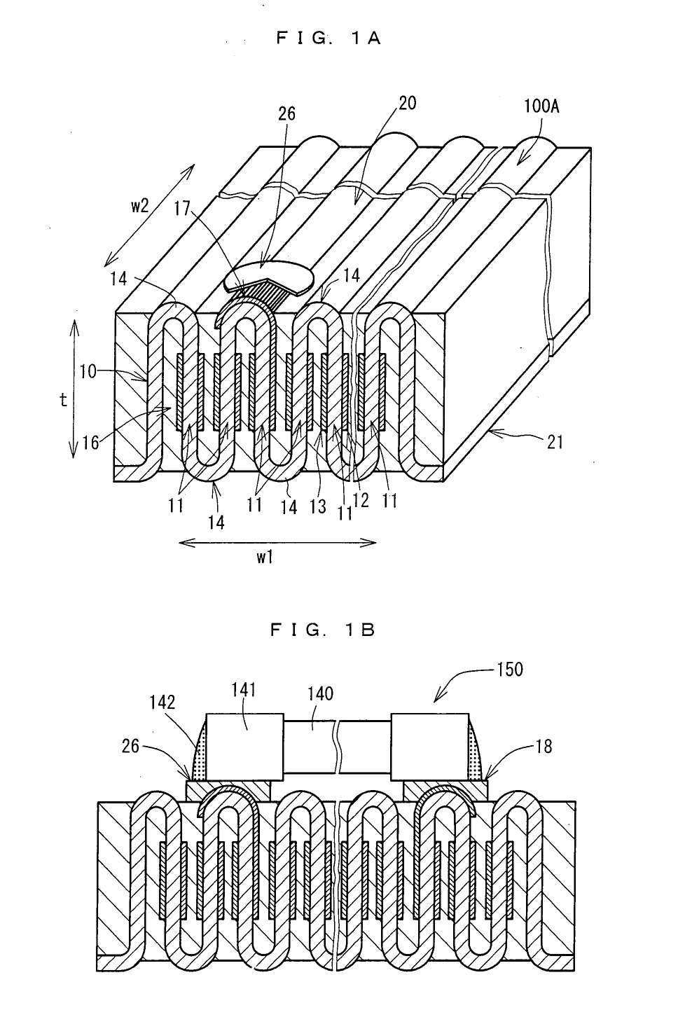

FIG. 1A shows a basic structure of a wiring board 100A according to a preferred embodiment 1 of the present invention. The wiring board 100A shown in FIG. 1A has a shape of rectangular flat-plate. The wiring board 100A comprises a plurality of dielectric layers 11. The respective dielectric layers 11 are arranged along a direction t where main surfaces of the substrate face each other (thickness direction) and laminated along a direction W1 intersecting with the facing direction t at right angles. The orthogonal intersecting direction w1 refers to a planar direction of the substrate along an arbitrary side of the rectangular wiring board 100A. Internal conductive patterns 12 and 13 are provided on surfaces of the respective dielectric layers 11. The respective internal conductive patterns 12 and 13 are provided on the both surfaces of the respective dielectric layers 11. The adjacent dielectric layers 11 are formed for connection so as to be integrally coupled at layer ends thereof on either of main surfaces 20 and 21 of the substrate.

The coupled layer ends constitute coupled sections 14 of the dielectric layers. The coupled section 14 is continuously provided on the dielectric layer 11 across a full width thereof (full width of the wiring board 100A), that is, along a planar direction w2 of the substrate that intersects in orthogonal way with the orthogonal intersecting direction w1 on the plane of the substrate. The coupled sections 14 are provided at both ends of the dielectric layers 11. The plurality of coupled sections 14 is alternately provided on either of both the main surfaces 20 and 21 of the substrate along the orthogonal intersecting direction w1. More specifically, the coupled section 14 adjacent to the coupled section 14 on the main-surface-20 side of the substrate is provided on the other main surface 21 of the substrate, and the coupled section 14 adjacent to the coupled section 14 on the other main surface 21 side of the substrate is provided on the main surface 20 of the substrate.

Accordingly, the wholeness of the plural dielectric layers 11 have a shape of a dielectric sheet 10 arranged in a bending manner by being folded at the coupled sections 14, and further the folded dielectric sheet 10 constitutes the substrate. The internal conductive patterns 12 and 13 are provided in a band shape along a longitudinal direction of the dielectric layers 11 constituting the dielectric sheet 10 as described above. Here, the longitudinal direction of the layer refers to a ridge-line direction of the coupled section 14, more specifically it is the planar direction w2 of the substrate.

The respective dielectric layers 11 are fixedly bonded to each other by insulating adhesive layers 16 provided between them, and the internal conductive patterns 12 and 13 are coated with the insulating adhesive layer 16. Thereby, the main surface 20 of the wiring board 100A is constituted with the continuous shape consisting of the plural coupled sections 14 fixedly bonded by the respective insulating adhesive layers 16. In a similar manner, the other main surface 21 of the wiring board 100A is constituted with the continuous shape consisting of the plural coupled sections 14 bonded fixedly by the respective insulating adhesive layers 16.

At least one of the plural internal conductive patterns 12 and 13 is extended until the coupled section 14 where the surface of the dielectric layer, on which the internal conductive pattern 12, 13 is formed, becomes an outer side of the coupling. The extended end of the internal conductive pattern 12, 13 is exposed on either of the main surfaces 20 and 21 (main surface 20 of the substrate in FIG. 1). The internal conductive pattern 12 exposed on the main surface 20, 21 of the wiring board 100A constitutes a lead electrode 17. An external connecting electrode 26 having an area larger than that of the lead electrode 17 is formed on an upper surface of the lead electrode 17. An upper surface of the external connecting electrode 26 has a flat surface in parallel with the main surfaces of the 20 and 21 of the substrate so that an electronic component mounted on the wiring board 100A can be stably loaded.

FIG. 1B shows a constitution of an electronic component mounting structure 150 in which a chip-type electronic component 140 is mounted on the wiring board 100A according to the present preferred embodiment. In the mounting structure 150, the external connecting electrode 26 is formed on each of at least the two lead electrodes 17 exposed on the main surface 20 of the wiring board 100A. Then, external connecting electrodes 141 of the electronic component 140 are made to abut the plurality of external connecting electrodes 26. Then, the external connecting electrodes 26 and the external connecting electrode 141 abutting each other are connected through conductors 142 (solder, conductive adhesive or the like). In the mounting structure 150, the electronic component 140 can be mounted on the wiring board 100A in a stable manner because the electronic component 40 is mounted on the external connecting electrodes 26 whose surfaces are flattened.

The first characteristic of the wiring board 100A according to the present preferred embodiment is to have the structure thereof where the plurality of internal conductive patterns 12 and 13 is laminated with the dielectric layers 11 between them along the planar direction of the wiring board 100A (orthogonal intersecting direction w1). Accordingly, the wirings can be dragged about at such very small pitches that thickness of the dielectric layer 11 and the internal conductive patterns 12 and 13 are added to each other. For example, assuming that the thickness of the dielectric layer 11 is 4 μm and the thickness of the internal conductive patterns 12 and 13 is 1 μm, the wirings can be dragged about at such a high density as 4-5 μm pitches. This value shows a wiring density equivalent to 8-10 build-up layers in comparison to the most-advanced 40 μm-pitch wirings in a build-up wiring board.

The second characteristic of the wiring board 100A according to the present preferred embodiment is to have the structure thereof where the internal conductive patterns 12 and 13 are coated with the insulating adhesive layers 16 and inner-packaged in the wiring board 100A. Thereby, it is possible to realize that the internal conductive patterns 12 and 13 are wired with a high density while the narrow pitches are maintained without any adverse influence from the external connecting electrode 26 formed on the main surface 20 of the wiring board 100A. In other words, the wirings can be wired with a high density without any influence from lands that has been a disincentive to the wiring density in the conventional build-up wiring board.

As described above, the present preferred embodiment provides the wiring board in which the wiring density is dramatically increased in comparison to the conventional build-up wiring board. The present preferred embodiment further solves the following technical problems that have been barriers in achieving the high density in the conventional build-up wiring board.

Though there is the narrow pitch of the wiring as a first problem for achieving a higher density, wiring layers having a large thickness are necessary in order to prevent the increase of a wiring resistance that is generated as micro-fabrication of the wirings is advanced. As a result, an advanced etching technology capable of forming a wiring pattern having a high aspect ratio is demanded. Assuming that the wiring width is, for example, 20 μm, it is necessary that the wirings are carried out at such a high aspect ratio as approximately 20 μm as a demanded wiring thickness in order to reduce the wiring resistance.

In the present preferred embodiment, the internal conductive patterns 12 and 13 are formed in the band shape on the surfaces of the respective dielectric layers 11, and the relevant pattern width can be made as wide as approximately half of the thickness of the wiring board 100A (distance between the main surfaces 20 and 21). Assuming that the thickness of the wiring board 100A is, for example, 1 mm, the internal conductive patterns 12 and 13 can have a width at least 400 μm. Then, a conductor sectional area equal to or more than that of wiring having such a high aspect ratio as width of 20 μm and thickness of 20 μm can be obtained even though the thickness of the internal conductive patterns 12 and 13 is reduced to 1 μm, and thereby it is easily achieved to reduce the wiring resistance. Because the internal conductive patterns 12 and 13 having the width of 100-μm order can be easily formed by means of a conventional etching technology, the internal conductive patterns can be formed with a good yield rate without using an etching technology for obtaining a difficult high aspect ratio.

Though there is the multi-layered wiring as a second problem to be solved for a higher density, the increase of the wiring layers indicates that the wirings go through more via holes, which deteriorates reliability. The so-called via-on-via structure in which the via hole is formed immediately above the via hole was developed in order to increase the wiring density, but it causes the new problem that the reliability is deteriorated due to thermal stress resulting from a difference in coefficients of thermal expansion in a via conductor and a dielectric member.

In the present preferred embodiment, the internal conductive patterns 12 and 13 are inner-packaged substantially with one layer in the wiring board 100A without through any via hole. Therefore, there is not any point at which the wirings are connected through the via hole. Further, the lead electrodes 17 exposed on the main surfaces 20 and 21 of the wiring board 100A have no connecting point because it is formed by extending a part of the internal conductive pattern 12. The present invention thus has a structure of the wiring board where the connecting point, that causes the deterioration of the reliability, is basically not present. Therefore, a high reliability can be easily realized in the present invention.

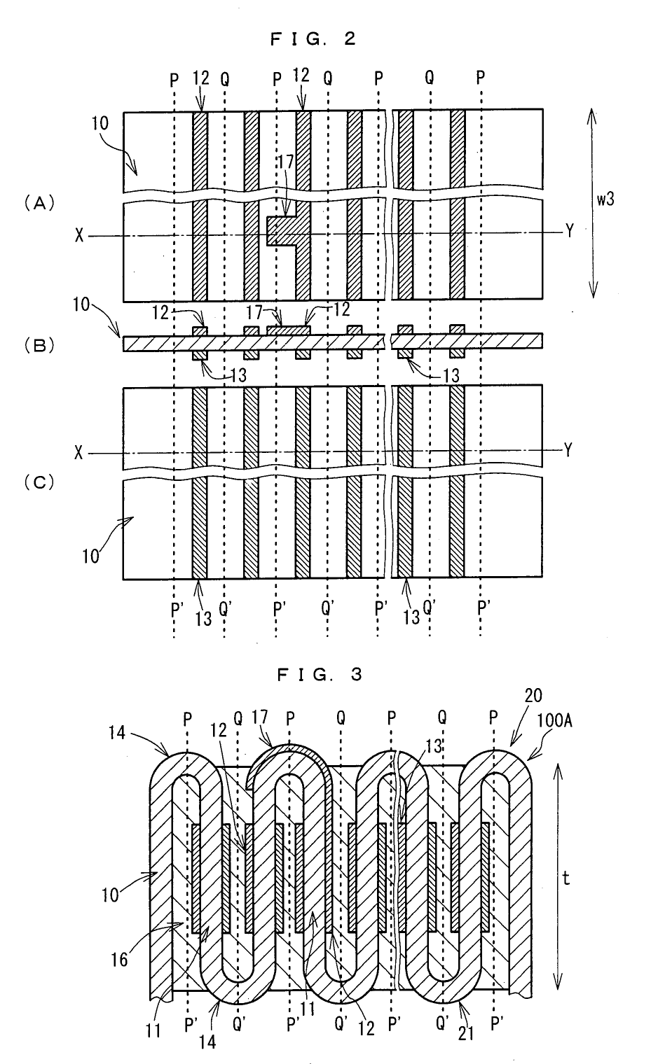

Next, a method of forming the wiring board 100A shown in FIG. 1A through alternately folding the dielectric sheet 10 is described referring to FIGS. 2A, 2B, 2C and FIG. 3.

FIGS. 2A, 2B and 2C show a planar view of the dielectric sheet 10 before it is folded, a sectional view thereof in X-Y, and a bottom view thereof respectively. As shown in FIG. 2A, mountain-side lines P-P′ which form mountains and valley-side lines Q-Q′ which form valleys in observing from one surface of the dielectric sheet 10 when the dielectric sheet 10 is folded later are virtually set on the rectangular dielectric sheet 10. The mountain-side lines P-P′ and the valley-side lines Q-Q′ are set along a direction w3 that is the one taken along one side of the dielectric sheet 10. The mountain-side lines P-P′ and the valley-side lines Q-Q′ are alternately set in parallel with each other at certain intervals. The direction w3 is a direction that is the same as the planar direction w2 of the wiring board 100A. Above is a first step.

Next, the internal conductive patterns 12 and 13 are formed on the both surfaces of the dielectric sheet 10. At the time, the internal conductive patterns 12 and 13 are formed in the band shape along the direction w3. Further, the internal conductive patterns 12 and 13 are arranged in each of the surface areas sandwiched between the adjacent mountain-side lines P-P′ and valley-side lines Q-Q′ in parallel with these lines P-P′ and Q-Q′. Further, the internal conductive patterns 12 provided on one of the surfaces of the dielectric sheet 10 and the internal conductive patterns 13 provided on the other surface thereof are arranged so as to face each other through interleaving the dielectric sheet 10 between them.

Out of the plurality of internal conducive patterns 12 and 13, a part of the internal conductive pattern 12 and 13 arbitrarily selected (internal conductive pattern 12 in the present preferred embodiment) is extended to a position beyond the mountain-side line P-P′ or the valley-side line Q-Q′ so as to constitute the lead electrode 17. The mountain-side lines P-P′ or the valley-side lines Q-Q′ is arranged on the both sides of the internal conductive patterns 12 and 13. One of these lines P-P′ and Q-Q′ is selected, and the internal conductive pattern 12 or 13 is extended until the selected line so that the lead electrode 17 is formed. The line P-P′ or Q-Q′ is selected as follows. The dielectric sheet 10 is alternately folded along the lines P-P′ and Q-Q′ in the post-step as shown in FIG. 3. When the internal conductive pattern 12 or 13 is extended to the line P-P′ or Q-Q′, there are the cases that the extended end thereof may be located within or outside the dielectric sheet 10 in the bent shape. As an extending side of the internal conductive pattern 12 or 13, the line P-P′ or Q-Q′ where the extended end of the relevant pattern is located outside of the bent dielectric sheet 10, is selected.

Here, an aramid film having the thickness of 4.5 μm is used as the dielectric sheet 10. After thin copper films are formed in the thickness of 1 μm on the dielectric sheet 10, the internal patterns 12 and 13 are formed with the width of 500 μm and at the intervals of 1 mm (interval between the mountain-side line P-P′ and the valley-side line Q-Q′). Above is a second step.

Next, as shown in FIG. 3, the dielectric sheet 10 is alternately folded along the mountain-side lines P-P′ and the valley-side lines Q-Q′. At the time, the dielectric sheet 10 is folded so that the mountain-side line P-P′ forms a mountain shape and the valley-side line Q-Q′ forms a valley shape in observing from one surface of the dielectric sheet 10. As a result, the plurality of dielectric layers 11 comprising sections superposed on one another is formed. The layer ends of the dielectric layers 11 are coupled at the coupled sections 14 formed through alternately folding the dielectric sheet 10. The plural coupled sections 14 are provided, and the respective coupled sections 14 are alternately arranged on one of the both ends of the respective dielectric layers 11. Further, the insulating adhesive layers 16 are filled between the dielectric layers 11 so that the respective dielectric layers 11 are fixedly bonded to each other. Above is a third step. In the case where the insulating adhesive layers 16 are provided so that the dielectric layers 11 are bonded to each other, suitable examples of a material used for the insulating adhesive layer 16 are thermosetting epoxy resin and a composite material including thermosetting epoxy resin as its composition. The dielectric layers 11 can be easily adhered to each other by heating to approximately 100-200° C.

Thus, the formation of the wiring board 100A shown in FIG. 1A is completed. The thickness t of the wiring board 100A is about 1 mm or less, and the wiring pitches of the internal conductive patterns 12 incorporated in the wiring board 100A are approximately 4 μm.

When the dielectric sheet 10 is folded as shown in FIG. 3, the lead electrode 17 is located on an outer connection side of the coupled section 14 and exposed on the main surface of the wiring board 100A.

### Preferred Embodiment 2

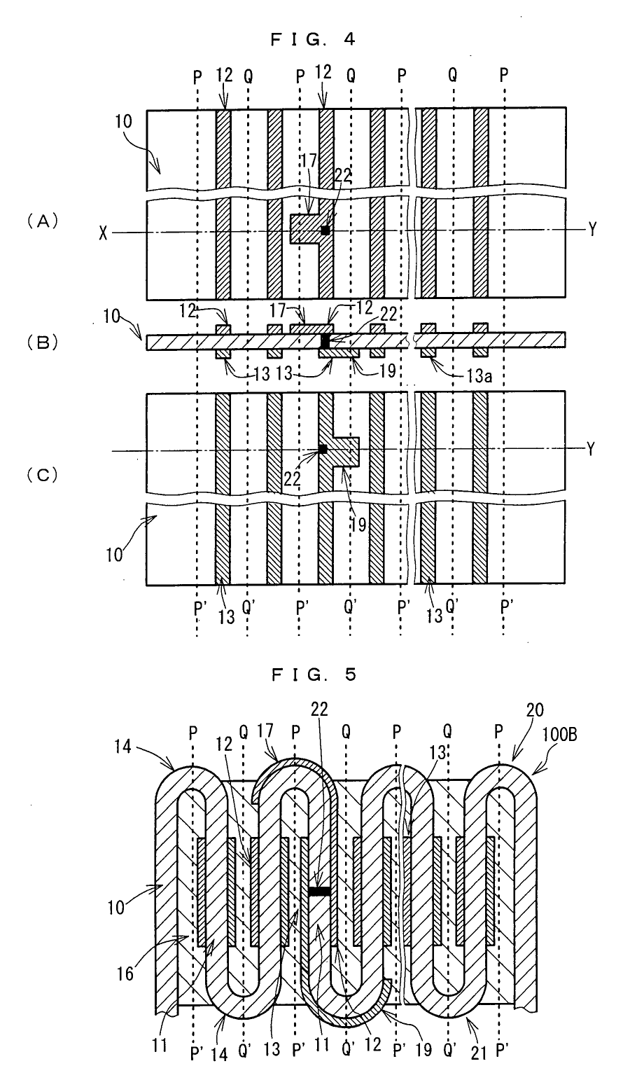

FIGS. 4A, 4B, 4C and 5 show a structure of a wiring board 100B according to a preferred embodiment 2 of the present invention and a manufacturing method thereof. The dielectric layers 11, internal conductive patterns 12 and 13, and lead electrode 17 are constituted just like the preferred embodiment 1. However, in the present preferred embodiment, the lead electrode 17 is provided on one of the main surfaces 20 of the wiring board 100B, while a lead electrode 19 is provided on the other main surface 21 of the wiring board 100B. The lead electrodes 17 and 19 are connected via the internal conductive patterns 12 and 13 above and below the wiring board 10B.

In order to mount a chip-type circuit component such as an LSI chip with a high density, the circuit component (electronic component or the like) is provided on both surfaces of a wiring board, and it becomes necessary to connect the circuit component mounted on one of the surfaces of the wiring board and the circuit component mounted on the other surface of the wiring board via a signal wire. Therefore, in the wiring board used in such application, a means for electrically connecting the lead electrode on one of the surfaces of the wiring board and the lead electrode on the other surface thereof is necessary.

FIGS. 4A, 4B and 4C are respectively a plan view of the dielectric sheet 10 before it is folded, a sectional view thereof in X-Y, and a bottom view thereof. As shown in FIG. 4A, the internal conductive patterns 12 are formed in the band shape on one of the surfaces of the dielectric sheet 10. The internal conductive pattern 12 arbitrarily selected is extended to a position beyond the mountainside line P-P′ so as to constitute the first lead electrode 17. As shown in FIG. 4C, the internal conductive patterns 13 are formed in the band shape on the other surface of the dielectric sheet 10. The internal conductive patterns 12 and 13 are arranged so as to face each other interleaving the dielectric sheet 10 between them.

The internal conductive pattern 13 facing the internal conductive pattern 12 having the lead electrode 17 is formed so as to extend until a position beyond the valley-side line Q-Q′, and the extended end constitutes the second lead electrode 19. The direction where the first and second lead electrodes 17 and 19 are extended is same as the description of the direction where the lead electrode 17 is extended in the preferred embodiment 1, therefore, not described again.

As shown in FIG. 4B, a via hole 22 is previously formed in the dielectric sheet 10. The via hole 22 is formed at a position where the internal conductive pattern 12 and the internal conductive pattern 13, in which the lead electrode 17 and the lead electrode 19 is formed respectively, face each other. The via hole 22 is filled with an inter-layer connecting conductor (metal conductor). The via hole 22 is arranged at a position as close as possible to the lead electrodes 17 and 19. Herewith, the lead electrodes 17 and 19 is connected to each other through abutting the via hole 22 (inter-layer connecting conductor) to them.

Next, as shown in FIG. 5, the dielectric sheet 10 is alternately and continuously folded along the mountainside lines P-P′ and the valley-side lines Q-Q′. At the time, the dielectric sheet 10 is folded so that the mountainside line P-P′ forms the mountain shape and the valley-side line Q-Q′ forms the valley shape in observing from one surface of the dielectric sheet 10. Thereby, the structure of the wiring board 100B comprising the plurality of dielectric layers 11 laminated along the planar direction of the substrate is embodied. The layer ends of the dielectric layers 11 are interconnected at the coupled sections 14 formed when the dielectric sheet 10 is alternately folded. A plurality of coupled sections 14 is provided, and the respective coupled sections 14 are alternately arranged on one of the both ends of the dielectric layers 11. Further, the insulating adhesive layers 16 are filled between the dielectric layers 11 so that the respective dielectric layers 11 are fixedly bonded to each other. Herewith, the plurality of dielectric layers 11 comprising sections superposed on one another is formed.

When the dielectric sheet 10 is folded, the lead electrodes 17 and 19 are located on the outer side of the coupled sections 14 and exposed on the main surfaces 20 and 21 of the wiring board 100B.

As is clear from FIG. 5, the lead electrode 17 is interconnected with the internal conductive pattern 12 by the same material moulded integrally, while the lead electrode 19 is interconnected with the internal conductive pattern 13 by the same material moulded integrally. The internal conductive patterns 12 and 13 are connected to each other through the via hole 22, and thereby the lead electrodes 17 and 19 are connected to each other.

If an electrode for external connecting (not shown) is formed in the lead electrodes 17 and 19, predetermined connecting electrodes of the circuit components mounted on the both main surfaces 20 and 21 of the wiring board 100B are connected to the external connecting electrodes so that the circuit components can be connected by the signal wire.

In the foregoing example, the number of the via hole 22 formed in the dielectric layers 11 is one. Because the internal conductive patterns 12 and 13 are formed in parallel with each other interleaving the dielectric layer 11 between them, the via hole 22 can be formed at any section between them.

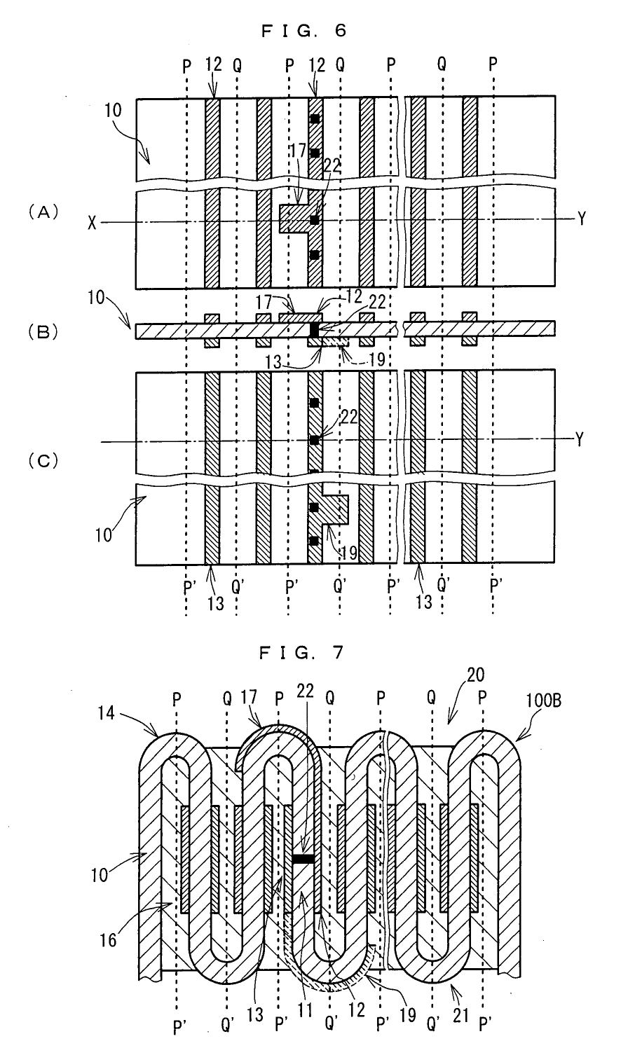

FIGS. 6A, 6B, 6C and 7 shows examples where the via hole 22 is formed at arbitrary positions. As shown in FIGS. 6A, 6B, 6C and 7, a plurality of via holes 22 is formed at approximately certain intervals in the dielectric sheet 10 (as shown in FIG. 7, dielectric layers 11 in the wiring board 100B) between the internal conductive patterns 12 and 13.

The lead electrode 17 and the internal conductive pattern 12, and the lead electrode 19 and the internal conductive pattern 13 are respectively integrally formed from the same materials, wherein any problem is not generated in terms of a contact resistance. However, the internal conductive pattern 12 and the via hole 22 (inter-layer connecting conductor), and the lead electrode 19 and the via hole 22 (inter-layer connecting conductor) are not integrally formed, and an area where they contact with each other is small. Therefore, the contact resistance is increased at these sections.

Therefore, such inconveniences as the increase of the contact resistance and the occurrence of a contact failure may be generated if the via hole 22 is formed at only one section. In the case where the plurality of via holes 22 is provided as shown in FIGS. 6A, 6B, 6C and 7, such inconveniences can be avoided, and the lead electrodes 17 and 19 can be connected in a stable manner.

In the examples shown in FIGS. 4A, 4B, 4C and 5, the lead electrode 19 is formed at the position immediately below the lead electrode 17, however, the lead electrodes 17 and 19 can be formed at positions shifted from each other as shown in FIGS. 6A and 6C. A connecting pad of the circuit component mounted on the main surface (lower surface) of the wiring board 100B and the lead electrode 19 can be more easily connected to each other by forming the lead electrodes 17 and 19 at the shifted positions.

### Preferred Embodiment 3

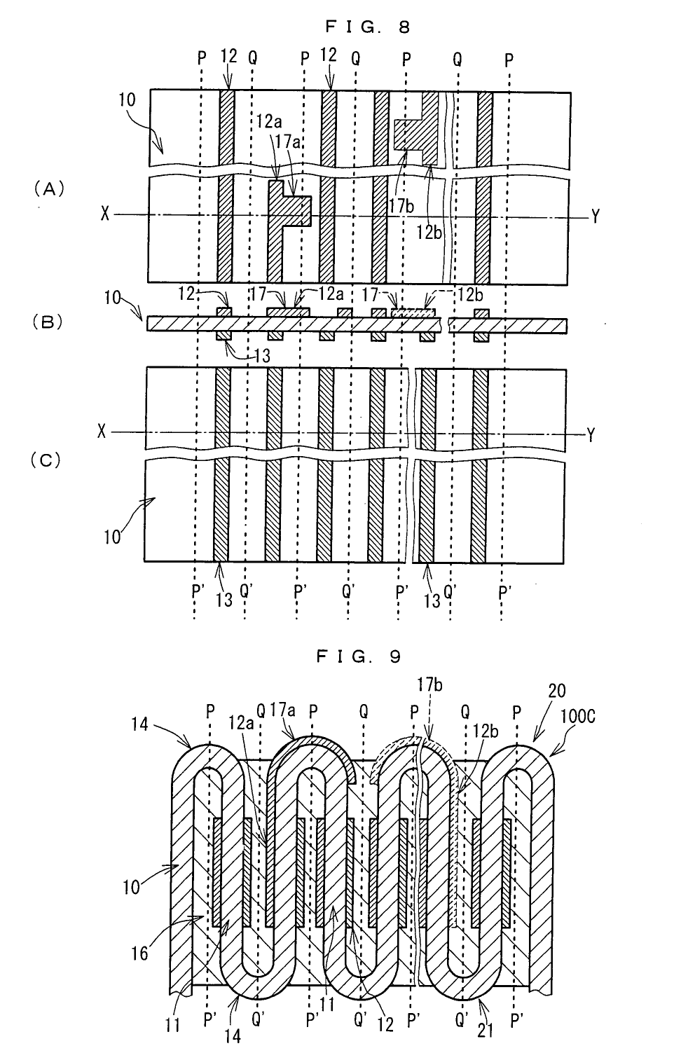

FIGS. 8A, 8B, 8C, 9 and 10 show a constitution of a wiring board 100C according to a preferred embodiment 3 of the present invention. The basic structure according to the present preferred embodiment is the same as that of the preferred embodiment 1. The present preferred embodiment is characterized in that the different internal conductive patterns 12 are connected to each other.

The basic constitution according to the present invention is characterized in that the internal conductive patterns formed with a high density are incorporated in the wiring board. The respective internal conductive patterns, that are formed in parallel with each other along the planar direction of the dielectric layers, cannot be connected to each other in the wiring board.

It can be also thought that a signal wire, which connects the internal conductive pattern constituting one signal wire to the internal conductive pattern constituting another signal wire, is hard-wired. FIGS. 8A, 8B, 8C 9 and 10 show a constitution of the preferred embodiment wherein such a wiring can be realized. As shown in FIG. 8A, an internal conductive pattern 12a constituting one signal wire and an internal conductive pattern 12b constituting another signal wire are formed on one of the surfaces of the dielectric sheet 10, and lead electrodes 17a and 17b are formed at ends of the respective internal conductive patterns 12a and 12b. The directions where the lead electrodes 17a and 17b are extended is same as that of the preferred embodiment 1.

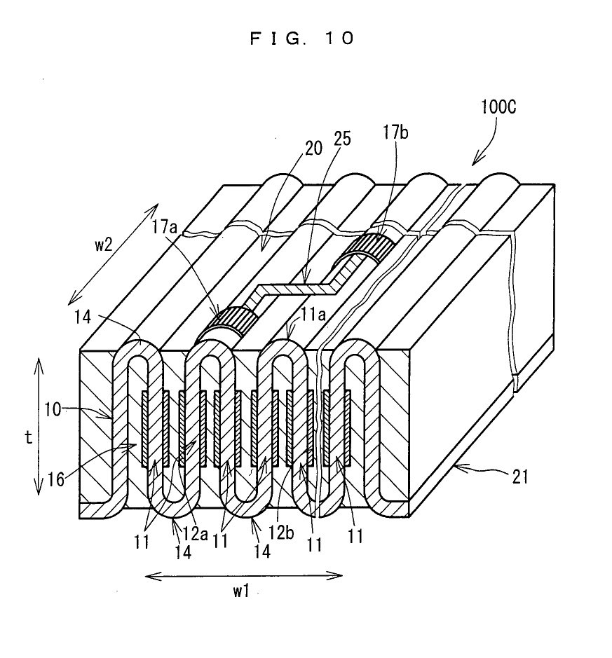

The dielectric sheet 10 is alternately and continuously folded along the mountain-side lines P-P′ and the valley-side lines Q-Q′ so that the wiring board 100C where the lead electrodes 17a and 17b are exposed at the bent sections on the mountainside of the dielectric sheet 10 can be formed as shown in FIGS. 9 and 10.

As is clear from FIG. 9, the main surfaces 20 and 21 of the wiring board 100C comprises the insulating adhesive layers 16 filled between the dielectric layers 11 and the coupled sections 14 except for the lead electrodes 17a and 17b. This means that the main surfaces 20 and 21 of the wiring board 100C are the regions insulated from the internal conductive patterns 12 and 13. Therefore, an external conductive pattern insulated from the internal conductive patterns 12 and 13 can be formed without any limitation on the main surfaces 20 and 21 of the wiring board 100c.

And so, as shown in FIG. 10, an external conductive pattern 25 that couples the lead electrodes 17a and 17b with each other is formed on the main surface 20 as one of the main surfaces of the wiring board 100C so that the internal conductive patterns 12a and 12b are connected to each other via the external conductive pattern 25. Here, because the internal conductive patterns 12 and 13 are not exposed on the main surface 20 of the wiring board 100C, the external conductive pattern 25 can be freely drabbed about and arranged on the main surface 20.

### Preferred Embodiment 4

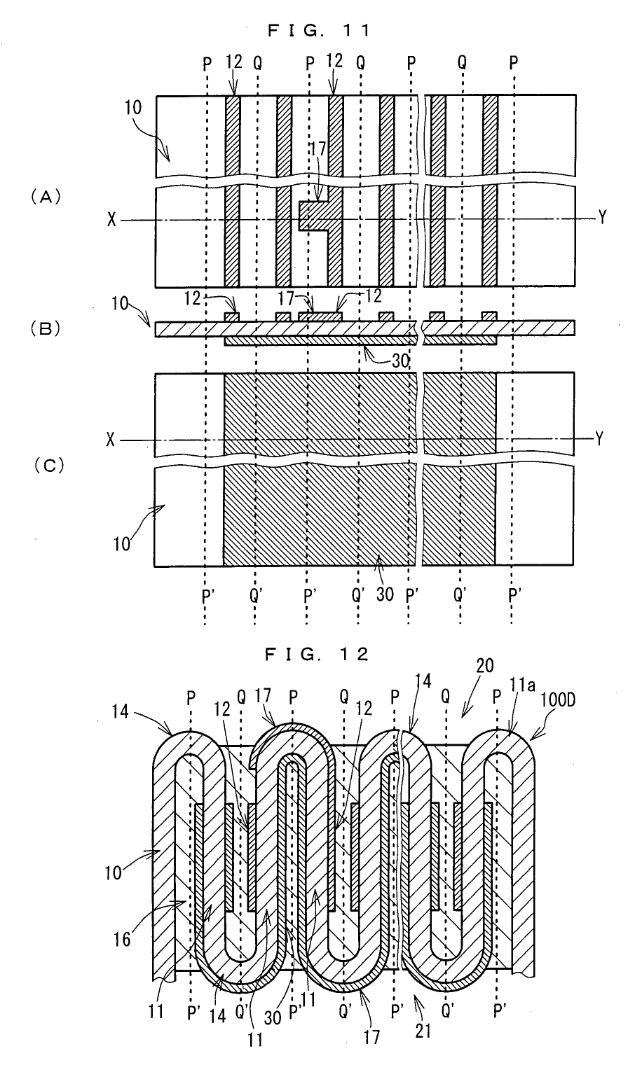

FIGS. 11A, 11B, 11C and 12 show a constitution of a wiring board 100D according to a preferred embodiment 4 of the present invention. The basic structure is the same as that of the preferred embodiment 1 in a point that the band-shape internal conductive patterns 12 are provided on one of the surfaces of the dielectric sheet 10. The present preferred embodiment is characterized in that internal conductive patterns 30 formed on the other surface of the dielectric sheet 10 are continuously connected to one another.

Generally speaking, as high integration of the LSI chip is advanced, a wiring with higher density be required, while an improvement in quality such as reduction of influences from inter-wiring crosstalk and external noises is also demanded based on a higher speed of the LSI. Conventionally, such countermeasures are devised that a shield layer was inserted between signal wiring layers or a shield wiring was inserted between signal wirings in the multi-layered wiring board. Further, a differential signal wire comprising a pair of signal wires was conventionally used in order to reduce the influence from the external noises. However, such actions resulted in the increase of build-up layers and the increase of the signal wires. Thus, it is technically difficult to strike a balance between the demand and a higher density in the wirings.

In the present preferred embodiment, such a wiring board is easily provided that the foregoing difficult problems in the conventional build-up wiring board can be solved and the wiring density is still maintained, while a constitution, wherein the shield layer covering the signal wires or shield wiring inserted between the signal wires is provided, or a constitution wherein the differential signal wire is provided.

As shown in FIGS. 11A, 11B and 11C, in the present preferred embodiment, a plurality of band-shaped first internal conductive patterns 12 is formed on one of the surfaces of the dielectric sheet 10. The second internal conductive patterns 30 are formed on the other surface of the dielectric sheet 10.

A part of the plurality of first internal conductive patterns 12 (one in FIG. 11A) has the lead electrode 17. The lead electrode 17 is constituted in a manner similar to the lead electrode 17 recited in the preferred embodiment 1, and exposed on the main surface 20 of the wiring board 100D in which the dielectric sheet 10 is arranged in a bent shape. The second internal conductive patterns formed on the other surfaces of the dielectric layers 11 are continuously formed so as to be interconnected with each other across an entire length of the patterns in a longitudinal direction thereof beyond the mountain-side and valley-side lines P-P′ and Q-Q′. The second internal conductive patterns 30 are formed in such a shape that covers an entire area of the main part on the other surface of the dielectric sheet 10. As a result, the second internal patterns 30, that are constituted with a plurality of second internal patterns in the preferred embodiment 1, are coupled with one another on the other main surface 21 of the wiring board 100D in the present preferred embodiment, and the section of the coupled second internal conductive patterns 30 is exposed on the other main surface 21 of the wiring board 100D and functions as the lead electrode 17.

Here, by using the first internal patterns 12 as the signal wires, and the second internal conductive patterns 30 as a ground wire, the first internal conductive patterns 12 constituting the signal wire incorporated in the wiring board 100D are substantially shielded by the second internal conducive patterns 30.

FIG. 12 shows the example in which the second internal conductive patterns 30 are formed across the substantially entire area of the other surface of the dielectric sheet 10. However, only the signal wire necessary to be shielded may be selected, and the continuous second internal conductive patterns 30 may be formed in any necessary section in accordance with the selected signal wire. For example, among the plurality of dielectric layers 11 incorporated in the wiring board 100D, the second internal conductive patterns 30 are pattern-formed so that the second internal conductive patterns formed in at least the four layers of the dielectric layers 11 adjacent to one another are integrally provided so as to interlink. Accordingly, the second internal conductive patterns that are adjacent and formed separately from each other between at least four patterns in the preferred embodiment 1, are continuously coupled in the present preferred embodiment and exposed on the other main surface 21 of the wiring board 100D. Even according to the constitution, the shielding effect by the second internal conductive patterns 30 can be sufficiently exerted.

Additionally, in the present preferred embodiment, the second internal conductive patterns 30 are used as the ground wire so as to exert the effect as the so-called shield layer, however, the second internal conductive patterns may be used for other purposes, for example, as a power-supply wire.

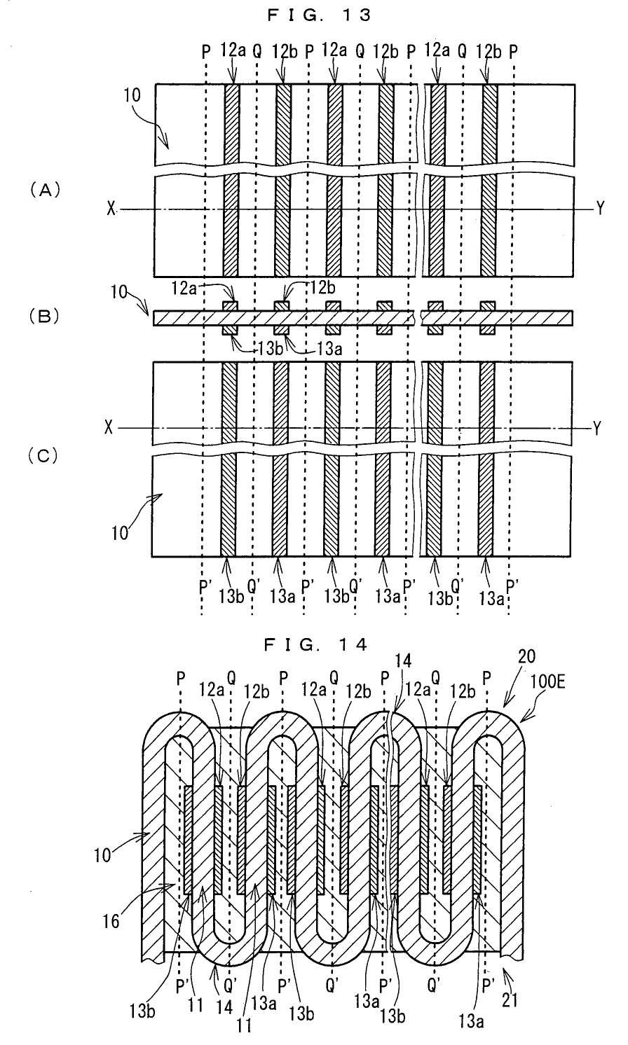

Next, the example in which the shield wire is provided between the signal wires is described referring to FIGS. 13A, 13B, 13C and 14. As shown in FIGS. 13A, 13B and 13C, in the present example, though the internal conductive patterns are provided in the same manner as described in the preferred embodiment 1, it is defined how a plurality of wiring functions should be allocated to the respective internal conductive patterns. More specifically, internal conductive patterns 12a functioning as the signal wire and internal conductive pattern 12b functioning as the shield wire are alternately arranged on one of the surfaces of the dielectric sheet 10. In a similar manner, internal conductive patterns 13a functioning as the signal wire and internal conductive pattern 13b functioning as the shield wire are alternately arranged on the other surface of the dielectric sheet 10. Further, the internal conductive patterns 12a and 12b and the internal conductive patterns 13a and 13b are respectively provided so as to face each other interleaving the dielectric sheet 10 between them. Further, the internal conductive patterns 13b functioning as the shield wire face the internal conductive patterns 12a functioning as the signal wire, and the internal conductive patterns 13a functioning as the signal wire face the internal conductive patterns 12b functioning as the shield wire.

The dielectric sheet 10 thus provided with the internal conductive patterns is folded so that a wiring board 100E shown in FIG. 14 is formed. Herewith, the wiring board 100E has such a structure that the internal conductive patterns 12b and 13b serving as the shield line are interposed between the internal conductive patterns 12a and 13a serving as the signal wire. Such a structure can prevent the crosstalk between the signal wires.

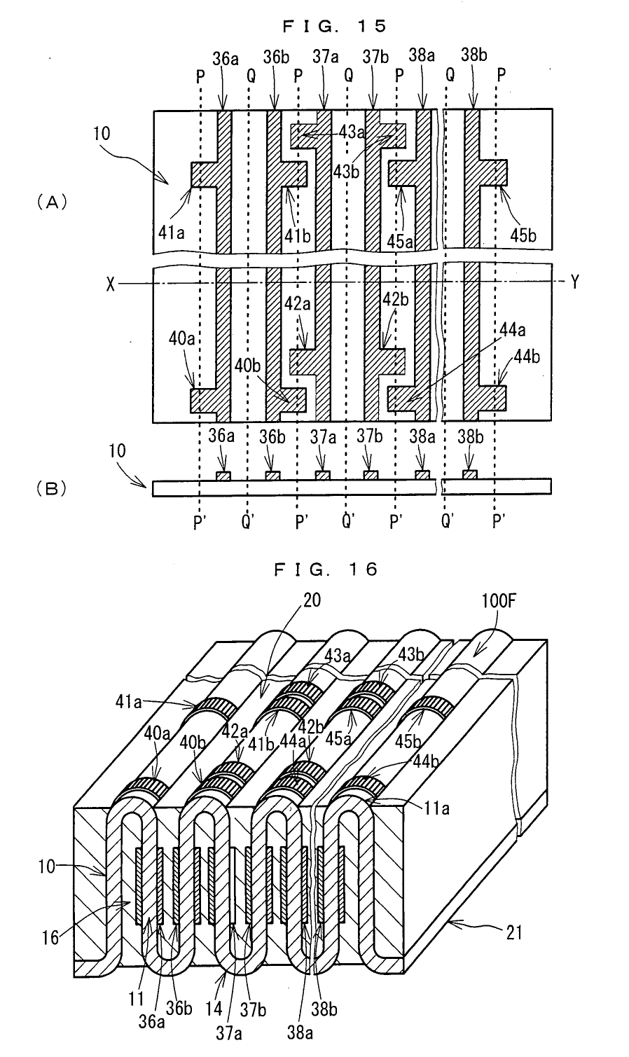

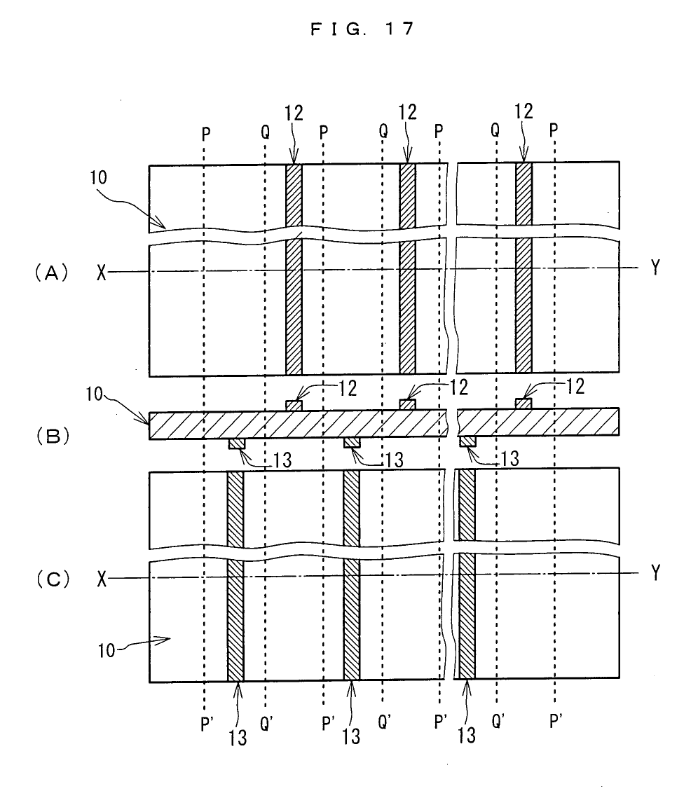

Next, the example, in which the differential signal wire comprising a pair of signal wires is provided, is described referring to FIGS. 15A, 15B and 16. As shown in FIGS. 15A and 15B (the lower surface of the dielectric sheet 10 is not shown), a plurality of internal conductive patterns 36a, 36b, 37a, 37b, 38a and 38b arranged in parallel on the surface of the dielectric sheet 10 is divided into the pairs of pattern, (36a and 36a), (37a and 37b) and (38a and 38b) respectively that face each other interleaving the valley-side line Q-Q′ between them. A pair of lead electrodes (40a and 40b), (42a and 42b) and (44a and 44b) are respectively formed at one ends of the pairs of patterns (36a and 36a), (37a and 37b) and (38a and 38b). The lead electrodes (40a and 40b), (42a and 42b) and (44a and 44b) are respectively formed toward the adjacent mountainside lines P-P′, and further extended to positions beyond the adjacent mountain-side lines P-P′. The lead electrodes 40b and 42a, and 44a and 42b are arranged at shifted positions so that these two lead electrodes do not respectively overlap with each other at positions beyond the mountain-side lines P-P′.

In a similar manner, another pairs of lead electrodes (41a and 41b), (43a and 43b) and (45a and 45b) are respectively formed at another ends of the pairs of patterns (36a and 36a), (37a and 37b) and (38a and 38b). The lead electrodes (41a and 41b), (43a and 43b) and (45a and 45b) are respectively formed toward the adjacent mountain-side lines P-P′, and further extended to positions beyond the adjacent mountain-side lines P-P′. The lead electrodes 40b and 42a are arranged at shifted positions so that they do not overlap with each other at a position beyond the mountain-side line P-P′. The lead electrodes 44a and 42b are similarly arranged.

The dielectric sheet 10 in which the pairs of patterns (36a and 36a), (37a and 37b) and (38a and 38b) are thus formed is folded so that a wiring board 100F constituted as shown in FIG. 16 is formed. Thereby, the respective pairs of patterns (36a and 36a), (37a and 37b) and (38a and 38b) are arranged at the positions where they face each other via the insulating adhesive layers 16 and constitute differential transmission wires.

The differential transmission wires constituted in the present preferred embodiment consist of the band-shape internal conductive patterns 36a, 36b, 37a, 37b, 38a and 38b extending in parallel with one another that are incorporated in the wiring board 100F. Further, lengths of the respective differential signal wires can be set to be uniform because the positions at which the lead electrodes 40a, 40b, 41a, 41b, 42a, 42b, 43a, 43b, 44a, 44b, 45a and 45b are formed in a coordinate state. As a result, variability of characteristic impedances can be controlled.

In order to shield the differential transmission wires, such a shield layer structure that the conductive patterns serving as the shield layers are formed on the entire area of the other surface of the dielectric sheet 10 as shown in FIGS. 11A, 11B and 11C may be provided.

### Preferred Embodiment 5

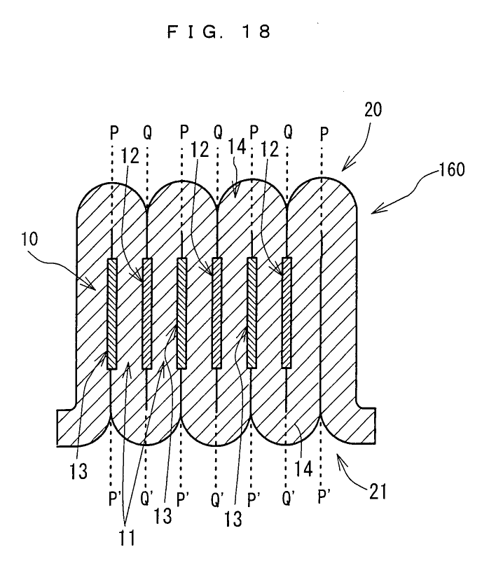

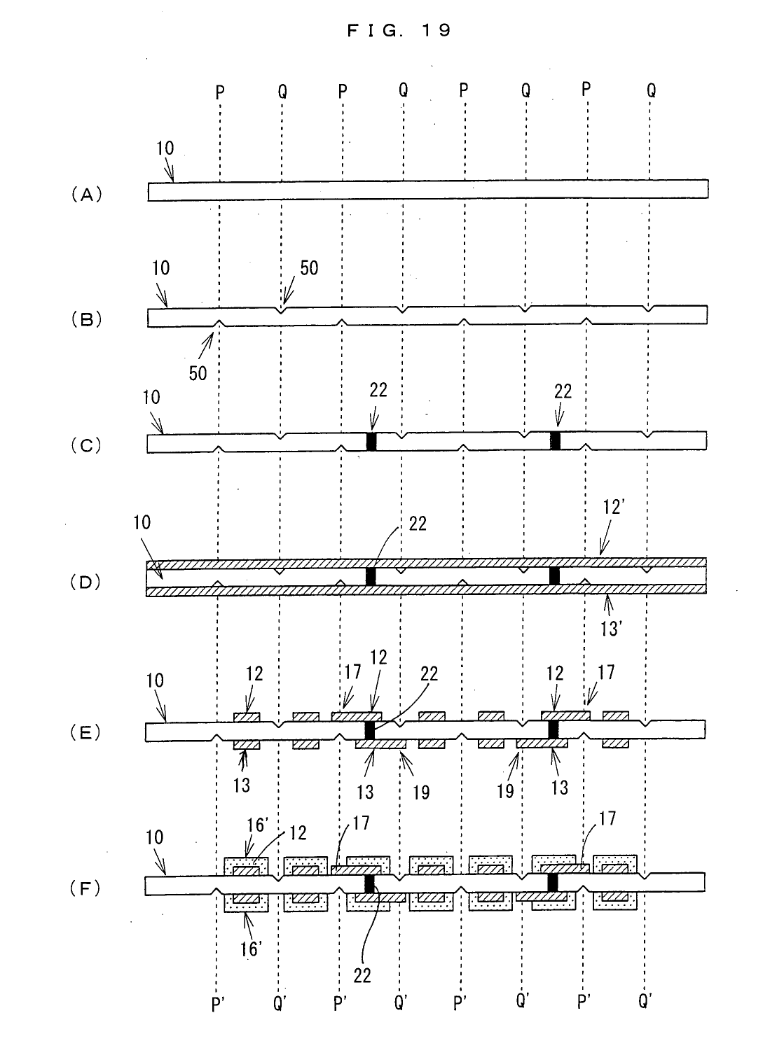

FIGS. 17A, 17B, 17C and 18 show a constitution of a wiring board 100G according to a preferred embodiment 5 of the present invention. In the present preferred embodiment, the internal conductive patterns are formed basically in the same manner as described in the preferred embodiments 1-4, however, the dielectric sheet 10 is folded in a different manner.

As shown in FIG. 17A, the internal conductive patterns 12 are formed on one of the surfaces of the dielectric sheet 10. The internal conductive patterns 12 are formed in the band shape in every other area between the valley-side lines Q-Q′ and the mountain-side lines P-P′. More specifically, the internal pattern 12 is formed in a region sandwiched between the valley-side line Q-Q′ and the mountain-side line P-P′, and the internal pattern 12 is not formed in a similar region adjacent thereto, and then, the internal conductive pattern 12 is formed in a similar region further adjacent thereto. Such a formation of the internal conductive patterns 12 is repeated.

In a similar manner, as shown in FIG. 17C, the internal conductive patterns 13 are formed on the other surface of the dielectric sheet 10. The internal conductive patterns 13 are formed in the band shape in every other region between the valley-side lines Q-Q′ and the mountain-side lines P-P′ in a manner similar to the formation of the internal conductive patterns 12. The regions where the internal conductive patterns 12 and the internal conductive patterns 13 are set so that they do not face each other.

Next, as shown in FIG. 18, the dielectric sheet 10 is alternately and continuously folded along the valley-side lines Q-Q′ and the mountain-side lines P-P′. As a result, the wiring board 100G where the dielectric layers 11 are inner-packaged and the internal conductive patterns 12 and 13 are formed on the both surfaces of the dielectric layers 11 is completed.

In the preferred embodiments 1-4, after the dielectric sheet 10 is folded, the dielectric layers 11 comprising the sections superposed on one another are bonded to one another by the insulating adhesive layers 16 filled between the dielectric layers 11. In the present preferred embodiment, the dielectric layers are directly bonded by pressure to be fixed to one another in place of the insulating adhesive layers. The internal conductive patterns 12 and 13 are alternately arranged on the upper surface and the lower surface of the dielectric sheet in order that the internal conductive patterns 12 and 13 do not overlap with each other when the dielectric layers are directly bonded by pressure to one another.

It is necessary to select a suitable material for the dielectric sheet 10 so that the dielectric layers 11 are bonded by pressure to one another. For example, a thermoplastic resin sheet can be used. In the present preferred embodiment, thermoplastic polyester such as polyethylene phthalate or polyethylene naphthalate is used as the dielectric sheet 10. These materials are molten each other when thermo compression bonding is carried out at the temperature of 200° C., and after then the dielectric layers are fixed to one another when cooled down to room temperature. Further, a thermoplastic fluorocarbon resin sheet can also be used as the dielectric sheet 10 though the heating to almost 400° C. is required for thermo compression bonding.

In the present preferred embodiment, the wiring board can be formed without the insulation adhesive layers, which simplifies the manufacturing process.

Further, the wiring board can be reduced in size because the insulating adhesive layers to be filled between the dielectric layers become unnecessary.

### Preferred Embodiment 6

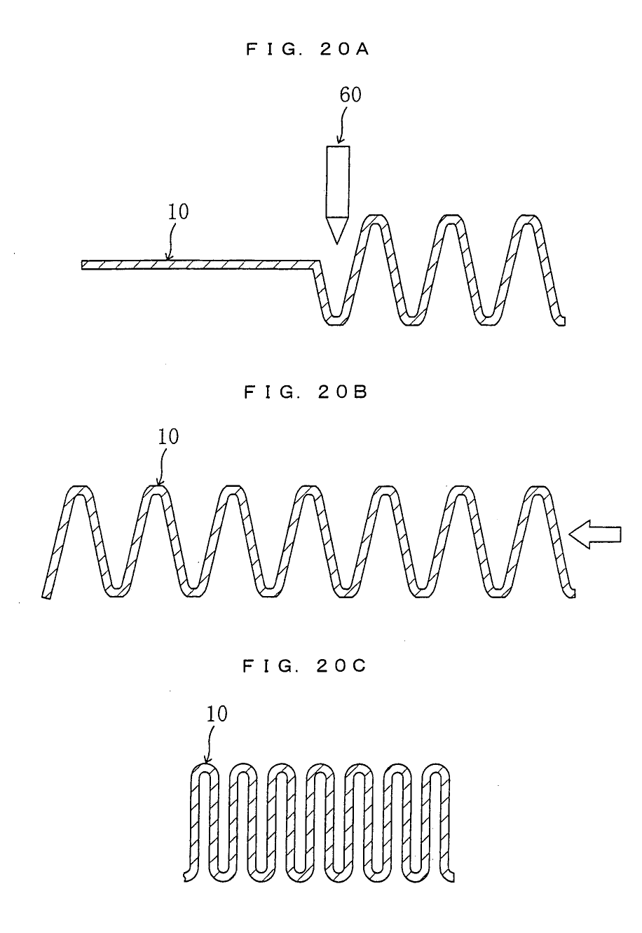

As mentioned above, explanation is given to the basic structure of the wiring board according to the present invention wherein the dielectric layers comprising the sections where the dielectric sheet is folded so as to be superposed on one another and the internal conductive patterns formed on the main surfaces of the dielectric layers, are inner-packaged, and the various modification examples of the wiring board. In a preferred embodiment 6 of the present invention, a more specific method of folding the dielectric sheet is described referring to FIGS. 19A-19F, 20A, 20B and 20C. FIGS. 19A-19B respectively show the process of forming the internal conductive patterns on the dielectric sheet before it is folded.

First, as shown in FIG. 19A, the dielectric sheet 10 having a certain width is prepared. For example, an aramid film having the thickness of 4.5 μm and width of 200 mm is used as the dielectric sheet 10.

Next, as shown in FIG. 19B, the virtual mountain-side lines P-P′ and the valley-side lines Q-Q′ for folding the sheet are provided on the surface of the dielectric sheet 10 along the direction w3 following one side of the dielectric sheet 10 (which is a perpendicular direction on the paper, see FIG. 2). The mountainside lines P-P′ and the valley-side lines Q-Q′ are alternately provided in parallel with each other at certain equal intervals.

In the present preferred embodiment, a part of the surface of the dielectric sheet 10 is removed in a wedge shape so that bending guide grooves 50 are formed along the mountain-side lines P-P′ and the valley-side lines Q-Q′ in order to facilitate the folding process. The bending guide grooves 50 of the mountain-side lines P-P′ are provided on one of the surfaces of the dielectric sheet 10, while the bending guide grooves 50 of the valley-side lines Q-Q′ are provided on the other surface of the dielectric sheet 10.

Next, as shown in FIG. 19C, the via holes 22 penetrating the dielectric sheet 10 in the thickness direction thereof are formed at predetermined positions of the dielectric sheet 10. The via holes 22 are provided at the positions abutting the lead electrodes 17 on one of the surfaces and the lead electrodes 17 on the other surface. Copper grown by means of the plating method is formed as connecting conductors on wall surfaces of the via holes 22.

After that, as shown in FIG. 19D, thin copper films 12′ and 13′ are formed at the thickness of 1 μm on the both surfaces of the dielectric sheet 10 by means of the sputtering method. Further, as shown in FIG. 19E, the thin copper films 12′ and 13′ are etched in a predetermined shape so that the internal conductive patterns 12 and 13 are formed. The internal conductive patterns 12 and 13 are formed on the sheet surface regions surrounded with the mountainside lines P-P′ and the valley-side lines Q-Q′.

A part of the internal conductive patterns 12 and 13 are headed to the adjacent mountainside line P-P′ or valley side line Q-Q′ and further formed so as to extend until positions beyond the lines P-P′ or Q-Q′, and the extended ends thereof constitute the lead electrodes 17 and 19. Further, a part of the internal conductive patterns 12 and 13, that face each other interleaving the dielectric sheet 10 between them, abut the via holes 22 and thereby connected to each other through the via holes 22.

Finally, as shown in FIG. 19F, after a semi-curable insulating sheet 16′ is formed on the dielectric sheet 10, the semi-curable insulating sheet 16′ is removed under a state where only the semi-curable insulating sheet 16′ in the upper regions of the internal conductive patterns 12 and 13 is selectively retained. As a result, the internal conductive patterns 12 and 13 are covered with the semi-curable insulating sheet 16′, and the lead electrodes 17 and 19 have a structure that they are exposed out of the semi-curable insulating sheet 16′. Here, composite resin consisting of an inorganic filler and epoxy resin is used as the semi-curable insulating sheet 16′.

Next, a method of folding the dielectric sheet 10 after the internal conductive patterns are formed thereon is described referring to FIGS. 20A, 20B and 20C. In FIGS. 20A, 20B and 20C, only the dielectric sheet 10 is shown, and the internal conductive patterns 12 and 13, and the semi-curable insulating sheet 16′ are omitted.

First, as shown in FIG. 20A, the dielectric sheet 10 is folded from the end thereof at each of the mountain-side lines P-P′ and the valley-side lines Q-Q′ while a plate-shape jig 60 whose lower surface is thinned is applied thereto. After the dielectric sheet 10 is completely folded, the dielectric sheet 10 is pressed from the both sides thereof until the respective semi-curable insulating sheets 16′ (not shown) contact with one another as shown in FIG. 20B. Finally, the dielectric sheet 10 is cooled down to room temperature after heated at the temperature of 200° C. for approximately 60 minutes under a pressurized state. Then, the semi-curable insulating sheets 16′ are bonded to one another, and the wiring board 100A is completed.

Examples of the technology for folding a flexible wiring board are recited in No. H11-330639 and No. 2002-319750 of the Japanese Patent Applications Laid-Open and No. 6121676 of the US Patent Publications and the like. However, any of these documents fails to disclose or imply the high-density wiring board comprising the wiring patterns (internal conductive patterns) provided at narrow pitches along the planar direction of the substrate that is the characteristic of the present invention.

No. H11-330639 of the Japanese Patent Applications Laid-Open recites a technology for continuously folding a wiring sheet having a film shape in a rectangular solid shape. An object of the technology is to realize a mounting substrate on which electronic components mounted on a surface of the wiring sheet are housed as closely as possible, and the relevant document fails to include any recitation in relation to the constitution of the wiring patterns or imply the constitution of the wiring patterns according to the present invention.

### Preferred Embodiment 7

In a build-up multi-layered substrate, a core substrate for supporting build-up layers is necessary since the build-up layers themselves are not self-organized. More specifically, in the build-up multi-layered wiring board, an insulation layer and a conductive layer are laminated on each other on the surface of the core substrate, then, the conductive layer is etched to form the wiring pattern so that one build-up layer is formed, and the procedure is repeated so that a multiple number of build-up layers are stacked on one another.

However, the core substrate is naturally thicker than the build-up layers, which inevitably increases a size of a through hole and consequently a land pitch. It cannot be expected in the core substrate to increase the wiring density, and the core substrate merely serves to support the build-up layers. Therefore, the core substrate itself is an obstacle in the reduction of the thickness of the build-up wiring board, and is also a factor of cost increase. A preferred embodiment 7 of the present invention is done to solve these problems.

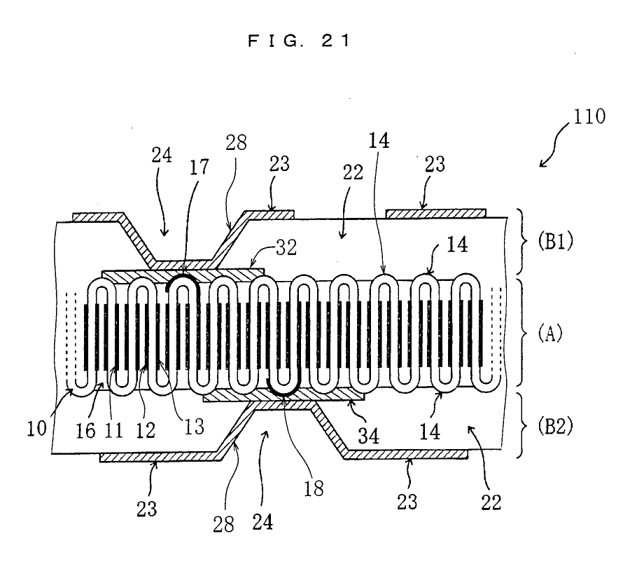

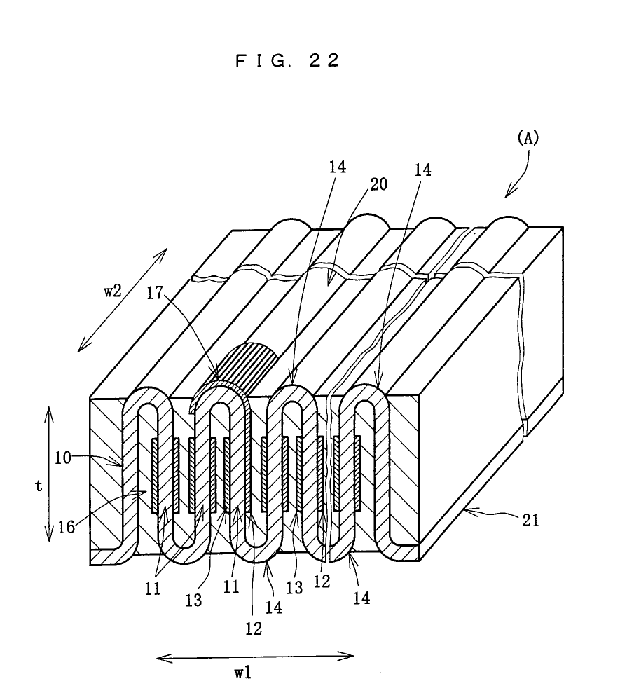

A multi-layered wiring board according to the preferred embodiment 7, which is different to the conventional multi-layered wiring board, does not require the formation of micro-fabricated wiring patterns and can remarkably reduce the number of the via holes to be connected which the signal wires go through. As a result, the reliable wirings at a high density can be obtained. FIGS. 21 and 22 show a constitution of a multi-layered wiring board 110 according to the preferred embodiment 7. FIG. 21 is a sectional view thereof, while FIG. 22 is a sectional view of the core substrate that is a main component of the substrate.

The wiring board 110 comprises a core substrate A and wiring boards B1 and B2 provided on main surfaces 20 and 21 of the core substrate A.

The core substrate A comprises a core substrate main body and internal conductive patterns 12 and 13. The core substrate main body comprises a plurality of dielectric layers 11 comprising sections formed by alternately folding the dielectric sheet 10 having a certain width so as to be superposed on one another. A plurality of internal conductive patterns 12 and 13 are formed on both surfaces of the dielectric layers 11.

The core substrate A has a structure of a rectangular flat-plate shape as shown in FIG. 22. The respective dielectric layers 11 are arranged along a direction t (thickness direction) where the main surfaces 20 and 21 of the core substrate A face each other and laminated along a direction w1 intersecting in orthogonal state with the facing direction t. The orthogonal-intersecting direction w1 refers to a planar direction of the substrate along an arbitrary side of the rectangular core substrate A. The internal conductive patterns 12 and 13 are provided on the surfaces of the dielectric layers 11. The internal conductive patterns 12 and 13 are provided on the both surfaces of the dielectric layers 11. The adjacent dielectric layers 11 are formed so as to interconnect by integrally interlinking the layer ends thereof with each other on any of the main surfaces 20 and 21 of the core substrate A.

The coupled layer ends constitute coupled sections 14 of the adjacent dielectric layers 11. The coupled sections 14 are continuously provided on the dielectric layers 11 across an entire width thereof (full width of the core substrate A), in other words, along a planar direction w2 of the substrate intersecting in orthogonal state with the orthogonal-intersecting direction w1 on the plane of the substrate. The coupled sections 14 are provided on the both layer ends of the respective dielectric layers 11. The plurality of coupled sections 14 are alternately provided on any of the main surfaces 20 and 21 of the core substrate A along the orthogonal-intersecting direction w1. More specifically, the coupled section 14 adjacent to the coupled section 14 on the main-surface-20 side is provided on the other main surface 21, while the coupled section 14 adjacent to the coupled section 14 on the other-main-surface-21 side is provided on the main surface 20.

Accordingly, the whole of the plural dielectric layers 10 constitute a dielectric sheet 10 arranged in a bent shape by folding at the coupled sections 14, and the folded dielectric sheet 10 constitutes the rectangular core substrate main body. The internal conductive patterns 12 and 13 are arranged in a band shape on the dielectric layers 11 thus constituting the dielectric sheet 10 along a longitudinal direction thereof. The longitudinal direction of the layers denotes a ridge-line direction of the coupled sections 14, more specifically, the planar direction w2 of the substrate.

The respective dielectric layers 11 are fixedly bonded to one another by insulating adhesive layers 16 provided between the layers, and the internal conductive patterns 12 and 13 are coated with the insulating adhesive layers 16. The continuum of the plurality of coupled sections 14 fixedly bonded by the insulating adhesive layers 16 constitute the main surface 20 of the core substrate A. In a similar manner, the continuum of the plurality of coupled sections 14 fixedly bonded by the insulating adhesive layers 16 constitute the other main surface 21 of the core substrate A

At least one of the plurality of internal conductive patterns 12 and 13 is extended to the coupled section 14 where the surface of the dielectric layer 11, on which the internal conductive pattern 12 or 13 is formed, becomes an outer side of the coupling. The extended end of the internal conductive pattern 12 or 13 is thereby exposed on one of the main surfaces 20 and 21 (main surface 20 of the substrate in FIG. 1). The internal conductive patterns 12 exposed on one of the main surfaces 20 and 21 of the core substrate A constitute lead electrodes 17 and 18. External connecting terminals 32 and 34 having areas larger than those of the lead electrodes 17 and 18 are formed on upper surfaces of the lead electrodes 17 and 18. The upper surfaces of the external connecting terminals 32 and 34 are flat surfaces in parallel with the main surfaces 20 and 21.

The wiring substrates B1 and B2 are respectively laminated on the main surfaces 20 and 21 of the core substrate A. The wiring board B1 and B2 respectively comprise insulating layers 27 laminated on the main surfaces 20 and 21 of the core substrate A and wiring patterns 23 laminated on exposed surfaces of the insulating layers 27. The wiring patterns 23 are patterned in a predetermined wiring shape. Via holes 24 are formed in the wiring boards B1 and B2. The via holes 24 are formed so as to penetrate the insulating layers 27 in a thickness direction thereof. The insulating layers 27 including the wiring patterns 23 are opened by the via holes 24 the in the thickness direction thereof at the positions where the wiring patterns 23 are formed. The external connecting terminals 32 and 34 are exposed at bottom sections of the via holes 24.

Connecting conductors 28 are formed in inner walls of the via holes 24. The connecting conductors 28 are formed from the connecting terminals 32 and 34 through the patterns 23, and the external connecting conductors 32 and 34, and the wiring patterns 23 are connected to each other via the connecting conductors 28.

Next, a structural characteristic of the multi-layered wiring board 110 thus constituted is described. In the core substrate A, the internal conductive patterns 12 formed in the band shape are alternately laminated interleaving the dielectric layers 11 between them in the horizontal direction (planar direction of the substrate).

Therefore, the wirings can be dragged about at such very small pitches substantially equal to the sum of thickness of the dielectric layer 11 and the thickness of the internal conducive patterns 12 and 13. Assuming that the thickness of the dielectric layer 11 is 4 μm and the thickness of the internal conductive patterns 12 and 13 is 1 μm, for example, the wirings can be dragged about at such a high density as 4-5 μm. This value is such a high wiring density equivalent to eight through ten wiring layers in comparison to the 40-μm-pitch wirings in the most-advanced multi-layered wiring board (for example, build-up multi-layered wiring board).

In the core substrate A, the internal conductive patterns 12 and 13 are coated with the insulating adhesive layers 16 and incorporated in the core substrate A. Therefore, the internal conducive patterns 12 and 13 can be maintained at narrow pitches without any adverse influence from the external connecting terminals 32 and 34 provided on the main surfaces 20 and 21 of the core substrate A, which realizes the high-density wirings.

Because the internal conductive patterns 12 and 13 are incorporated in the core substrate A, the conductive patterns (wiring patterns) can be formed without any restriction on the main surfaces 20 and 21 of the core substrate A. The conductive patterns can function as intermediate members that connect the external connecting terminals 32 and 34, and the lead electrodes 17 and 18. Therefore, the external connecting terminals 32 and 34 can be provided at any arbitrary position on the main surfaces 20 and 21 of the core substrate A.

As described above, the structure of the core substrate A can contain the high-density wirings at narrow pitches. However, as the wirings (internal conductive patterns 12 and 3) are all together in the same direction (perpendicular direction on the paper), a degree of freedom in the wirings is limited in the case where the LSI chips having a large number of connecting terminals are connected to each other via the wirings. The before-mentioned conductive patterns are provided on the main surface of the core substrate A, and the lead electrodes 17, 17 or the lead electrodes 18, 18 on the same main surface are connected to each other by the conductor patterns so that the degree of freedom in the wirings is increased. However, the main surfaces 20 and 21 of the core substrate A, consisting of the coupled sections 14 of the dielectric layers 11, are not so flat, and therefore, not suitable for the formation of the micro-fabricated patterns thereon. Thus, it is difficult for the core substrate A to function as the wiring board.

Focusing on that the structure of the core substrate A has such a mechanical strength that allows a physical independence, the multi-layered wiring board 110 is constituted as follows. More specifically, in the multi-layered wiring board 110, the substrate structure is made a structure of the build-up wiring board, and then the build-up wiring boards are integrally laminated on the core substrate A so that the core substrate A supports the build-up wiring boards.

Accordingly, the core substrate, which was unsuitable for the high-density wirings and could only serve as the substrate which supports the build-up wiring board, can be replaced with the high-density wiring board equivalent to eight to ten build-up layers. The limitation of the degree of freedom in the wirings can be solved when the wiring boards B1 and B2 comprising the build-up wiring layers are laminated on the core substrate A. By laminating the wiring boards B1 and B2 comprising the build-up wiring layers on the core substrate A, the flatness of the main surfaces of the entire multi-layered wiring board can be improved, which facilitates the formation of the micro-fabricated wiring patterns.

Further, because the flatness of the surfaces of the core substrate A can be improved, there is no particular problem generated when the insulating layer 27 is opened to form the via hole 24, and also when the wiring pattern 23 is etched.

The sizes of the lead electrodes 17 and 18 exposed on the main surfaces 20 and 21 of the core substrate 17 and 18 can be as very small as approximately 8-10 μm. On the contrary, the size of the via hole 24 formed in the insulating layer 27 is approximately 30-40 μm at the minimum, which is significantly larger than the lead electrodes 17 and 18. Therefore, the external connecting terminals 32 and 34, which are as large as the via hole 24, are formed on the lead electrodes 17 and 18, so that the wiring patterns 23 and the lead electrode 17 and 18 can be more easily connected.

Thus, the internal conductive patterns 12 and 13 formed on the core substrate A can be connected to the wiring patterns 23 via the lead electrodes 17 and 18, external connecting terminals 32 and 34 and connecting conductors 28. The wiring patterns 23 are thereby connected to a predetermined electrode terminal of the LSI chip mounted on the multi-layered wiring board.

According to the multi-layered wiring board 110 of the present preferred embodiment, the wiring boards B1 and B2 comprising the build-up wiring layers, which have the degree of freedom in the wirings, though the wiring pitch thereof is large, are laminated on the core substrate A capable of dragging about a large number of many signal wirings having the small wiring (internal conductive pattern) pitches, so that the wiring density can be increased with a smaller number of layers in the wiring board. Further, the connection number of the via holes where the signal wires go through and the number of the wiring layers can be significantly reduced. As a result, the reliable multi-layered wiring board can be realized.

As well, in the present preferred embodiment, the connecting conductors 28 formed in the via holes 24, and the lead electrodes 17 and 18 are connected via the external connecting terminals 32 and 34. However, the connecting conductors 28 and the lead electrodes 17 and 18 may directly abut each other to be connected without the interposition of the external connecting terminals 32 and 34. According to the constitution, when the via holes 24 are formed in the insulating layers 27 provided on the main surfaces 20 and 21 of the core substrate A, the wiring patterns 23 can be prevented from short-circuiting to the wiring sections except for the lead electrodes 17 and 18 in the connected sections because the main surfaces 20 and 21 of the core substrate A comprise the bent sections of the dielectric sheet and the insulating adhesive layers 16 filled between the dielectric layers 11 except for the sections where the lead electrodes 17 and 18 are exposed.

In the present preferred embodiment, the wiring boards B1 and B2, which are respectively one layer, are laminated on the main surfaces 20 and 21 of the core substrate A. However, wiring boards, which are respectively at least two layers, may be laminated if necessary. Additionally, it is preferable that these wiring boards are formed as the build-up wiring layers since the main surfaces 20 and 21 of the core substrate A are thereby flattened. However, the effect of the present invention can be still exerted even when wiring boards formed in a different manner are provided.

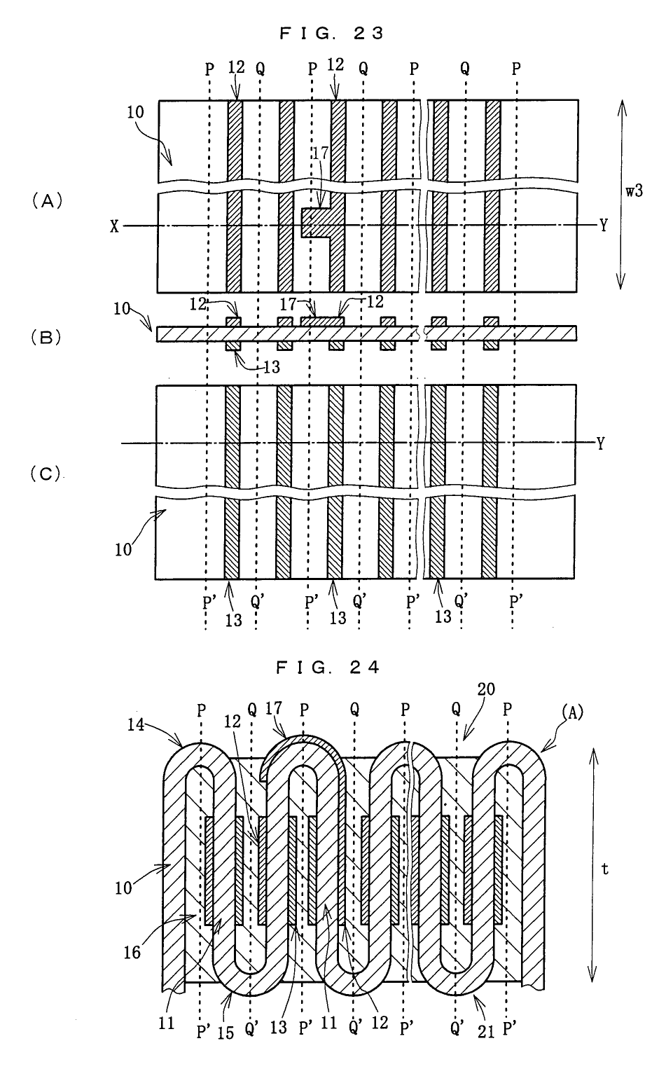

Next, a method of forming the core substrate A shown in FIG. 22 by alternately folding the dielectric sheet 10 is described referring to FIGS. 23A, 23B, 23C and 24.

FIGS. 23A, 23B and 23C are respectively a plan view of the dielectric sheet 10 before it is folded, a sectional view thereof in X-Y, and a bottom view thereof. As shown in FIG. 23A, the mountain-side lines P-P′ which forms mountains and the valley-side lines Q-Q′ which forms valleys in observing from one surface of the dielectric sheet 10 when the dielectric sheet 10 is folded later, are virtually set on the rectangular dielectric sheet 10. The mountainside lines P-P′ and the valley-side lines Q-Q′ are set along a direction w3 taken along one side of the dielectric sheet 10. The mountainside lines P-P′ and the valley-side lines Q-Q′ are alternately set in parallel with each other at certain intervals. The direction w3 is a direction that is the same as the planar direction w2 of the core substrate A. Above is a first step.

Next, the internal conductive patterns 12 and 13 are formed on the both surfaces of the dielectric sheet 10. At the time, the internal conductive patterns 12 and 13 are formed in the band shape along the direction w3. Further, the internal conductive patterns 12 and 13 are arranged in surface areas wedged between the adjacent mountain-side lines P-P′ and valley-side lines Q-Q′ in parallel with these lines P-P′ and Q-Q′. Further, the internal conductive patterns 12 provided on one of the surfaces of the dielectric sheet 10 and the internal conductive patterns 13 provided on the other surface thereof are provided so as to face each other interleaving the dielectric sheet 10 between them.

Among the plurality of internal conducive patterns 12 and 13, a part of the internal conductive patterns 12 and 13 arbitrarily selected (internal conductive pattern 12 in the present preferred embodiment) is extended to a position beyond the mountain-side line P-P′ or the valley-side line Q-Q′ so as to constitute the lead electrode 17. The mountainside line P-P′ or the valley-side line Q-Q′. are arranged on the both sides of the internal conductive patterns 12 and 13. One of these lines P-P′ and Q-Q′ is selected, and the internal conductive patterns 12 and 13 are extended to the selected lines so that the lead electrodes 17 and 18 are formed. The line P-P′ or Q-Q′ is selected as follows. The dielectric sheet 10 is alternately folded along the lines P-P′ and Q-Q′ in the following step as shown in FIG. 24. In the case where the internal conductive patterns 12 and 13 are extended to the lines P-P′ and Q-Q′, the extended end thereof may be located within or outside of the dielectric sheet 10. The line P-P′ or Q-Q′, in which the extended end of the relevant pattern is located outside of the bent dielectric sheet, is selected as the extended side of the internal conductive patterns 12 and 13.

Here, an aramid film having the thickness of 4.5 μm is used as the dielectric sheet 10. After thin copper films are formed in the thickness of 1 μm on the dielectric sheet 10, the internal patterns 12 and 13 are formed on the dielectric sheet 10 with the width of 400-600 μm and at the interval of 1 mm (interval between the mountain-side line P-P′ and the valley-side line Q-Q′) by means of the etching process. Above is a second step.

Next, as shown in FIG. 24, the dielectric sheet 10 is alternately folded along the mountain-side lines P-P′ and the valley-side lines Q-Q′. At the time, the dielectric sheet 10 is folded so that the mountainside lines P-P′ forms the mountain shape and the valley-side lines Q-Q′ forms the valley shape in observing from one surface of the dielectric sheet 10. Thereby, the structure of the core substrate A comprising the plurality of dielectric layers 11 laminated along the planar direction of the substrate is embodied. The thickness t of the core substrate A is approximately less than 1 mm, and the wiring pitches of the internal conductive patterns 12 incorporated in the wiring board 100A are approximately 4 μm.

Here, the layer ends of the dielectric layers 11 are interconnected at the coupled sections 14 formed when the dielectric sheet 10 is alternately folded. A plurality of coupled sections 14 is provided, and the respective coupled sections 14 are alternately arranged on either of the both ends of the dielectric layers 11. Further, the respective dielectric layers 11 are fixedly bonded to each other by filling the insulating adhesive layers 16 between the dielectric layers 11. As a result, the plurality of dielectric layers 11 comprising sections superposed on one another is formed. Above is a third step. When the insulating adhesive layers 16 are provided so that the dielectric layers 11 are bonded to each other, suitable examples of a material used for the insulating adhesive layer 16 are thermosetting epoxy resin and a composite material including thermosetting epoxy resin in its composition. The dielectric layers 11 can be easily adhered to each other when heated to approximately 100-200° C. When the dielectric sheet 10 is folded, the lead electrodes 17 and 18 are located on an outer side of the coupled sections 14 and exposed on the main surfaces 20 and 21 of the core substrate A.

As is clear from FIG. 24, the lead electrodes 17 and 18 are coupled with the internal conductive patterns 12 and 13 by the same material integrally formed, and the lead electrodes 17 and 18 are coupled with the internal conductive patterns 12 and 13 by the same material integrally formed.

As shown in FIG. 21, the external connecting terminals 32 and 34 are formed on the main surfaces 20 and 21 of the core substrate A. The external connecting terminals 32 and 34 abut and are thereby connected respectively to the lead electrodes 17 and 18. The external connecting terminals 32 and 34 have flat upper surfaces in parallel with the main surfaces 20 and 21.

Other than the aramid film, thermoplastic fluororesin, thermosetting epoxy resin or the like, can be used as the dielectric sheet 10 (dielectric layers 11). The folded dielectric layers 11 are bonded to one another by filling the insulating adhesive layers 16 between them, however, the dielectric layers 11 can be directly bonded by pressure to each other without the insulating adhesive layers 16. A suitable example of the material used for the dielectric layers 11 (dielectric sheet 10) in this case is thermoplastic polyeseter or the like.

Next, a process of the formation of the wiring boards B1 and B2 laminated on the main surfaces 20 and 21 of the core substrate A is described. First, insulating layers 27 are laminated on the main surfaces 20 and 21 of the core substrate A. This is a fourth step. Further, via holes 24 are formed in the insulating layers 27. The via holes 24 are formed in the insulating layers 27 so as to penetrate in a thickness direction thereof. The via holes 24 are formed so as to penetrate the insulating layers 27 including the wiring patterns 23 in the thickness direction thereof at the positions where the wiring patterns 23 are formed so that the external connecting terminals 32 and 34 are exposed at the bottoms of the via holes 24.

Next, the conductive layers are formed on the surfaces of the insulating layers 27, and the formed conductive layers are etched so that the wiring patterns 23 are formed. At the time, the connecting conductors 28 are formed inside the via holes 24 formed in the insulating layers 27. The wiring patterns 23 formed in the build-up wiring layers B1-B2 are thereby connected to the internal conductive patterns 12 and 13 formed in the core substrate A via the lead electrodes 17 and 18. This is a fifth step.

When the first through fifth steps are implemented, the manufacturing of the multi-layered wiring board 110 is completed. As the method of forming the wiring boards B1 and B2 laminated on the main surfaces 20 and 21 of the core substrate A, description is given to the case where the wiring patterns are formed after the insulating layers 27 and the via holes 24 are formed. However, the same effect can be still exerted in the case where a process similar to the conventional method of forming the build-up layers for the build-up substrate is adopted. For example, copper foils including resin are laminated on the core substrate A so that the copper foils for the insulating layers 27 and the wiring patterns 23 are previously formed.

Then, the via holes 24 are formed so as to open a hole by penetrating the copper foils and the insulating layers 27 by means of a laser or the like, and the connecting conductors 28 are thereafter formed in the via holes 24.

### Preferred Embodiment 8

When the LSI chip is mounted on the multi-layered wiring board 110 shown in FIG. 22, it may be necessary to electrically connect the wiring patterns 23 formed on the surface of the wiring board B1 and the wiring patterns 23 formed on the surface of the wiring board B2 to each other in the multi-layered wiring board 110 in which the wiring boards B1 and B2 are laminated on the main surfaces 20 and 21 of the core substrate A.

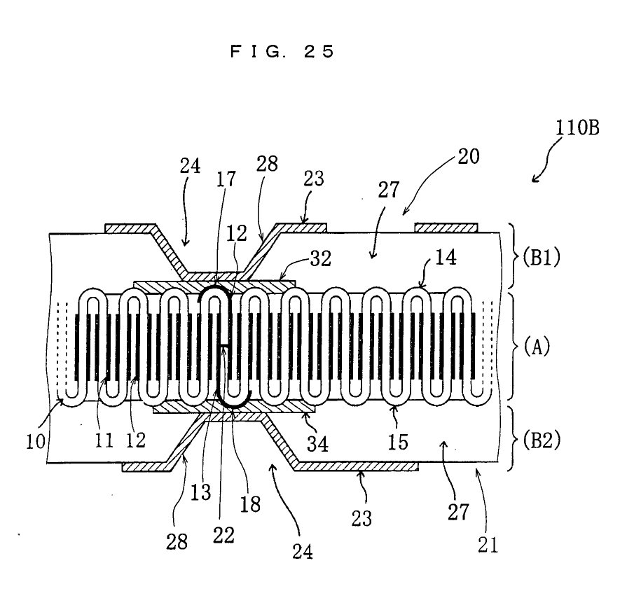

FIG. 25 shows a constitution of a multi-layered wiring board 110B according to a preferred embodiment 8 of the present invention. The basic structure is similar to that of the multi-layered wiring board 110A shown in FIG. 21. In the structure of the core substrate A, the lead electrode 17 formed on the main surface 20 of the core substrate A and the lead electrode 18 formed on the other main surface 21 of the core substrate A are connected to each other through the via holes (inter-layer connecting conductors) 22 formed in the dielectric layers 11. The wiring patterns 23 formed on the wiring board B1 and the wiring patterns 23 formed on the wiring board B2 are thereby connected to each other.

As shown in FIG. 25, the internal conductive patterns 12 and 13 are formed on the both surfaces of the dielectric layers 11 in the core substrate A, and a part of the internal conductive patterns 12 and 13 is exposed on the main surface 20 or 21 of the core substrate A so as to constitute the lead electrode 17 or the lead electrode 18. The external connecting electrodes 32 and 32 are formed on the lead electrodes 17 and 18.

The internal conductive patterns 12 and 13 in which the lead electrodes 17 and 18 are formed are connected to each other through the via holes 22 formed in the dielectric layers 11. As a result, the lead electrodes 17 and 18 formed on the both surfaces of the core substrate A are connected to each other through the via holes 22 formed in the dielectric layers 11.

The wiring boards B1 and B2 are respectively laminated on the main surfaces 20 and 21 of the core substrate A, and the wiring patterns 23 and 23 are respectively formed on the exposed surfaces of the wiring boards B1 and B2. The via holes 24 and 24 are opened in the insulating layers 27 and 27 at positions corresponding to the lead electrodes 17 and 18 formed in the core substrate A, and the connecting conductors 28 and 28 are formed in the via holes 24 and 24. As a result, the wiring patterns 23 and 23 respectively formed on the wiring boards B1 and B2 are connected to each other via the connecting conductors 28, external connecting terminals 32 and 34, lead electrodes 17 and 18, internal conductive patterns 12 and 13 and via holes 22.

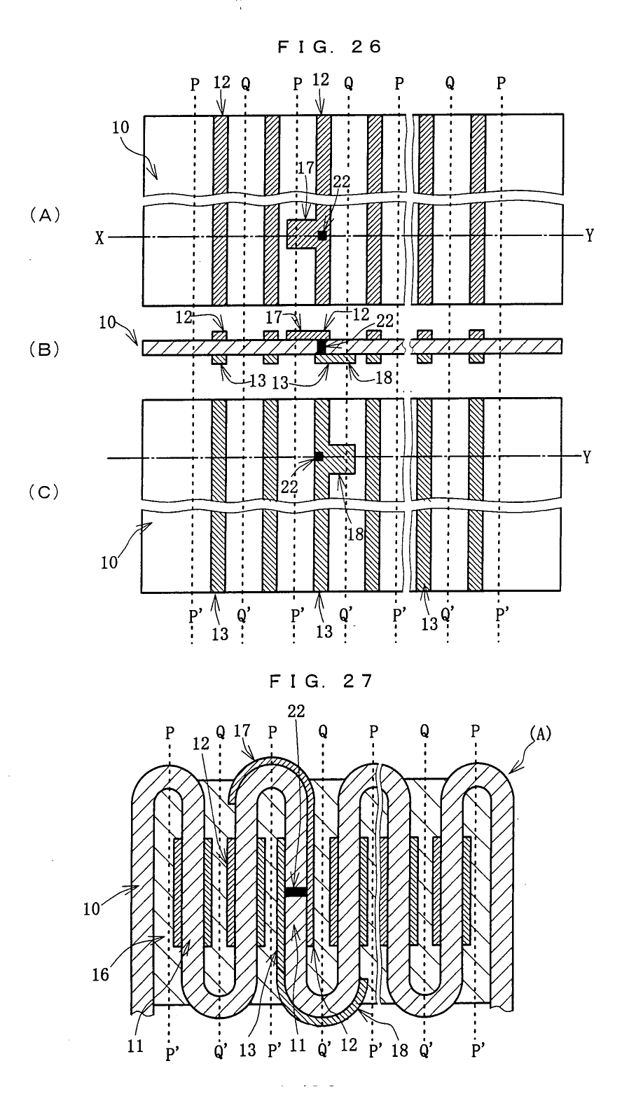

Next, a method of forming the core substrate A shown in FIG. 25 by alternately folding the dielectric sheet 10 is described referring to FIGS. 26A-26C and 27. The method is basically similar to the method shown in FIGS. 23A-23C, however, different in a point that the internal conductive patterns 12 and 13 are connected to each other through the via hole 22 formed in the dielectric sheet 10.

FIGS. 26A, 26B and 26C are respectively a planar view of the dielectric sheet 10 before it is folded, a sectional view thereof in X-Y, and a bottom view thereof. As shown in FIG. 26A, the mountain-side lines P-P′ which forms the mountains and the valley-side lines Q-Q′ which forms valleys in observing from one surface of the dielectric sheet 10 when the dielectric sheet 10 is folded later are virtually set on the rectangular dielectric sheet 10. The mountainside lines P-P′ and the valley-side lines Q-Q′ are set along a direction w3 taken along one side of the dielectric sheet 10. The mountainside lines P-P′ and the valley-side lines Q-Q′ are alternately set in parallel with each other at certain intervals. The direction w3 is a direction that is the same as the planar direction w2 of the multi-layered wiring board 110. Above is a first step.

Next, the internal conductive patterns 12 and 13 are formed on the both surfaces of the dielectric sheet 10. At the time, the internal conductive patterns 12 and 13 are formed in the band shape along the direction w3. Further, the internal conductive patterns 12 and 13 are arranged in surface areas wedged between the adjacent mountainside lines P-P′ and valley-side lines Q-Q′ in parallel with these lines P-P′ and Q-Q′. Further, the internal conductive pattern 12 provided on one of the surfaces of the dielectric sheet 10 and the internal conductive pattern 13 provided on the other surface thereof are arranged so as to face each other interleaving the dielectric sheet between them.

Among the internal conducive patterns 12 and 13, a part of the internal conductive patterns 12 and 13 arbitrarily selected is extended to a position beyond the mountainside line P-P′ or the valley-side line Q-Q′ so as to constitute the lead electrode 17. The mountain-side line P-P′ or the valley-side line Q-Q′ is arranged on the both sides of the internal conductive patterns 12 and 13. One of these lines P-P′ and Q-Q′ is selected, and the internal conductive pattern 12 or 13 is extended to the selected line so that the lead electrode 17 is formed. The line P-P′ or Q-Q′ is selected as follows. The dielectric sheet 10 is alternately folded along the lines P-P′ and Q-Q′ in the post-process as shown in FIG. 27. In the case where the internal conductive pattern 12 or 13 is extended to the line P-P′ or Q-Q′, the extended end thereof may be located within or outside of the dielectric sheet 10.

The line P-P′ or Q-Q′, in which the extended end of the relevant pattern is located outside of the bent dielectric sheet, is selected as the extended side of the internal conductive pattern 12 or 13.

An aramid film having the thickness of 4.5 μm is used as the dielectric sheet 10. After thin copper films are formed in the thickness of 1 μm on the dielectric sheet 10, the internal patterns 12 and 13 are formed on the dielectric sheet 10 with the width of 400-600 μm and at the interval of 1 mm (interval between the mountainside line P-P′ and the valley-side line Q-Q′) by means of the etching process. Above is a second step.

As is clearly shown in FIG. 26B, the via hole 22 is previously formed in the dielectric sheet 10. The via hole 22 is formed at a position where the internal conductive pattern 12 in which the lead electrode 17 is formed and the internal conductive pattern 13 in which the lead electrode 18 is formed face each other. The inter-layer connecting conductor (metal conductors) is filled into the via hole 22. The via hole 22 is formed at a position as close to the lead electrodes 17 and 18 as possible. The lead electrodes 17 and 18 are thereby connected to each other by abutting the via hole 22 (inter-layer connecting conductor).

Next, as shown in FIG. 27, the dielectric sheet 10 is alternately and continuously folded along the mountainside lines P-P′ and the valley-side lines Q-Q′. At the time, the dielectric sheet 10 is folded so that the mountainside lines P-P′ forms the mountain shape and the valley-side lines Q-Q′ form the valley shape in observing from one surface of the dielectric sheet 10. As a result, the structure of the core substrate A comprising the plurality of dielectric layers 11 laminated along the planar direction of the substrate is embodied. The layer ends of the dielectric layers 11 are interconnected at the coupled sections 14 formed when the dielectric sheet 10 is alternately folded. A plurality of coupled sections 14 is provided, and the respective coupled sections 14 are alternately arranged on either of the both ends of the dielectric layers 11. Further, the insulating adhesive layers 16 are filled between the dielectric layers 11 so that the respective dielectric layers 11 are fixedly bonded to one another. As a result, the dielectric layers 11 comprising the sections superposed on one another are formed. Above is a third step. In the case where the insulating adhesive layers 16 are provided so that the dielectric layers 11 are bonded to one another, suitable examples of a material used for the insulating adhesive layer 16 are thermosetting epoxy resin and a composite material including thermosetting epoxy resin in its composition. The dielectric layers 11 can be easily adhered to each other by heating it to approximately 100-200° C.

When the dielectric sheet 10 is folded, the lead electrodes 17 and 18 are located on an outer side of the coupled sections and exposed on the main surfaces 20 and 21 of the core substrate A.

As is clear from FIGS. 26A-26C, the lead electrode 17 is coupled with the internal conductive pattern 12 by the same material formed by integral moulding, while the lead electrode 18 is coupled with the internal conductive pattern 13 by the same material formed by integral moulding. Further, the internal conductive patterns 12 and 13 are connected to each other through the via hole 22, and the lead electrodes 17 and 18 are thereby connected to each other.

Here, the external connecting terminals 32 and 34 are formed on the main surfaces 20 and 21 of the core substrate A. The external connecting terminals 32 and 34 abut the lead electrodes 17 and 18 and are thereby connected thereto. The upper surfaces of the external connecting terminals 32 and 34 are flat surfaces in parallel with the main surfaces 20 and 21.

The foregoing description recites the example in which one via hole 22 is formed in the dielectric layers 11. However, because the internal conductive patterns 12 and 13 are formed in parallel with each other in such a manner that the dielectric layer 11 is thereby sandwiched, the via hole 22 may be formed at any position between them.

Other than the aramid film, thermoplastic fluorocarbon resin, thermosetting epoxy resin or the like, can be used as the dielectric sheet 10 (dielectric layers 11). The folded dielectric layers 11 are bonded to one another by filling the insulating adhesive layers 16 between them, however, the dielectric layers 11 can be directly bonded by pressing to each other without filling the insulating adhesive layers 16. A suitable example of the material used for the dielectric layers 11 (dielectric sheet 10) in this case is thermoplastic polyester or the like.

### Preferred Embodiment 9

The core substrate A used in the multi-layered wiring board according to the present invention is characterized in that, though there is such a restriction that the wirings cannot be freely dragged about because the internal conductive patterns 12 and 13 formed in the core substrate A are extended in the certain directions (direction w2 or perpendicular direction on the paper in the core substrates A shown in FIGS. 22 and 25), the internal conductive patterns 12 and 13 formed in the core substrate A can achieve such a high density in the internal conductive patterns 12 and 13 which could not be obtained in the existing wiring board.

In recent years, a higher integration and a higher speed of the LSI chip and mass storage of a memory chip have been rapidly developed, and a complicated and skilled system can now be controlled by a chip set comprising a plurality of LSI chips. Though the performance of each LSI chip was improved, in a wiring board provided with the plurality of LSI chips, it is in a state where a performance for transmitting a signal having a large capacity at a high speed between the LSI chips has not able to catch up with the improvement.

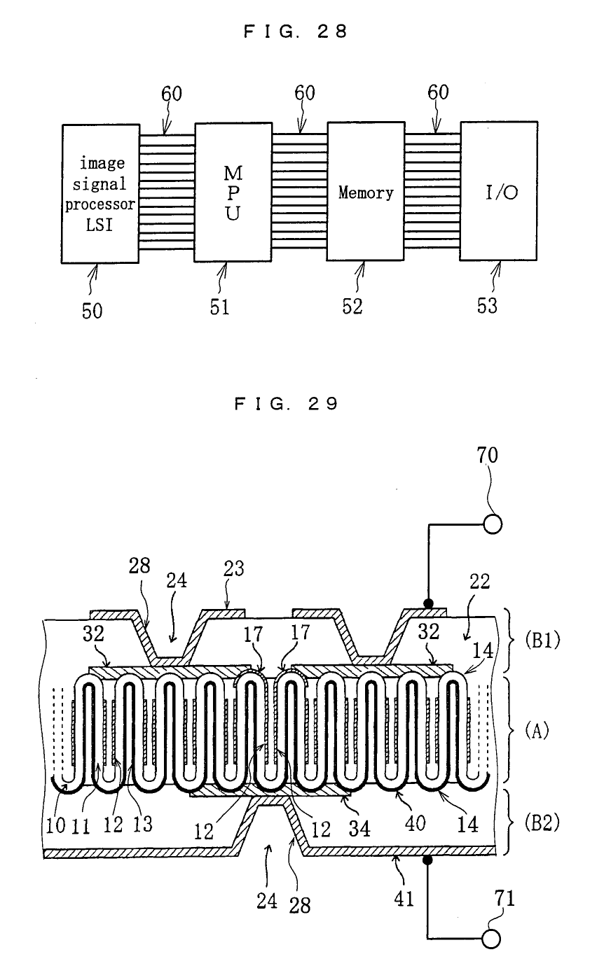

FIG. 28 shows an example of a constitution of an image signal processing system comprising an image signal processing LSI 150, an MPU (microprocessor) 51, a memory 52, and an I/O 53 chip set, wherein the respective chips. Is connected between them with busses 60. In some of the recent image signal processing system having a large capacity, the number of the busses 60 is as many as a few thousands, which will inevitably increase in the future. The core substrate used in the multi-layered wiring board according to the present invention sufficiently satisfies the increasing demand. Though not only a large capacity but also reliability is required in the busses 60, the risk of skew is very low, which is suitable in the expected reliability because the wirings in the core substrate are in parallel with each other and the lengths thereof are aligned.

FIG. 29 shows a constitution of a multi-layered wiring board 100D according to a preferred embodiment 9 of the present invention that satisfies such a demand. As shown in FIG. 29, a plurality of internal conductive patterns 12 and 13 is formed on the both surfaces of the dielectric layers 11 in the core substrate A. Among the plurality of internal conductive patterns formed on one of the surfaces, a particular internal conducive pattern 12 is provided with the lead electrode 17. All of the internal conductive patterns 13 provided on the other surface are extended to the coupled sections 14 on an outer side of the coupling, and connected so as to be coupled to each other at the coupled sections 14. Then, the internal conductive patterns 13 constitute lead electrodes 40 at the sections where they are coupled with each other.

By using the internal conductive patterns 12 as the signal wires (bus lines) and the internal conductive patterns 13 as the ground wires, the internal conductive patterns 12 constituting the signal wires incorporated in the core substrate A are substantially shielded by the internal conductive patterns 13.

Furthermore, the wiring boards B1 and B2 are laminated on the main surfaces 20 and 21 of the core substrate A, and the wiring patterns 23 are formed on the exposed surface of the wiring board B1. The wiring patterns 23 are connected to the lead electrodes 17 formed on the main surface 20 of the core substrate A via the connecting conductors 28 formed in the wiring board B1.

The wiring pitches of the internal conducive patterns 12 are very narrow, and the adjacent lead electrodes 17 and 17 are thereby very close to each other. Therefore, the two connecting conductors 28 cannot be formed separately from each other immediately above the lead electrodes 17. Accordingly, the external connecting terminals 32 and 34 provided in such a manner as drawn from the lead electrodes 17 and 17 in the horizontal direction (planar direction of the core substrate A), are formed on the adjacent lead electrodes 17 and 17. The adjacent lead electrodes 17 and 17 are connected to the separate connecting conductors 28 (wiring patterns 23) via the external connecting terminals 32 and 34.

The wiring patterns 41 is formed on the exposed surface of the other wiring board B2. The wiring patterns 41 are connected to the external connecting terminal 34 (external connecting electrode 26) formed on the other main surface 21 of the core substrate A via the connecting conductor 28 formed in the wiring board B2.

The internal conductive patterns 12 used as the signal wires are connected to the wiring patterns 23 formed on the wiring board B1, and the wiring patterns 23 are connected to a signal terminal 70 of the signal wires. The internal conductive patterns 13 used as the ground wires are connected to the wiring patterns 41 formed on the wiring board B2, and the wiring patterns 41 are connected to a ground terminal 71.

According to the multi-layered wiring board 100D of the present preferred embodiment, the high-density wirings (internal conductive patterns 12) incorporated in the core substrate A are used as the signal wires (bus lines) having a large capacity so that a signal transmittance can be realized at a high speed and with high reliability between the LSI chips mounted on the multi-layered wiring board. Further, any influence from the crosstalk, noises and the like can be reduced because the internal conductive patterns 12 used as the signal wires can be shielded by the internal conductive patterns 13.

In the present preferred embodiment, the internal conductive patterns 13 are used as the ground wires, so as to give effect as the shielding layers, however, it can be used for other purposes such as the power-supply wires. Meanwhile, a pair of internal conductive patterns 17 and 17 can be used as a differential transmission path.

Furthermore, in the multi-layered wiring boards according to the present invention recited in the respective preferred embodiments, the thickness of the dielectric layers 11 constituting the core substrate A is set to a sufficiently small value in comparison to the width dimensions of the external connecting terminals 32 and 34. Further, the intervals between the multi-layered internal conductive patterns 12 and 13 provided on the surfaces of the dielectric layers 11 so as to insulate from each other are set to a sufficiently small value in comparison to the width dimensions of the external connecting terminals 32 and 34. Therefore, the external connecting terminals 32 and 34, where their alignment is overlapped to each other, can be connected with a high area efficiency of the core substrate A. via the internal conducive patterns 12 and 13 densely housed in the core substrate A. In order to increase the mounting density, the shape of the multi-layered wiring board 110 is preferably a rectangular shape having a longer side in the planar direction (longitudinal direction) of the dielectric layers 11 and a shorter side in the thickness direction of the dielectric layers 11. Accordingly, the number of the connection lines where the connection ends of the dielectric layers 11 are located can be increased along the longitudinal direction of the dielectric layers 11, and the number of the wiring patterns to be formed as the connection intermediates on the main surfaces 20 and 21 of the core substrate A can be reduced, which further increases the wiring density.

### Preferred Embodiment 10

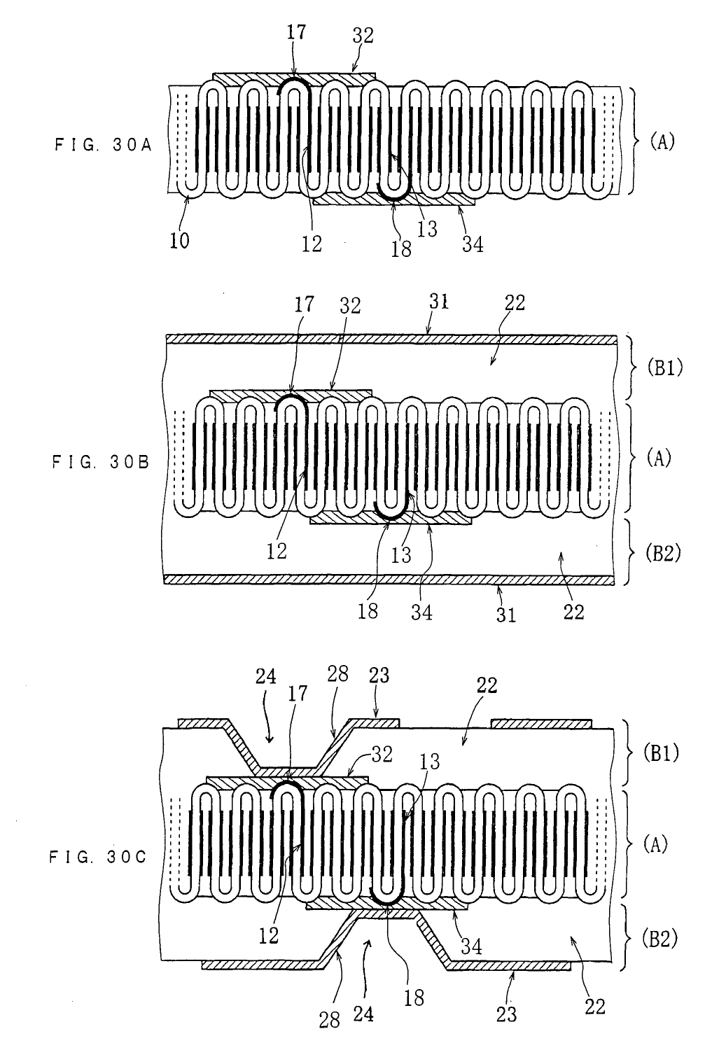

Next, referring to FIGS. 30A, 30B and 30C, description will be given to a method of manufacturing a multi-layered wiring board by respectively laminating the wiring boards B1 and B2 comprising the build-up wiring layers on the main surfaces of the core substrate A manufactured by means of the method described in the preferred embodiment 6.

As shown in FIG. 30A, the external connecting terminals 32 and 34 are formed so as to cover the lead electrodes 17 and 18 exposed on the main surfaces 20 and 21 of the core substrate A manufactured by means of the method according to the preferred embodiment 6. The external connecting terminals 32 and 34 are provided in order to enlarge an effective area of the lead electrodes 17 and 18 so that the connection to the wiring patterns 23 formed on the wiring boards B1 and B2 comprising the build-up wiring layers can be facilitated because the lead electrodes 17 and 18 are formed at such a very small size as approximately 8-10 μm.

Next, as shown in FIG. 30B, the wiring boards B1 and B2 comprising the build-up wiring layers are respectively laminated on the main surfaces 20 and 21 of the core substrate A. Then, the unevenness of the main surfaces 20 and 21 of the core substrate A is reduced by laminating the insulating layers 27, and the surfaces of the insulating layers 27 are flattened.

Then, conductive layers 31 are formed on the surfaces of the insulating layers 27, and the formed conductive layers 31 are etched as shown in FIG. 30C so that the wiring patterns 23 and 23 are formed. The via holes 24 are opened in the insulating layers 27. The via holes 24 are formed at the positions where the external connecting terminals 32 and 34 are formed. Next, the connecting conductors 28 are formed in the formed via holes 24. Thereby, the wiring patterns 23 formed on the build-up wiring layers B1-B2 are connected to the internal conductive patterns 12 and 13 formed in the core substrate A via the lead electrodes 17 and 18.

By the way, in the method of manufacturing the core substrate A described in the preferred embodiment 6, in order to expose the lead electrodes 17 and 18 on the main surfaces 20 and 21 of the core substrate A when the dielectric sheet 10 is folded, the insulating adhesive layers 16 were formed in such a manner that the lead electrodes 17 and 18 are not thereby covered as shown in FIG. 19F. However, in case of considering a series of the steps of forming the multi-layered wiring board by laminating the wiring boards B1 and B2 on the core substrate A after the formation of the core substrate A, a part of the steps can be omitted so that the total process can be simplified.

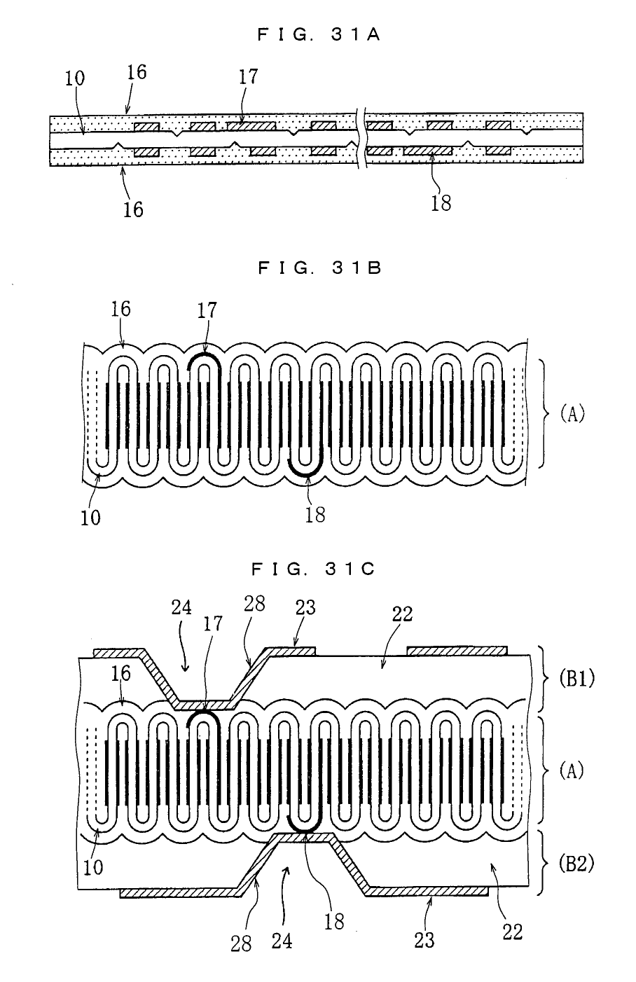

Referring to FIGS. 31A, 31B and 31C, a process of manufacturing the multi-layered wiring board that is simplified under a aforementioned viewpoint is described. In place of the formation of the insulating adhesive layers 16 on the dielectric sheet 10 in such a manner that the lead electrodes 17 and 18 are not thereby covered in the step shown in FIG. 19F, the insulating adhesive layers 16 are formed on the entire surfaces of the dielectric sheet 10 as shown in FIG. 31A.

Next, as shown in FIG. 31B, the dielectric sheet 10 thus formed is folded by mean of the method shown in FIGS. 20A-20C so that the core substrate A is formed. The both main surfaces 20 and 21 of the core substrate A after the sheet is folded are constituted with the insulating adhesive layers 16 because the insulating adhesive layers 16 are formed on an entire area in the both surfaces of the dielectric sheet 10.

As shown in FIG. 31C, the wiring boards B1 and B2 comprising the build-up wiring layers are respectively laminated on the main surfaces 20 and 21 of the core substrate A, and the via holes 24 are formed in the insulating layers 27. At this time, because the insulating layer 27 and the insulating adhesive layer 16 are formed from the same type of material, not only the insulating layer 27 but also the insulating adhesive layer 16 can be opened all at once so that the via hole 24 can be formed. As a result, the lead electrodes 17 and 18 are exposed at the openings of the insulating adhesive layers 16. After the via holes 24 are opened, the connecting conductors 28 are formed in the via holes 24. Thereby, the wiring patterns 23 and 23 formed on the wiring boards B1 and B2 are connected to the internal conductive patterns 12 and 13 of the core substrate A via the lead electrodes 17 and 18.

So far was described the preferred embodiment 9 in which the present invention was applied to the build-up substrate. However, the present invention is not limited to the recited constitution, and various modifications are allowed. For example, in the preferred embodiment 9, the example in which one wiring board B1 and one wiring board B2 are provided on the main surfaces of the core substrate A has been described, however, at least two wiring boards may be provided depending on complexity of the wirings. Further, It is preferable in appoint that the main surfaces 20 and 21 of the core substrate A are flattened in the case where these wiring boards are formed as the build-up wiring layers. However, the effect of the present invention can be still executed when wiring boards formed by means of a different method are laminated on the core substrate.

### Preferred Embodiment 10

In order to respond to narrow-pitch CSP having an area array structure, multilayer of an interposer is absolutely necessary. However, when the layers are increased, points at which wirings formed in the respective layers are connected between them through via holes are accordingly increased, which results in deterioration of the reliability and yield ratio. In addition to the cut-down of the yield ratio, the increase of the layers leads to the increase of the manufacturing steps, which invites the cost increase.

It is effective to increase the wiring density in order to control the increase of the layers. However, it is necessary to interconnect the wirings in the respective layers while avoiding the via holes. In order to do so, it is necessary to reduce a diameter of the via hole when the wiring is connected with high density. However, an accuracy in processing the via holes is lower than an accuracy in processing the wirings, which is a factor interfering the higher wiring density.

Meanwhile, it is technically possible in the LSI chip to narrow pitches of electrode pads to a few-μm order along with the advancement of the semiconductor processing technology, however, the wirings in the conventional interposer are not technically advanced enough to allow the connection to the electrode pads with a pitch of a few-μm order. More specifically, the conventional interposer cannot adapt to the pitch of the LSI chip that have been dramatically reduced, and there is no way except coordinating the pitches of the electrode pads of the LSI chip with the pitches of connecting terminals of the interposer in the current status. Focusing on the problem, an interposer according to a preferred embodiment 10 of the present invention is proposed. The interposer according to the preferred embodiment 10, which is different from the conventional interposer, does not require the formation of such micro-fabricated wiring patterns and can remarkably reduce the connection number of the via holes gone through by the signal wirings. As a result, the wirings can be obtained with a high density and reliability.

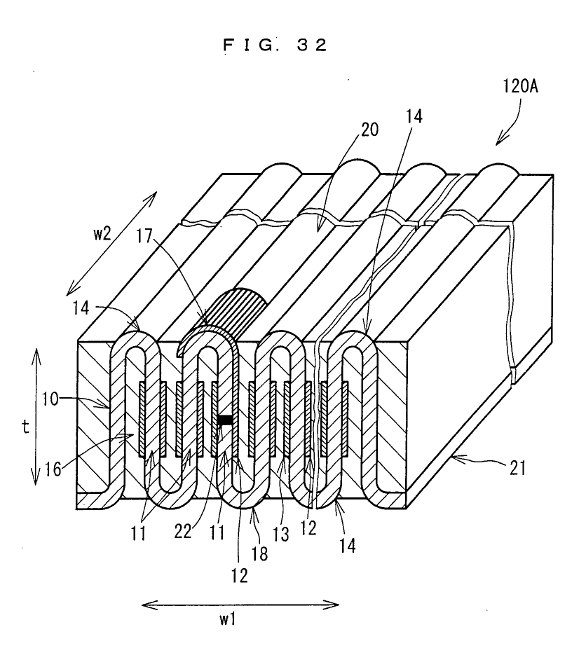

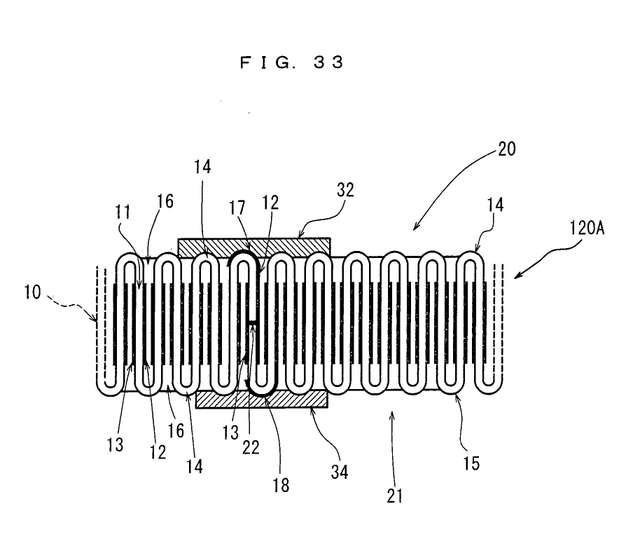

FIGS. 32 and 33 show a constitution of the interposer according to the preferred embodiment 10. FIG. 32 is a perspective view of a main component shown in section, and FIG. 33 is a sectional view of the main component.

An interposer 120A has a substrate structure of a rectangular flat-plate shape. The interposer 120A comprises a plurality of dielectric layers 11. The respective dielectric layers 11 are arranged along a direction t (thickness direction) where main surfaces of the substrate face each other, and laminated along a direction w1 intersecting in orthogonal state with the facing direction t. The orthogonal-intersecting direction W1 refers to a planar direction of the substrate along an arbitrary side of the rectangular interposer 120A. The internal conducive patterns 12 and 13 are provided on surfaces of the dielectric layers 11. The internal conductive patterns 12 and 13 are provided on both surfaces of the dielectric layers 11. The adjacent dielectric layers 11 are interconnected integrally and continuously with each other at layer ends thereof on any of main surfaces 20 and 21 of the interposer.

The coupled ends of the layers constitute coupled sections 14 of the dielectric layers 11. The coupled sections 14 are continuously provided in the dielectric layers 11 in a full width thereof (full substrate width of the interposer 120A), in other words, along a planar direction w2 of the substrate intersecting in orthogonal state to the orthogonal-intersecting direction w1 on the plane of the substrate. The coupled sections 14 are provided at the both ends of the dielectric layers 11. The plurality of coupled sections 14 are alternately provided on any of the main surfaces 20 and 21 of the interposer along the orthogonal-intersecting direction w1. Namely, the coupled section 14 adjacent to the coupled section 14 on the main-surface-20 side is provided on the other main surface 21, and the coupled section 14 adjacent to the coupled section 14 on the other-main-surface-21 side is provided on the main surface 20.

Accordingly, the whole of the plurality of dielectric layers 11, which are folded at the coupled sections 14, constitute a bent dielectric sheet 10, and the folded dielectric sheet 10 has a substrate structure having a rectangular flat-plate shape. The internal conductive patterns 12 and 13 are arranged in a band shape on the dielectric layers 11 constituting the dielectric sheet 10 along a longitudinal direction thereof. The longitudinal direction of the layer refers to a ridge-line direction of the coupled section 14, and more specifically to the planar direction w2 of the substrate.

The respective dielectric layers 11 are bonded to each other by insulating adhesive layers 16 interposed between the layers, and the internal conductive patterns 12 and 13 are coated with the insulating adhesive layers 16. The main surface 20 of the interposer 120A consists of a continuum of the plural coupled sections 14 bonded to each other by the insulating adhesive layers 16. In a similar manner, the other main surface 21 of the interposer 120A consists of a continuum of the plural coupled sections 14 bonded to each other by the insulating adhesive layers 16.

At least one of the plurality of internal conductive patterns 12 and 13 is extended to the coupled section 14 where the surface of the dielectric layer 11 provided with the internal conducive pattern 12 or 13 becomes an outer side of the coupling. Thereby, the extended end of the internal conductive pattern 12 or 13 is exposed on one of the main surfaces 20 and 21 (main surface 20 of the substrate in FIGS. 32 and 33). The internal conductive patterns 12 exposed on the main surface 20 or 21 constitute lead electrodes 17 and 18. The external connecting terminals 32 and 34 having areas larger than those of the lead electrodes 17 and 18 are formed on upper surfaces of the lead electrodes 17 and 18. Upper surfaces of the external connecting terminals 32 and 34 have flat surfaces in parallel with the main surfaces 20 and 21 of the substrate so that a semiconductor device can be mounted on the interposer 120A in a stable manner and the interposer 120A can be mounted on a circuit substrate in a stable manner.

A via hole (inter-layer connecting conductor) 22 is formed previously in the dielectric sheet 10 where the internal conducive patterns 12 and 13 comprising the lead electrodes 17 and 18 is provided both surfaces thereof. The via hole 22 is formed at a position where the internal conductive patterns 12 and 13 face each other. The via hole 22 is filled with an inter-layer connecting conductor (metal conductor). The via hole 22 is provided at a position as close to the lead electrodes 17 and 18 as possible.

Accordingly, the internal conductive pattern 12 having the lead electrode 17 and the internal conductive pattern 13 having with the lead electrode 18 abut the via hole 22 (inter-layer connecting conductor) and thereby connected to each other.

As the interposer 120A has the structure where the internal conducive patterns 12 and 13 formed in the band shape are laminated alternately in the horizontal direction (planar direction of the substrate) interleaving the dielectric layers 11 between them, the wirings can be dragged about at such very small pitches that a thickness of the dielectric layer 11 and a thickness of the internal conductive patterns 12 and 13 are added to each other. Assuming that the thickness of the dielectric layer 11 is 4 μm and the thickness of the internal conductive patterns 12 and 13 is 1 μm, for example, the wirings can be dragged about at such a extremely high density as 4-5 μm. This is a wiring density equivalent to 8-10 wiring layers in comparison to 40 μm-pitch wirings in the most-advanced multi-layered wiring board (for example, build-up multi-layered wiring board).

Further, in the interposer 120A, the internal conductive patterns 12 and 13 are coated with the insulating adhesive layers 16 and incorporated in the interposer 120A. Therefore, the internal conductive patterns 12 and 13 can maintain the narrow-pitch arrangement without any adverse influence from the external connecting terminals 32 and 34 provided on the main surfaces 20 and 21 of the interposer 120A, which realizes the high-density wirings.

In general, the external connecting terminals are provided on the main surfaces of the interposer. The external connecting terminal provided on one of the surfaces is connected to the semiconductor device (LSI chip or the like) and arranged along a periphery of the one surface in accordance with the structure of the semiconductor device. The arrangement of the terminal on the periphery is called the peripheral alignment. The external connecting terminal provided on the other surface is connected to a circuit substrate (mother substrate), and two-dimensionally arranged on the other main surface in an array shape in accordance with the structure of the circuit substrate. The arrangement of the terminals is called the area array alignment. In the interposer, the internal conductive patterns are dragged about so that the external connecting terminal on the main surface (peripheral alignment) is connected to the external connecting terminal on the other main surface (area array alignment). More specifically, the external connecting terminal of the peripheral alignment and the external connecting terminal of the area array alignment are alternately converted in arrangement by the internal conductive pattern in the interposer. In the interposer 120A according to the present invention, the alignment conversion of the external connecting terminals is implemented through a connecting conductor 19 formed in the dielectric layers 11.

In the conventional interposer in which the build-up substrate or the like is used, multi-layered wiring patterns, in which the wiring layers are vertically connected through the via holes for the alignment conversion, are used, and it is necessary to provide a land having a diameter larger than that of the via hole in the wiring layers in a part where the via hole is provided. Therefore, in the conventional interposer, it is difficult to form the narrow-pitch wiring patterns due to hindrance of the land.

In the interposer 120A according to the preferred embodiment 10, the internal conductive patterns 12 and 13 are incorporated in the interposer 120A. Therefore, the wiring patterns having such very small pitches can be formed free of interference from the wirings or lands provided on the main surfaces 20 and 21 of the interposer 120. Further, rewiring patterns and the connection lands formed on the main surfaces 20 and 21 of the interposer 120A can be arbitrarily provided without the intervention of the internal conductive patterns 12 and 13. The wiring patterns provided on the main surfaces 20 and 21 of the substrate can function as the wiring patterns that connect the lead electrodes 17 and 18, and the external connecting terminals 32 and 34 to each other. In the interposer 120A where the wiring patterns capable of exerting such a function can be provided at any arbitrary position on the main surfaces 20 and 21 of the substrate, the external connecting terminals 32 and 34 can be provided at any arbitrary position on the main surfaces 20 and 21.

As described above, the interposer 120A can house such narrow-pitch wirings with high density, and can realize such a structure that the housed high-density wirings and the LSI chip comprising the narrow-pitched electrode pads can be connected to each other.

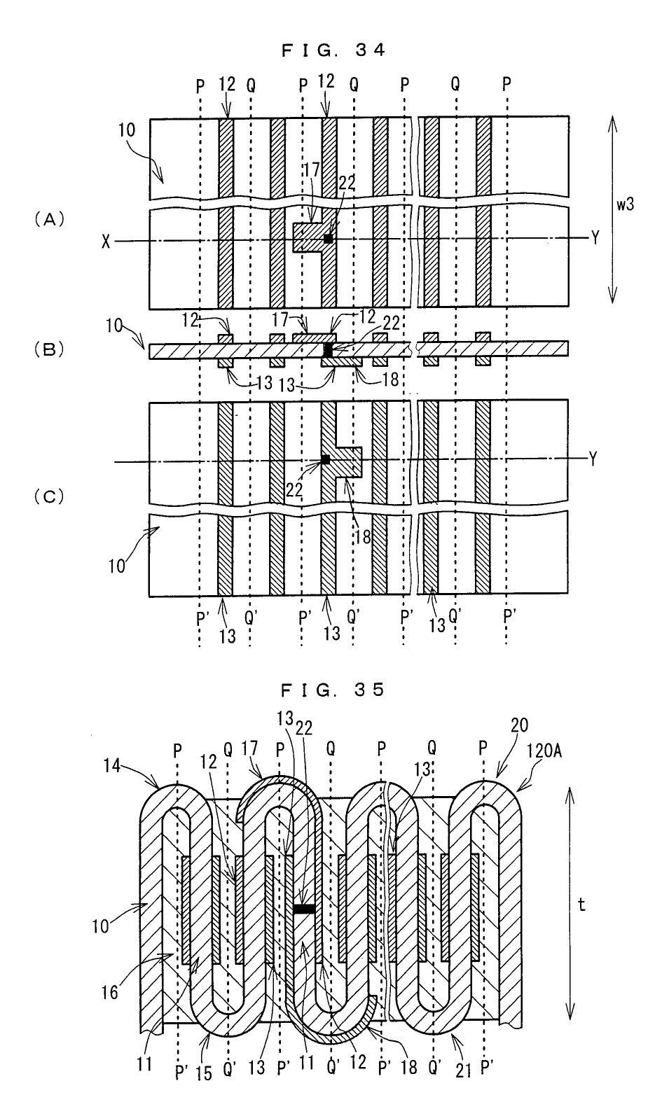

Next, a method of manufacturing the interposer 120A according to the preferred embodiment 10 is described referring to FIGS. 34A, 34B, 34C and 35.

FIGS. 34A, 34B and 34C show a planar view of the dielectric sheet 10 before it is folded, a sectional view thereof in X-Y, and a bottom view thereof respectively. As shown in FIG. 34A, the mountain-side lines P-P′ that form mountains and valley-side lines Q-Q′ that form valleys in observing from one surface of the dielectric sheet 10 when the dielectric sheet 10 is folded later are virtually set on the rectangular dielectric sheet 10. The mountainside lines P-P′ and the valley-side lines Q-Q′ are set along a direction w3 taken along one side of the dielectric sheet 10. The mountainside lines P-P′ and the valley-side lines Q-Q′ are alternately set in parallel with each other at certain intervals. The direction w3 is a direction that is the same as the planar direction w2 of the interposer 120A. Above is a first step.

Next, the internal conductive patterns 12 and 13 are formed on the both surfaces of the dielectric sheet 10. At the time, the internal conductive patterns 12 and 13 are formed in the band shape along the direction w3. Further, the internal conductive patterns 12 and 13 are arranged in surface areas sandwiched between the adjacent mountainside lines P-P′ and valley-side lines Q-Q′ in parallel with these lines P-P′ and Q-Q′. Further, the internal conductive pattern 12 provided on one of the surfaces of the dielectric sheet 10 and the internal conductive pattern 13 provided on the other surface thereof are arranged so as to face each other interleaving the dielectric sheet between them.

Among the internal conducive patterns 12 and 13, a part of the internal conductive patterns 12 and 13 arbitrarily selected is extended to positions beyond the mountain-side line P-P′ or the valley-side line Q-Q′ so as to constitute the lead electrodes 17 and 18. The mountainside line P-P′ or the valley-side line Q-Q′ is arranged on the both sides of the internal conductive patterns 12 and 13. One of these lines P-P′ and Q-Q′ is selected, and the internal conductive patterns 12 and 13 are extended to the selected lines so that the lead electrodes 17 and 18 are formed. The line P-P′ or Q-Q′ is selected as follows. The dielectric sheet 10 is alternately folded along the lines P-P′ and Q-Q′ in the post-process as shown in FIG. 35. In the case where the internal conductive patterns 12 and 13 are extended to the line P-P′ or Q-Q′, the extended end thereof may be placed within or outside of the dielectric sheet 10 in a bent state. The line P-P′ or Q-Q′, in which the extended end of the relevant pattern is located outside of the bent dielectric sheet 10, is selected as the extended side of the internal conductive patterns 12 and 13.

An aramid film having the thickness of 4.5 μm is used as the dielectric sheet 10. After thin copper films are formed in the thickness of 1 μm on the dielectric sheet 10, the internal patterns 12 and 13 are formed with the width of 500 μm and at the intervals of 1 mm (interval between the mountain-side line P-P′ and the valley-side line Q-Q′). Above is a second step.

As shown in FIG. 34B, a via hole 22 is previously formed in the dielectric sheet 10. The via hole 22 is formed at a position where the internal conductive pattern where the lead electrode 17 is formed and the internal conductive pattern 13 where the lead electrode 18 is formed, face each other. The via hole 22 is filled with an inter-layer connecting conductor (metal conductor). The via hole 22 is arranged at a position as close to the lead electrodes 17 and 18 as possible. As a result, the lead electrodes 17 and 18 abut the via hole 22 (inter-layer connecting conductor) and thereby connected to each other.

Next, as shown in FIG. 35, the dielectric sheet 10 is alternately and continuously folded along the mountainside lines P-P′ and the valley-side lines Q-Q′. At the time, the dielectric sheet 10 is folded so that the mountainside line P-P′ forms the mountain shape and the valley-side line Q-Q′ forms the valley shape in observing from one surface of the dielectric sheet 10. Thereby, the structure of the interposer 120A comprising the plurality of dielectric layers 11 laminated along the planar direction of the substrate is embodied. The layer ends of the dielectric layers 11 are coupled at the coupled sections 14 formed when the dielectric sheet 10 is alternately folded. A plurality of coupled sections 14 is provided and the respective coupled sections 14 are alternately arranged on one of the both ends of the dielectric layers 11. Further, the insulating adhesive layers 16 are filled between the dielectric layers 11 so that the respective dielectric layers 11 are fixedly bonded to each other. As a result, the plurality of dielectric layers 11 comprising sections superposed on one another is formed. Above is a third step. In the case where the insulating adhesive layers 16 are provided so that the dielectric layers 11 are bonded to each other, suitable examples of a material used for the insulating adhesive layer 16 are thermosetting epoxy resin and a composite material including thermosetting epoxy resin in its composition. The dielectric layers 11 can be easily adhered to each other by heating to approximately 100-200° C.

When the dielectric sheet 10 is folded, the lead electrodes 17 and 18 are located on the outer side of the coupled sections 14 and exposed on the main surfaces 20 and 21 of the wiring board 100B.

As is clear from FIG. 35, the lead electrode 17 is coupled with the internal conductive pattern 12 by the same material integrally formed, while the lead electrode 18 is coupled with the internal conductive pattern 13 by the same material integrally formed. The internal conductive patterns 12 and 13 are connected to each other through the via hole 22. Accordingly, the lead electrodes 17 and 18 are connected to each other.

As shown in FIG. 33, external connecting terminals 32 and 34 are formed on the main surfaces 20 and 21 of the interposer 120A. The external connecting terminals 32 and 34 respectively abut and are thereby connected to the lead electrodes 17 and 18. Upper surfaces of the external connecting terminals 32 and 34 have flat surfaces in parallel with the main surfaces 20 and 21.

In the foregoing example, the number of the via hole 22 formed in the dielectric layers 11 is one. Because the internal conductive patterns 12 and 13 are formed in parallel with each other in such a manner that the dielectric layer 11 is thereby sandwiched, the via hole 22 can be formed at any section between them.

Other than the aramid film, thermoplastic fluorocarbon resin, thermosetting epoxy resin or the like, can be used as the dielectric sheet 10 (dielectric layers 11). The folded dielectric layers 11 are bonded to each other by filling the insulating adhesive layers 16 between them, however, the dielectric layers 11 can be directly bonded by pressure to each other without filling the insulating adhesive layers 16. A suitable example of the material used for the dielectric layers 11 (dielectric sheet 10) in that case is, for example, thermoplastic polyeseter or the like.

### Preferred Embodiment 11

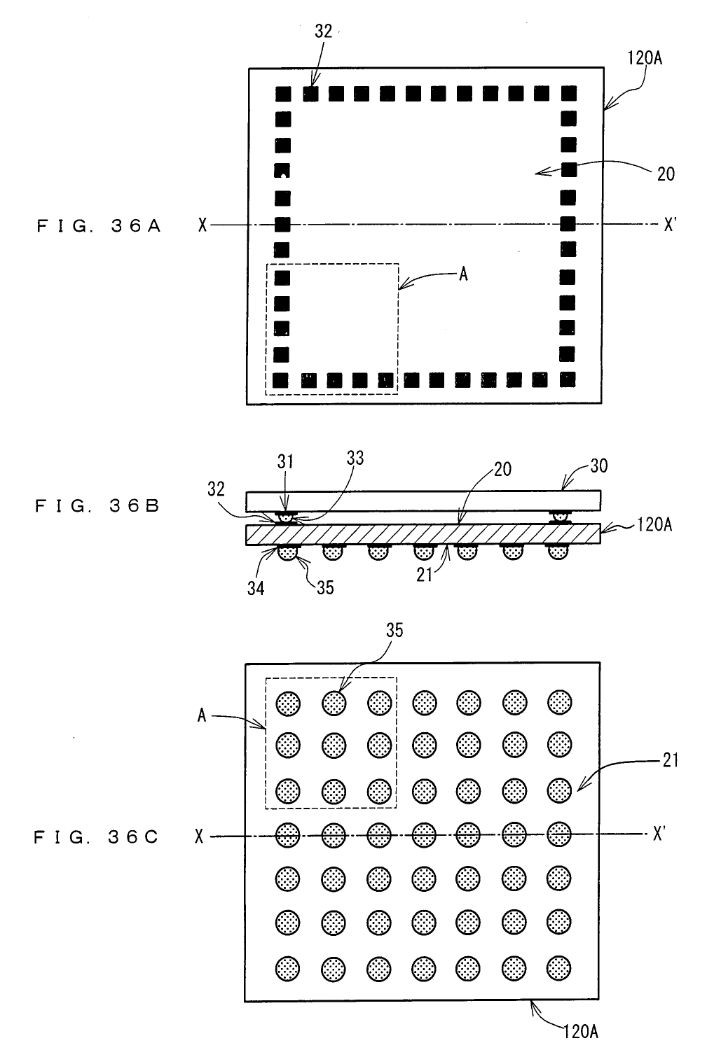

Next, a preferred embodiment 11 of the present invention where the interposer 120A is adapted to the CSP mounting in the LSI chip is described referring to FIGS. 36A-36C. FIG. 36A is an upper view of the interposer 120A. FIG. 36B is a sectional view showing a state where an LSI chip 30 is mounted on the interposer 120A. FIG. 36C is a bottom view of the interposer 120A.

As shown in FIG. 36A, the external connecting terminals 32 (terminal connected to the electrode pads of the LSI chip 30) are formed at a certain interval on the main surface 20 of the interposer 120A along a periphery thereof. The external connecting terminals 32 are provided in response to the LSI chip 30. The electrode pads 31 An arranged on the mounting surface of the LSI chip 30 along a periphery thereof (peripheral alignment). The external connecting terminals 32 are placed in manner similar to the placement of the electrode pads 31 (peripheral alignment).

The LSI chip 30 is mounted on the one main surface 20 of the interposer 120A as shown in FIG. 36B. Further, the LSI chip 30 is face-down mounted to the external connecting terminals 32 by means of the flip-chip method via metal bumps 33 formed on the electrode pads 31.

As shown in FIG. 36C, the external connecting terminals 34 are two-dimensionally arranged on the other main surface 21 of the interposer 120A in an array shape, and thereby the interposer 120A has such a CSP structure that the external connecting terminals 34 are arranged in the area-array shape. In order to facilitate the connection when the interposer 120A is mounted on the print wiring board, solder balls 35 are formed on the external connecting terminals 34.

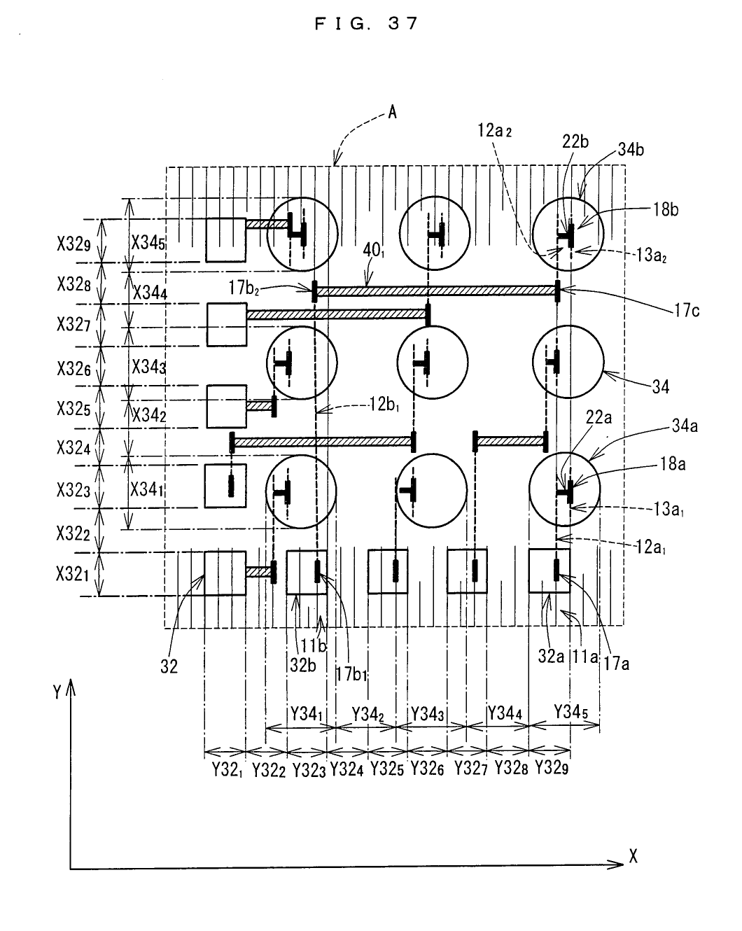

The external connecting terminals 32 arranged on the main surface 20 of the interposer 120A along the periphery thereof are connected to the external connecting terminals 32 arranged on the other main surface 21 of the interposer 120A in the area-array shape. The terminal alignment conversion structure at the time is described referring to FIG. 37.

FIG. 37 is an enlarged sectional view schematically illustrating a region A of the interposer 120A shown in FIGS. 36A-36C. In FIG. 37, the dielectric layers 11 are arranged in parallel with one another along a certain direction (vertical direction on the paper), and the internal conductive patterns 12 and 13 provided on the surfaces of the dielectric layers 11 so as to be inner-packaged in the interposer 120A are also formed in parallel with each other in a similar manner along the certain direction (vertical direction on the paper). Because the internal conductive patterns 12 and 13 are actually formed at such narrow pitches as 4-5 μm, intervals between them are much smaller than those of the pitches schematically shown in FIG. 37.

The external connecting terminal 32 on the main-surface-20 side and the external connecting terminal 34 on the main-surface-21 side are connected to each other via the internal conductive patterns 12 and 13. More specifically:
The internal conductive patterns 12 and 13 provided on the both surfaces of an arbitrary dielectric layer 11 are connected by the inter-layer connecting conductor (via hole 22) formed in the dielectric layers 11;
The lead electrodes 17 and 18 connected continuously to the internal conductive patterns 12 and 13 are drawn to the main surfaces 20 and 21 of the interposer 120A; and
The lead electrodes 17 and 18 are connected to the external connecting terminals 32 and 34.
   By providing the above constitution, the external connecting terminals 32 and 34 are connected to each other.

When the external connecting terminal 32 according to the peripheral alignment and the other external connecting terminal 34 according to the area-array alignment are responded to each other, the terminals to be combined to each other may not be necessarily arranged so as to face each other interleaving the interposer 120A between them, and some pairs of the terminals may be at positions distant from each other. However, in the structure of the interposer 120A, the wiring patterns can be formed without any restriction on the main surfaces 20 and 21. Therefore, the rewiring patterns are extended until the positions of the external connecting terminals 32 and 34 so that any predetermined connection is realized.

A specific connecting method is described below referring to FIG. 37. In FIG. 37 and the following description, in order to discriminate any particular one among the respective dielectric layers 11, lead electrodes 17 and 18, via hole 22 and external connecting terminals 32 and 34, additional characters, a, b, c . . . , are attached to the reference symbols 11, 32, 34, 17 and 18 of the identified components. In FIG. 37, the direction where the dielectric layers 11 are arranged is defined as Y direction, while the thickness direction of the dielectric layers 11 is defined as X direction. The external connecting terminals 32 are arranged according to the peripheral alignment (one-row alignment) along the periphery of the interposer 120A. The external connecting terminals 34 are provided according to the area-array alignment along the X and Y directions respectively. FIG. 37 is a sectional view schematically illustrating an internal structure of the wiring board 100A, wherein the external connecting terminals 32 and 34 not shown originally in FIG. 37 since they are provided on the main surfaces 20 and 21 of the substrate are shown by solid lines.

It is assumed here that the interposer 120A is divided into band regions along the Y direction. In that case, the band regions where the external connecting terminals 32 are arranged and the regions located between the band regions and the adjacent external connecting terminals 32 are referred to as layout band regions Y32₁, Y32₂, . . . , Y32₈, Y32₉ sequentially from the left in the drawing. In the layout band regions Y32₁, Y32₂, . . . , Y32₈, Y32₉, the layout band regions Y32₁, Y32₃, Y32₅, Y32₇, and Y32₉, whose subscripts are odd numbers, denote the regions where the external connecting terminals 32 are arranged, and the layout band regions Y32₂, Y32₄, Y32₆, and Y32₈, whose subscripts are even numbers, denote the regions located between the adjacent external connecting terminals 32.

The region A shown in FIG. 37 is located at a corner periphery of the interposer 120A. Therefore, the plurality of external connecting terminals 32 arranged in a line in the Y direction are located in the layout band region Y32₁ closest to the corner among the layout band regions Y32₁, Y32₃, Y32₅, Y32₇, Y32₉, while the two external connecting terminals 32 (only one is shown in the drawing) are arranged in the respective other layout band regions Y32₃, Y32₅, Y32₇ and Y32₉.

In a similar manner, the band regions where the external connecting terminals 34 are arranged along the Y direction and the regions between the adjacent external connecting terminals 34 are referred to as band regions Y34₁, Y34₂, . . . Y34₅. sequentially from the left in the drawing, In the layout band regions Y34₁, Y34₂, . . . Y34₅, the layout band regions Y32₁, Y32₃ and Y32₅, whose subscripts are the odd numbers, denote the regions where the external connecting terminals 34 are arranged, and the layout band regions Y34₂ and Y34₄, whose subscripts are the even numbers, denote the regions located between the adjacent external connecting terminals 34. The plurality of external connecting terminals arranged in line 34 are located In the layout band regions Y34₁, Y34₃ and Y34₅.

Assuming that the interposer 120A is divided into the band regions along the X direction, the band regions where the external connecting terminals 32 are arranged, and the regions between the adjacent external connecting terminals 32 are referred to as Y32₁, Y32₂, . . . Y32₈, and Y32₉ sequentially from the left in the drawing. In these layout band regions Y32₁, Y32₂, . . . Y32₈, and Y32₉, the layout band regions provided with the odd-number subscripts, Y32₁, Y32₃, . . . , and Y32₉, indicate the layout band regions where the external connecting terminals 32 are arranged, while the layout band regions provided with the even-number subscripts, Y32₂, Y32₄, Y32₆, and Y32₈, indicate the regions between the adjacent external connecting terminals 32.

The region A shown in FIG. 37 is located in the corner periphery of the interposer 120A. Therefore, the plurality of external connecting terminals 32 arranged in line along the X direction are located in the layout band region Y32₁ closest to the corner among the layout band regions Y32₁, Y32₃, Y32₅, Y32₇, and Y32₉, and the external connecting terminals 32 is located one by one in the other layout band regions Y32₃, Y32₅, Y32₇, and Y32₉.

In a similar manner, the band regions where the external connecting terminals 34 are arranged along the X direction and the regions between the adjacent external connecting terminals 34 are referred to as band regions Y34₁, Y34₂, . . . Y34₅. sequentially from the left in the drawing, In the layout band regions Y34₁, Y34₂, . . . Y34₅, the layout band regions Y34₁, Y34₃ and Y34₅, whose subscripts are the odd numbers, denote the region where the external connecting terminals 34 are arranged, and the layout band regions Y34₂ and Y34₄, whose subscripts are the even numbers, denote the regions between the adjacent external connecting terminals 34. The plurality of external connecting terminals 34 arranged in line are located in the layout band regions Y34₁, Y34₃ and Y34₅.

Based on the assumption with respect to the region setting described above, the structure where the external connecting terminals 32 and the external connecting terminals 34 are connected is explained. First, the connection structure of the external connecting terminals Y32ₐ and Y34ₐ is described. The terminals Y32ₐ and Y34ₐ are arranged closely and adjacently to each other without the intervention of the other terminals 32 and 34 between them. Further, the terminals Y32ₐ and Y34ₐ are arranged so as to face each other in the Y direction (direction in parallel with the surfaces of the dielectric layers 11), and abut the same dielectric layer 11a. Therefore, the terminals Y32ₐ and Y34ₐ are connected to each other as follows. The connection setting described below is implemented when the internal conductive patterns and the via holes are pattern-designed.

First, as the internal conductive patterns for connecting the terminals Y32ₐ and Y34ₐ, the internal conducive patterns 12a and 13a provided on the both surfaces of the dielectric layer 11a abutted by the terminals Y32ₐ and Y34ₐ are selected.

Next, pattern lengths of patterns regions 12a₁ and 13a₁ used for the connection of the terminals 32a and 34a are set as follows in the selected internal conductive pattern 12a. The pattern region 12a₁ is set to such a pattern length that the layout band region X32₁ where the external connecting terminal 32a is located and the band region X34₁ where the external connecting terminals 34a is located are pattern ends. The pattern region 13a, is set to such a pattern length that covers the band region X34₁ where the external connecting terminal 34a is located and does not cause any problem in the connection with respect to the via hole 22.

When the internal conductive patterns 12a and 13a are used for the connection of the external connecting terminals 32 and 34 other than the external connecting terminals 32a and 34a, the patterns regions 12a₁ and 13a₁ are separated from the other pattern regions of the internal conductive patterns 12a and 13a. However, in the case where the internal conductive patterns 12a and 13a are not used for the connection of the other external connecting terminals, it is not necessary for the patterns regions 12a₁ and 13a₁ to be separated from the other pattern regions. Additionally, such pattern design is only an example of the pattern design for connecting the external connecting terminals 32a and 34a, and any pattern may be adopted as far as the external connecting terminals 32a and 34a can be connected.

The lead electrode 17a extended from the pattern region 12a₁ is arranged in the band region X32₁ and made to abut the external connecting terminal 32a so that the external connecting terminal 32a and the lead electrode 17a (pattern region 12a₁) are connected to each other. Similarly, the lead electrode 18a extended from the pattern region 13a₁ is made to abut the external connecting terminal 34a so that the external connecting terminal 34a and the lead electrode 18a (pattern region 13a₁) are connected to each other. Because the pattern region 13a₁ is selectively provided in the band region X34₁, the lead electrode 18a abuts the external connecting terminal 34a even in the case where it is provided at any position of the pattern region 13a₁.

The via hole 22a is provided in the layer region of the dielectric layer 11a (layout band region X34₁) where the pattern regions 12a₁ and 13a₁ face each other, and the via hole 22a is made to abut the pattern regions 12a₁ and 13a₁ so that the pattern regions 12a₁ and 13a₁ are connected to each other. By taking the foregoing constitution, the external connecting terminals 32a and 34a are connected to each other via the pattern regions 12a₁ and 13a₁ and the via hole 22a.

In the foregoing example, the external connecting terminals 32 and 34 are close to each other. Further, the terminals 32 and 34, that are distant from each other and arranged at positions where they do not abut the same dielectric layer 11 because the other terminals 32 and 34 are intervened between them, are also connected to each other. The connecting structure in that case is described referring to FIG. 37 that shows the example where the external connecting terminals 32b and 35b are connected to each other.

In this case, the terminals 32b and 34b are connected to each other via the rewiring patterns 40 intervened between the terminals. The rewiring patterns 40 are formed on any of the main surfaces 20 and 21 of the interposer 120A. The rewiring patterns 40 are provided on the main surface 20 or 21 of the substrate around the band region where the external connecting terminals 32b and 34 are placed. As well, in FIG. 37 showing the sectional view, the rewiring patterns 40, that are not originally emerged, are shown by solid lines.

In the following explanation, the example is described wherein the rewiring patterns 40 are provided on the main surface 20 of the substrate where the external connecting terminals 32 are formed, however, the rewiring patterns 40 can be provided on the main surface 21 of the substrate basically in a similar manner. Further, it is needless to say that each of the plurality of rewiring patterns 40 can be provided in a divided way on the main surfaces 20 or 21 of the substrate. Below is described the connecting structure.

First, the internal conductive patterns 12b, 12a and 13a are selected as the internal conductive patterns for connecting the terminals 32b and 34b. The internal conductive pattern 12b is located on one of the surfaces of the dielectric layer 11b abutted by the terminal 32b. The internal conductive patterns 12a and 13a are located on the both surfaces of the dielectric layer 11a abutted by the terminal 34b. In this case, the dielectric layer 11a provided with the selected internal conductive patterns 12a and 13a is the same as the dielectric layer 11a selected for the connection of the terminals 32b and 34b because the dielectric layer 11a abuts the terminals 32b and 34b.

In the selected internal conductive patterns 12b, 12a and 13b, pattern lengths of the pattern regions 12b₁, 12a₂ and 13b₂ used for the connection of the terminals 34a and 34a are set as follows.

The pattern region 12b, is set to such a pattern length that the layout band region X32₁ and X32₈ become pattern ends. The layout band region X32₁ is selected based on a reason because it is the layout band region where the external connecting terminal 32b is arranged. The layout band region X32₈ is selected based on a reason because it is an arbitrary region between the layout band region X32₁ of the external connecting terminal 32b and the layout band region X32₉ of the external connecting terminal 34b and does not interfere with the connection between the other pattern regions.

The pattern region 12a₂ is set to such a pattern length that the layout band region X32₈ and X34₅ are made pattern ends. The layout band region X32₈ is selected based on a reason because it is the layout band region where an end of the pattern region 12b₁ is located. The layout band region X34₅ is selected based on a reason because it is the layout band region where the external connecting terminal 34b is located.

The pattern region 13a₂ is set to such a pattern length that covers the band region X34₅ where the external connecting terminal 34b is located and does not cause any problem in the connection with respect to the via holes 22.

In addition, the internal conductive pattern 12a provided with the pattern region 12a₂ and the internal conducive pattern 13a provided with the pattern region 13a₂ are also used for the other connections such as the connection between the external connecting terminals 32a and 34a other than the connection between the external connecting terminals 32b and 34b. Therefore, the pattern regions 12a₂ and 13a₂ are separated from the other pattern regions of the internal conductive patterns 12a and 13a.

The rewiring pattern 40₁ is formed on any of the main surfaces 20 and 21 of the substrate (main surface 20 of the substrate in the present preferred embodiment). The rewiring pattern 40₁ is arranged in the layout band region where one ends of the pattern regions 12b₁ and 12a₂ are located. In the constitution shown in FIG. 37, the wiring pattern 40 is provided in the layout band region X32₈, and formed along the region. The wiring pattern 40₁ is provided from the dielectric layer 11b through the dielectric layer 11a.

The lead electrodes 17b₁ and 17b₂ are extended from the both ends of the pattern region 12b₁. The one lead electrode 17b₁ abuts the external connecting terminal 32b, and the external connecting terminal 32b and the lead electrode 17b₁ (pattern region 12b₁) are thereby connected to each other. The other lead electrode 17b₂ abuts the rewiring pattern 40₁, and the external connecting terminal 32b and the rewiring pattern 40₁ are thereby connected to each other.

The lead electrode 17c is extended from one end of the pattern region 12a₂ on the band-region-X32₈ side. The lead electrode 17c abuts the rewiring pattern 40₁, and the rewiring pattern 40₁ and the lead electrode 17c (pattern region 12a₂) are thereby connected to each other.

The lead electrode 18b extended from the pattern region 13a₂ abuts the external connecting terminal 34b, and the external connecting terminal 34b and the lead electrode 18b (pattern region 13a₂) are thereby connected to each other. Because the pattern region 13a₂ is selectively provided in the layout band region X34₅, the lead electrode 18b abuts the external connecting terminal 34b even in the case where it is provided at any position of the pattern region 13a₂.

The via hole 22b is provided in the layer region (layout band region X34₅) of the dielectric layer 11a where the pattern region 12a₂ and the pattern region 13a₂ face each other so that the via hole 22b abuts the pattern regions 12a₂ and 13a₂. The pattern regions 12a₂ and 13a₂ are thereby connected to each other. According to the foregoing constitution, the external connecting terminals 32b and 34b are connected to each other via the pattern region 12b₁, rewiring pattern 40₁, pattern region 12a₂, via hole 22b, and pattern region 13a₂.

The structure where the external connecting terminals 32 and 34 are connected was described above based on the connection structures between the external connecting terminals 32a and 34b, and 32b and 34b. It is needless to say that the other terminals are connected according to a similar connecting structure.

### Preferred Embodiment 12

The interposer according to the present preferred embodiment is suitable for a small-sized package with a high density such as CSP. However, a possible disadvantage is that the external connecting terminals of the CSP, even though they are provided at narrow pitches, may not be consistent with the external connecting terminals at wide pitches prepared on the printed board side when the CSP is mounted on the printed board together with other components. Further, some of the LSI chips 30 have the area-array electrode pads obtained by rewiring the LSI bare chip itself in place of obtaining the area-array external connecting terminals by mounting the LSI chip 30 on the interposer. In this case, another interposer for connecting the narrow-pitch external connecting terminals on the CSP side or the narrow-pitch electrode pad on the LSI-bare-chip side to the wide-pitch connecting terminals on the printed board side (hereinafter, referred to as extension interposer) is becomes necessary in addition.

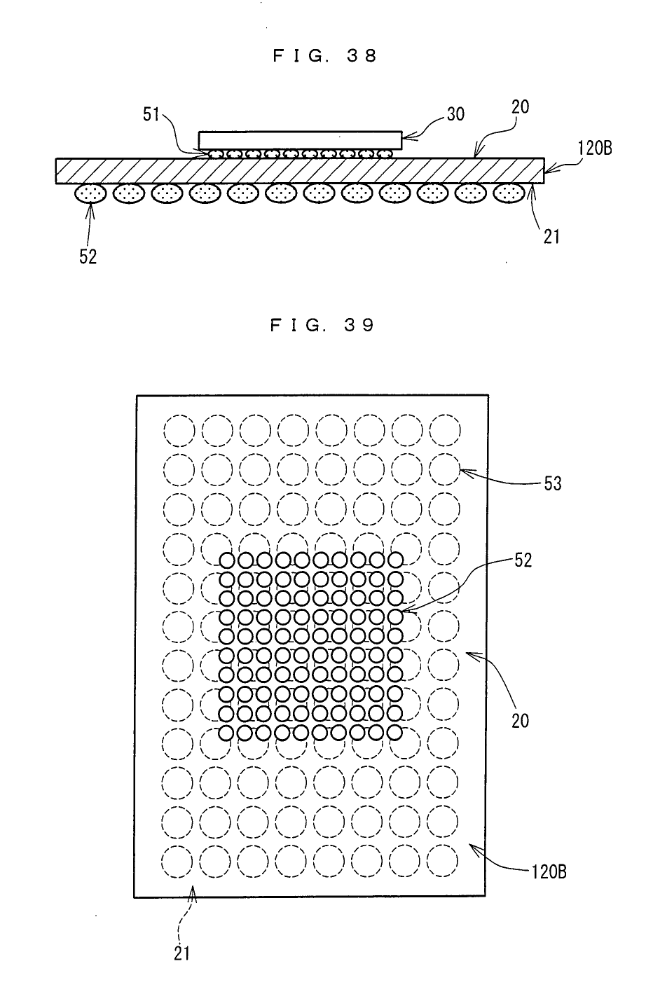

The interposer according to the present invention is suitably adopted as the extension interposer. Hereinafter, a preferred embodiment 12 of the present invention, in which the present invention is applied to the extension interposer, is described referring to FIGS. 38-41.

FIG. 38 is a sectional view illustrating an extension interposer 120B schematically according to the preferred embodiment 12. FIG. 39 is a plan view thereof. As shown in FIG. 38, the LSI chip 30 comprising the area-array electrode pad (not shown) is mounted on the extension interposer 120B. Further, as shown in FIG. 38 and FIG. 39, external connecting terminals 51 for receiving the electrode pads of the LSI chip 30 are formed on a main surface 20 of the extension interposer 120B, while external connecting terminals 52, in which the array of the external connecting terminals 51 are extended, are formed on another main surface 21 of the extension interposer 120B. The external connecting terminals 52 are extended in compliance with the pitches of the connecting terminals prepared on the printed board.

In addition, the example is shown here wherein the LSI chip 30 comprising the area-array electrode pads is mounted on the interposer 120B c. It is possible that CSP, wherein the LSI chip 30 having the peripheral-arrayed electrode pads as shown in FIGS. 36A-36C is mounted on the interposer 110 so as to include the area-array connecting terminals, is mounted on the extension interposer 120B.

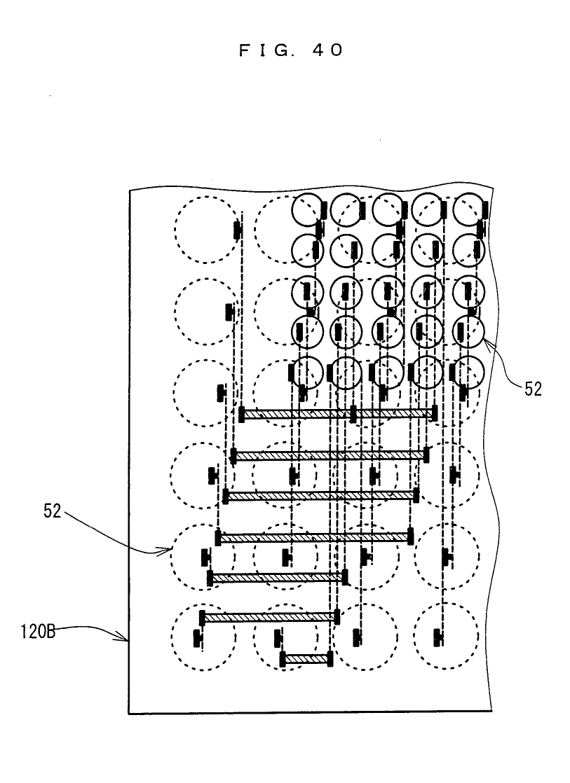

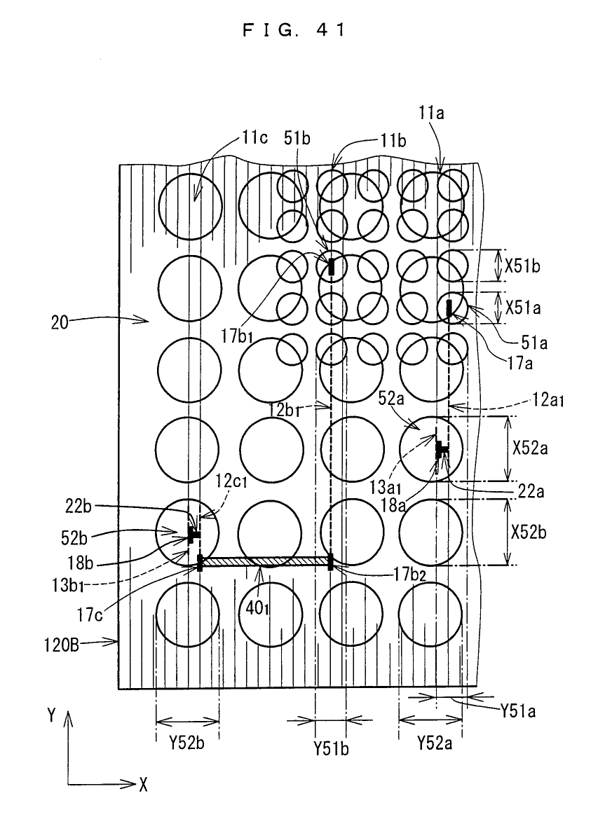

Next, the connection structure is described wherein the external connecting terminals 51 and 52 are formed respectively on the main surfaces 20 and 21 of the extension interposer 120B referring to FIGS. 40 and 41.

FIG. 40 is an enlarged view of a lower-left region divided into four regions in the extension interposer 120B shown in FIG. 39. In the extension interposer 120B, the dielectric layers 11 are laminated along a certain direction (horizontal direction in the drawing), and the internal conductive patterns 12 and 13 are provided on the both surfaces of the dielectric layers 11 though the reference symbols of these components are omitted in FIG. 40. The external connecting terminals 51 and 52 are connected to each other according to a predetermined connecting structure (connecting structure described in the preferred embodiment 11 referring to FIG. 37) via the internal conductive patterns 12 and 13 selected from the aforementioned internal conductive patterns 12 and 13, lead electrode 17 and rewiring patterns 40.

A specific example of the connecting structure is described referring to FIG. 40. FIG. 41 shows only a part extracted from the connecting relationship shown in FIG. 40 in order to simplify the description.

Hereinafter, description is given to the structure for connecting the external connecting terminals 51a and 52a and the structure for connecting the external connecting terminals 51b and 52b as a typical example among the plurality of structures for connecting the external connecting terminals 51 and 52. In FIG. 41, the direction where the dielectric layers 11 are arranged is referred to as the Y direction, and the thickness direction of the dielectric layers 11 is referred to as the X direction in a manner similar to FIG. 37. The external connecting terminals 51a and 52a are arranged in an overlapping manner in regions in parallel with the Y direction in the drawing. The external connecting terminals 51b and 52b are arranged in such a manner that that they do not overlap with each other in any of the directions X and Y in the drawing.

It is assumed that the extension interposer 120B is divided into band regions along the Y direction in a manner similar to the interposer 120A shown in FIG. 37. In that case, the band regions where the external connecting terminals 51a, 51b, 52a and 52b are arranged are called layout band regions Y51a, Y51b, Y52a and Y52b respectively.

In a similar manner, the band regions where the external connecting terminals 51a, 51b, 52a and 52b are arranged along the X direction are called layout band regions X51a, X51b, X52a and X52b respectively.

Based on the foregoing region setting, the structure for connecting the external connecting terminals 51a and 52a and the structure for connecting the external connecting terminals 51b and 52b are described.

First, the structure for connecting the external connecting terminals 51a and 52a is described. The terminals 51a and 52a are arranged so as to face each other along the Y direction (direction in parallel with the surfaces of the dielectric layers 11), and abut the same dielectric layer 11. Therefore, the terminals 51a and 52a are connected to each other as follows. The following connection setting is implemented in pattern-design of the internal conductive patterns and via holes.

First, the internal conductive patterns 12a and 13a provided on the both surfaces of the dielectric layer 11a abutted by the terminals 51a and 52a are selected as the internal conductive patterns for connecting the terminals 51a and 52a.

Next, in the selected internal conductive pattern 12a, pattern lengths of the pattern regions 12a₁ and 13a₁ used for the connection of the terminals 51a and 52a are set as follows. The pattern region 12a, is set to such a pattern length that the layout band region X51a where the external connecting terminal 51a is located and the layout band region X52a where the external connecting terminals 52a is located are pattern ends. The pattern region 13a₁ is set to such a pattern length that covers the layout band region X52a where the external connecting terminal 52a is located and does not cause any problem in the connection with respect to the via hole 22.

In the case where the internal conductive patterns 12a and 13a are used for the connection of the external connecting terminals 51 and 52 other than the external connecting terminals 51a and 52a, the pattern regions 12a₁ and 13a₁ are separated from the other pattern regions of the internal conductive patterns 12a and 13a. However, it is unnecessary for the pattern regions 12a₁ and 13a₁ to be separated from the other pattern regions of the internal conductive patterns 12a and 13a in the case where they are not used for the connection of the other terminals. The described pattern design is only an example of the pattern design for connecting the external connecting terminals 51a and 52a, and any pattern may be adopted as far as the external connecting terminals 51a and 52a are connected.

The lead electrode 17a extended from the pattern region 12a₁ is arranged in the layout band region X51a so as to abut the external connecting terminal 51a, and the external connecting terminal 51a and the lead electrode 17a (pattern region 12a₁) are thereby connected to each other. In a similar manner, the lead electrode 18a extended from the pattern region 13a₁ is made to abut the external connecting terminal 52a, and the external connecting terminal 52a and the lead electrode 18a (pattern region 13a₁) are thereby connected to each other. Because the pattern region 13a₁ is selectively provided in the layout band region X52a, the lead electrode 18a abuts the external connecting terminal 52a even in the case where in the pattern region 13a₁ is provided at any position.

The via hole 22a is provided in the layer region of the dielectric layer 11a where the pattern regions 12a₁ and 13a₁ face each other, and the via hole 22a is made to abut the pattern regions 12a₁ and 13a₁, so that the pattern regions 12a₁ and 13a₁ are connected to each other. By being constituted above, the external connecting terminals 51a and 52a are connected to each other through the pattern region 12a₁, and via hole 22a and pattern region 13a₁.

Next, the interconnection between the external connecting terminals 51b and 52b, which are arranged without overlapping with each other in any of the X and Y directions in the drawing, is described.

In this case, the terminals 51b and 52b are connected to each other with the rewiring patterns 40 between them. The rewiring patterns 40 are formed on any of the main surfaces 20 and 21 of the extension interposer 120B. The rewiring patterns 40 are provided on the main surface 20 or 21 around the external connecting terminals 51 and 52.

In the following description, explanation is given to the example where the rewiring patterns 40 are provided on the main surface 20 of the substrate provided with the external connecting terminals 51, and a similar constitution is adopted in the case where the rewiring patterns 40 are provided on the main surface 21 of the substrate. It is needless to say that the plurality of rewiring patterns 40 may be arranged dividing into the main surfaces 20 and 21. the connection structure is described below.

First, the internal conductive patterns 12b, 12c and 13b are selected as the internal conductive patterns for connecting the terminals 51b and 52b. The internal conductive pattern 12b is located on one of the surfaces of the dielectric layer 11b abutted by the terminal 51b. The internal conductive patterns 12c and 13b are located respectively on the both surfaces of the dielectric layer 11c abutted by the external connecting terminals 52b.

Next, in the selected internal conductive patterns 12b, 12c and 13b, pattern lengths of the pattern regions 12b, 12c, and 13b, used for the connection of the terminals 51b and 52b are set as follows.

The pattern region 12b₁ is set to such a pattern length that the layout band region X51b and the layout band region X52b are made pattern ends. The layout band region X51b is selected based on a reason because it is the band region where the external connecting terminal 51b is placed. The layout band region X52b is arbitrarily selected based on a reason because it does not interfere with the connection of the other pattern regions. In FIG. 41, the layout band region X52b where the external connecting terminal 52b is located is selected as an example.

The pattern region 12c₁ is set to such a length that covers the layout band region X52b. The layout band region X52b is selected based on a reason because it is the region where an end of the pattern region 12b₁ is located and the region where the external connecting terminal 52b is located.

The pattern length 13b₁ is set to such a length that covers the layout band region X52b where the external connecting terminal 52b is located and does not cause any problem in the connection with respect to the via hole 22.

The internal conductive pattern 12c provided with the pattern region 12c₁ and the internal conductive pattern 13b provided with the pattern region 13b₁ may be used for the connection of the other terminals. In that case, the pattern regions 12c₁ and 13b₁ are separated from the other pattern regions of the internal conductive pattern 12b and 13b.

The rewiring pattern 40₁ is formed on any of the main surfaces 20 and 21 of the substrate (main surface 20 of the substrate in the present preferred embodiment). The rewiring pattern 40₁ is arranged in the layout band region where an end of the pattern region 12b₁ is located and the band region where an end of the layout band region 12c₁ is located. In the constitution shown in FIG. 10, the rewiring pattern 40₁ is provided in the band region X52b and formed along the region.

The lead electrodes 17b₁ and 17b₂ are extended respectively from the both ends of the pattern region 12b₁. The one lead electrode 17b₁ abuts the external connecting terminal 51b, and the external connecting terminal 51b and the lead electrode 17b₁ (pattern region 12b₁) are thereby connected to each other. The other lead electrode 17b₂ abuts the rewiring pattern 40₁, and the external connecting terminal 51b and the rewiring pattern 40₁ are thereby connected to each other.

The lead electrode 17c is extended from the pattern region 12c₁. The lead electrode 17c is provided at a position abutting the rewiring pattern 40₁, and the rewiring pattern 40₁ and the lead electrode 17c (pattern region 12c₁) are thereby connected to each other.

The lead electrode 18b extended from the pattern region 13b₁ abuts the external connecting terminal 52b, and the external connecting terminal 52b and the lead electrode 18b (pattern region 13b₁) are thereby connected to each other. Because the pattern region 13b₁ is selectively provided in the layout band region X52b, the lead electrode 18b abuts the external connecting terminal 52b even in the case where the pattern region 13b₁ is provided at any position.

The via hole 22b is provided in the layer region of the dielectric layer 11 (layout band region X52b) where the pattern region 12c₁ and the pattern region 13b₁ face each other so that the via hole 22b abuts the pattern regions 12c₁ and 13b₁, and the pattern regions 12c₁ and 13b₁ are thereby connected to each other. By being thus constituted, the external connecting terminals 51b and 52b are connected to each other via the patter region 12b₁, rewiring pattern 40₁, pattern region 12c₁, via hole 22b and pattern region 13b₁.

The interconnection between the external connecting terminals 51 and 52 was described above referring to the interconnection between the external connecting terminals 51a and 52a and the interconnection between the external connecting terminals 51b and 52b. It is needless to say that the connection structures between the other terminals are similarly constituted.

As described in the preferred embodiments 11 and 12, the external connecting terminals 32 and 51, and 34 and 52 are arranged according to the array-shape alignment or peripheral alignment, and there are sections where these terminals are arranged so as to intersect with each other in a complicated manner.

In order to deal with such a structure, the thickness of the dielectric layer 11 is set to a sufficiently small value in comparison to the width dimensions of the external connecting terminals 32, 34, 51 and 52, and the distance between the internal conductive patterns 12 and 13 provided on the surfaces of the dielectric layer 11 and insulated from each other is also set to a sufficiently small value in comparison to the width dimensions of the external connecting terminals 32, 34, 51 and 52. Accordingly, the external connecting terminals 32 and 34, and 51 and 52, which are arranged according to the array-shape alignment or peripheral alignment and overlapped with one each other, can be connected with a high area efficiency on the substrate via the internal conductive pattern 12 and 13 housed with a high density in the interposers 120A and 120B.

In order to increase the density in the mounting process, the interposer 120A preferably has a rectangular shape in which a side in the planar direction of the dielectric layers 11 (longitudinal direction, Y direction in the drawing) is longer and a side in the thickness direction of the dielectric layers 11 is shorter. Thereby, the number of the connection lines where the both ends of the connections are located along the longitudinal direction of the dielectric layers 11 can be set much more so as to reduce the number of the rewiring patterns 40 to be formed. As a result, the high density can be further advanced. By taking the outer shape consisting of such a rectangular shape that is shorter in the thickness direction of the dielectric layers 11 (lamination direction), the number of the array alignment of the external connecting terminals 34 and 52 provided on the main surface 21 of the interposer 120A which is mounted on the mother board, can be increased in the planar direction of the dielectric layers 11 and reduced in the direction where the dielectric layers 11 are multi-layered.

When the wirings are drawn from the connecting terminals in the printed board (mother board) on which the LSI chip comprising the area-array connecting terminals is mounted, the wirings are drawn outward sequentially from the outer periphery of the area-array terminals. Further, when the wirings are drawn from the terminals in the inner periphery, it is necessary that the wirings are passed through the intervals between the terminals in the outer periphery, or the wirings are drawn using the wiring in a below layer in the printed board by connecting to the wiring layers further below through the via holes or the like. Therefore, as the increase of the number of the area-array connecting terminals is increased, an expensive high-density printed board comprising more layers is necessary only to draw the wirings, which disadvantageously results in the cost increase in the whole system. When the interposer according to the present invention is used, the number of the external connecting terminals 34 and 52 in the direction where the dielectric layers 11 are laminated can be significantly reduced, and the numbers of the external connecting terminals from which the wirings are to be drawn toward the outer periphery and the number of the wiring layers in the printed board on which the interposer is mounted can be thereby significantly reduced. As a result, a less expensive printed board can be effectively used.

The conventional interposer, in which the wiring layers in the plane in parallel with the main surfaces are used for the wirings, is suited when the external connecting terminals connected to the LSI chip are equally extended in the plane and connected to the external terminals in the side mounted on the printed board, therefore it is preferable to have a shape close to square. In the case of the interposer according to the present invention, in which the multiple number of internal conductive patterns 12 and 13 extending in the planar direction of the dielectric layers 11 (longitudinal direction) are used for the wirings, the extension wirings can be drawn with the highest density independent from the rewiring patterns 40 in the rectangular shape where the width of the dielectric layers 11 in the lamination direction in the width of the interposer is close to the width of the LSI chip to be mounted. Therefore, in the present invention, the rectangular shape in which the width of the dielectric layers 11 is close to the width of the LSI chip to be mounted is adopted so that the wirings on the mother substrate described earlier can be more easily realized. As a result, the rectangular interposer in which the number of the area-array connecting terminals on one side can be significantly reduced can be realized

Furthermore, as described above, though the external connecting terminals 51 and 52 formed on the surfaces of the interposer 120A are connected, only a part of the internal conductive patterns is used in the interposer according to the present invention for the interconnection between the external connecting terminals as in the foregoing example because the interposer is inner-packaged with the narrow-pitch internal conductive patterns with the high density. Further, as the external connecting terminals 52 are formed at wide pitches, alignment of the external connecting terminals 52 has the luxury.

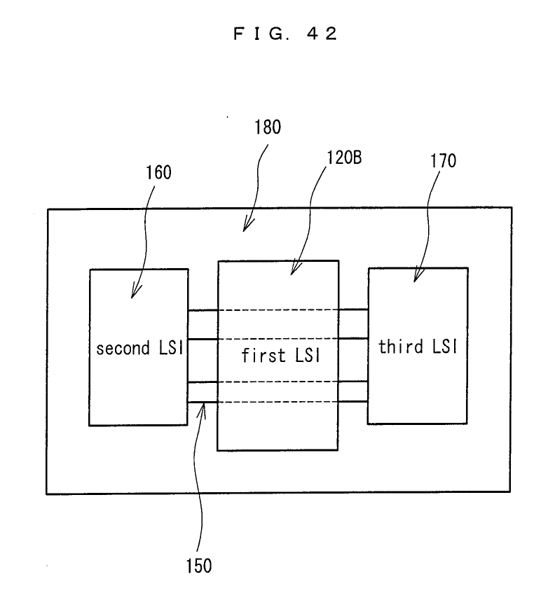

An example of effectively utilizing the internal conductive patterns 12 and 13 and the external connecting terminals 52 which are such unused portions is described referring to FIG. 42.

FIG. 42 shows a constitution wherein the extension interposer 120B on which a first LSI chip is mounted according to the preferred embodiment 12, and second and third LSI chips 160 and 170, which are packaged in a conventional structure, are mounted on a printed board 180. Signal wires of the respective LSI chips are connected to one another by wiring patterns formed on the printed board 180, and external connecting terminals are formed on one of main surfaces of the printed board 180 in the conventional package. Therefore, it is not possible to put through the wiring patterns (signal wires) in a planar region of the printed board 180 mounted with the package unless a multi-layered wiring board is used as the printed board 180.

When the extension interposer 120B according to the present invention is used, however, the signal wires can be put through a place where the extension interposer 120B is mounted. More specifically, as shown in FIG. 42, when a part of the signal wires of the second LSI chip 160 is connected to the third LSI chip 170 through the region of the first LSI chip 120 (interposer 120B), the part of the signal wires is connected to the unused external connecting terminals 52 on the second-LSI-chip side of the extension interposer 120B, and the relevant signal wires are connected to the unused external connecting terminals 52 on the third-LSI-chip-170 side via the unused internal conductive patterns so that the signal wires can be connected to the third LSI chip 170. In this case, it is necessary for the internal conductive patterns 12 and 13 to be formed in parallel in the extension interposer 120B shown in FIG. 11 from the second-LSI-chip-160 side to the third-LSI-chip-170 side.

When the constitution of the extension interposer 120B described above is adopted, it becomes easier to achieve packaging with high density in the mounting process in the printed board, and it becomes possible to avoid unnecessary multi-lamination in the printed board. As a result, the mounting process can be realized in an inexpensive printed board.

Though the preferred embodiments in which the present invention was applied to the interposer was described above, the recitation of the embodiments does not limit the present invention, and can be variously modified. For example, in the present preferred embodiments, the rewiring patterns 40 are formed on the surface of the interposer on which the external connecting terminals 32 are formed, however, may be formed on the surface of the interposer on which the external connecting terminals 34 are formed.

### Preferred Embodiment 13

The wiring board according to the present invention realizes the high-density wirings at such narrow pitches that could not be obtained in the conventional build-up wiring board. However, a degree of freedom in the wirings is limited in the case where the LSI chips comprising a large number of connecting terminals are connected to each other by the wirings because the wirings (internal conductive patterns) are uniformly arranged in one direction (vertical direction on the paper in the drawing). It is possible to connect the internal conductive patterns terminals by forming the surface wirings which connect the lead electrodes between them on the surface of the wiring board according to the present invention, however, the wiring pitches are the same as in the conventional technology because the surface wirings are formed by means of a conventional method (for example, etching method). Therefore, as there is a restriction generated by the wiring pitches of the surface wirings even though the pitches of the internal wirings (internal conductive patterns) are narrowed, it is difficult to bring out a potential performance sufficiently.

A preferred embodiment 13 of the present invention focuses on the foregoing problem, and realizes a multi-layered wiring board capable of interconnecting the LSI chips comprising a large number of connecting terminals without the surface wirings. According to the present preferred embodiment, the LSI chips comprising a large number of connecting terminals can be connected to each other without detriment to the performance of the narrow-pitch wirings according to the present invention.

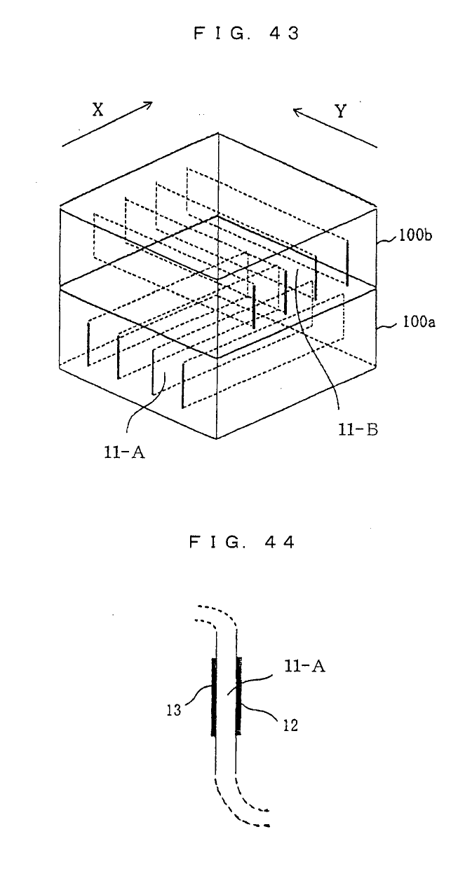

Hereinafter, the preferred embodiment 13 is described referring to the drawings. FIG. 43 shows a basic structure of the multi-layered wiring board according to the present preferred embodiment.

As shown in FIG. 43, the multi-layered wiring board is formed by laminating a a second core substrate 100b on first core substrate 100a. The first and second core substrates 100a and 100b have a basically same constitution as that of the wiring board 100A shown in FIG. 1.

More specifically, the first core substrate 100a comprises a plurality of dielectric layers 11-A consisting of sections superposed on one another formed by folding a dielectric sheet 10 having a certain width alternately and continuously, and internal conductive patterns 12 and 13 formed in a band shape on main surfaces of the dielectric layers 11-A along a width direction of the dielectric layers 11-A. The second core substrate 100b is similarly constituted.

In FIG. 43, thickness of the dielectric layers 11-A and 11-B is omitted. As shown in FIG. 44, the internal conductive patterns 12 and 13 are formed on the both surfaces of the dielectric layers 11-A having a certain thickness in the band shape along a width direction of the dielectric layers 11-A. The dielectric layers 11-B are similarly constituted.

As shown in FIG. 43, the plurality of dielectric layers 11-A formed on the first core substrate 100a is aligned in parallel in an arrow-X direction, and the plurality of dielectric layers 11-B formed on the first core substrate 100b is aligned in parallel in an arrow-Y direction. This constitution is obtained by folding the respective dielectric sheets alternately in directions intersecting in orthogonal state with each other.

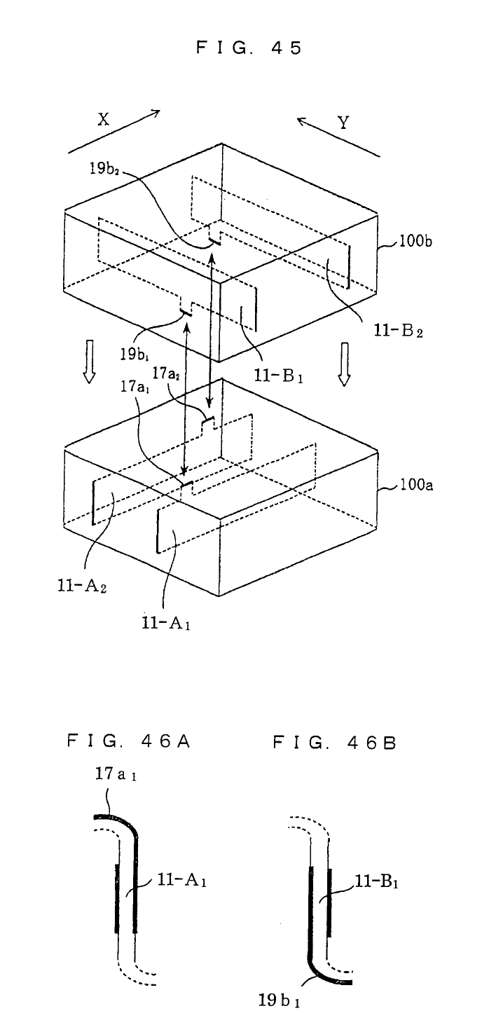

FIG. 45 shows a constitution wherein a part of the internal conductive patterns formed in the first core substrate 100a and a part of the internal conductive patterns formed in the second substrate 100b are connected to each other in the multi-layered wiring board 110 shown in FIG. 43.

As shown in FIG. 45, a part of the plurality of dielectric layers constituting the first core substrate 100a, which are dielectric layers 11-A₁ and 11-A₂, comprise the internal conductive patterns, and a part of the internal conductive patterns is extended to bent sections on a mountainside of the dielectric layers 11-A₁ and 11-A₂. The bent sections constitute one main surface of the first core substrate 100a, and the one main surface faces the second core substrate 100b. The extended ends of the internal conductive patterns constitute lead electrodes 17a₁ and 17a₂, and the lead electrodes 17a₁ and 17a₂ are exposed on the surface of the first core substrate 100a.

In a similar manner, a part of the plurality of dielectric layers constituting the first core substrate 100b, which are dielectric layers 11-B₁ and 11-B₂, comprise the internal conductive patterns, and a part of the internal conductive patterns is extended to bent sections on a mountainside of the dielectric layers. The bent sections constitute one main surface of the second core substrate 100b, and the main surface faces the second core substrate 100a. The extended ends of the internal conductive patterns constitute lead electrodes 19b₁ and 19b₂, and the lead electrodes 19b₁ and 19b₂ are exposed on the main surface of the second core substrate 100b. As well, in FIG. 45, any dielectric layer other than 11-A₁, 11-A₂, 11-B₁, and 11-B₂ is not shown.

The lead electrodes 17a₁, 17a₂, 19b₁ and 19b₂ are constituted respectively as shown in FIGS. 46A and 46B. More specifically, though the thickness of the dielectric layers 11-A₁, 11-A₂, 11-B₁, and 11-B₂ are omitted in FIG. 45, the lead electrodes 17a₁, 17a₂, 19b₁ and 19b₂ are provided actually on the surfaces of each of the dielectric layers 11-A₁, 11-A₂, 11-B₁, and 11-B₂ having a certain thickness as shown in FIGS. 46A and 46B. The lead electrodes 17a₁, 17a₂, 19b₁ and 19b₂ are formed in the band shape along the width direction of the dielectric layers 11-A₁, 11-A₂, 11-B₁, and 11-B₂.

The positions where the respective lead electrodes 17a₁, 17a₂, 19b₁ and 19b₂ are exposed are predetermined so that the lead electrodes 17a₁ and 19b₁, and 17a₂ and 19b₂ are connected to each other.

The lead electrodes 17a₁, 17a₂, 19b₁ and 19b₂ are constituted as described so that the internal conductive patterns, which are arbitrarily selected from the plurality of internal conductive patterns in the core substrates laminated respectively, can be connected to each other.

The plurality of dielectric layers 11 constituting the first and second core substrates 100a and 100b are bonded to one another by insulating adhesive layers provided between the dielectric layers 11. The respective internal conductive patterns (wiring layers) 12 and 13 are coated with the insulating adhesive layers and incorporated in the core substrates. Therefore, the multi-layered wiring board can be formed through laminating the core substrates in a state where they are insulated from each other while narrow pitches are maintained therein.

The foregoing description relates to the structure where the internal conductive patterns formed in the upper-side core substrate and the internal conductive patterns formed in the lower-side core substrate are connected to each other in the multi-layered wiring board comprising the core substrates laminated on each other. Further, according to the constitution of the present invention, the wirings, which may intersect with one another when formed on the substrate surface, can be freely wired while any intersection is avoided. Hereinafter, such a wiring structure is described referring to FIGS. 47-49. FIG. 47 shows a constitution wherein the lead electrodes 17b₁ and 17b₂ exposed on the same main surface of the second core substrate 100b are connected to each other by the internal conductive patterns incorporated in the first and second core substrates 100a and 100b.

All of the dielectric layers 11 in the second core substrate 100b including the dielectric layers 11-B₁ and 11-B₂ where the lead electrodes 17b₁ and 17b₂ is provided, are arranged in parallel with one another along the arrow-Y direction. Therefore, it is not possible to connect the lead electrodes 17b₁ and 17b₂ through only the internal conductive patterns formed in the second core substrate 100b. On the contrary, the dielectric layers 11 in the first core substrate 100a laminated so as to be arranged on the second core substrate 100b are in parallel with one another along the arrow-X direction intersecting in orthogonal state with the arrow-Y direction. In FIG. 47, the constitution of the first core substrate 100a is utilized so that the lead electrodes 17b₁ and 17b₂ are connected to each other. A description will is given below. As well, in the following description, the main surfaces facing each other are called facing main surfaces, while the main surfaces located on the rear sides of the facing main surfaces are called rear main surfaces in the first and second core substrates.

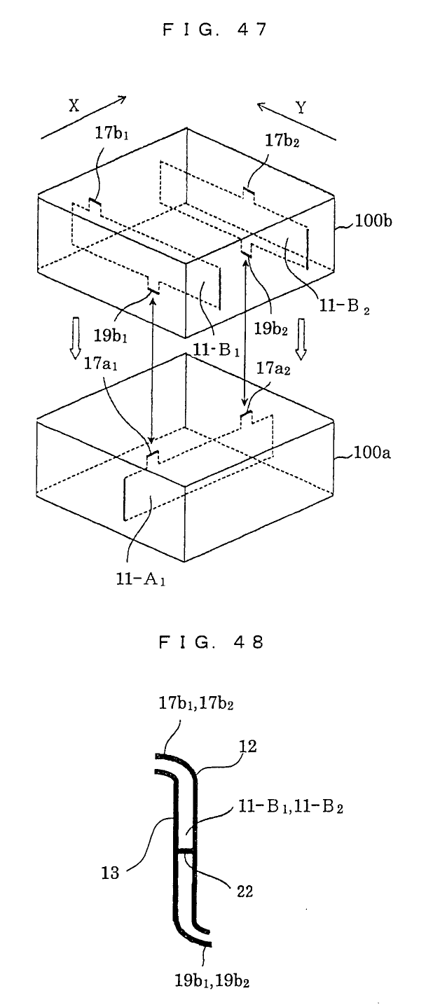

The lead electrode 17b₁ exposed on the rear main surface of the second core substrate 100b is led out to the facing main surface of the second core substrate 100b. The lead electrode 17b₁ is led out as follows. As shown in FIG. 48, the internal conductive pattern 12 continuous to the lead electrode 17b₁ is provided on one surface of the dielectric layer 11-B₁ where the lead electrode 17b₁ is provided. The internal conductive pattern 12 has such a width dimension that reaches a central part of the dielectric layer 11-B₁ in the width direction thereof. The lead electrode 19b₁ is provided on the surface of the dielectric layer 11-B₁ (hereinafter, referred to as the other surface) located on the rear side of the one surface. The lead electrode 19b₁ can be provided at any arbitrary position in the Y direction. The internal conductive pattern 13 continuous to the lead electrode 19b₁ is provided on the other surface of the dielectric layer 11-B₁ provided with the lead electrode 19b₁. The internal conductive pattern 13 has such a width dimension that reaches a central part of the dielectric layer 11-B₁ in the width direction thereof. The internal conductive patterns 12 and 13 are connected to each other through the via hole 22 provided in the dielectric layer 11-B₁. Herewith, the lead electrode 17b₁ provided on the rear main surface of the second core substrate 100b, which is arranged at the arbitrary position in the Y direction, can be led out to the lead electrode 19b₁ on the facing main surface of the second core substrate 100b.

Next, the lead electrode 17b₂ exposed on the rear main surface of the second core substrate 100b is led out to the facing main surface of the second core substrate 100b. The lead electrode 17b₂ can be led out in a manner similar to the lead electrode 17b₁. As shown in FIG. 48, the internal conductive pattern 12 continuous to the lead electrode 17b₂ is provided on one surface of the dielectric layer 11-B₂ where the lead electrode 17b₂ is provided. The internal conductive pattern 12 has such a width dimension that reaches a central part of the dielectric layer 11-B₂ in the width direction thereof. The lead electrode 19b₂ is provided on the other surface of the dielectric layer 11-B₂. The lead electrode 19b₂ is provided at a position on the same line as the lead electrode 19b₁ along the X direction. The internal conductive pattern 13 continuous to the lead electrode 19b₂ is provided on the other surface of the dielectric layer 11-B₂ provided with the lead electrode 19b₂. The internal conductive pattern 13 has such a width dimension that reaches a central part of the dielectric layer 11-B₂ in the width direction thereof. The internal conductive patterns 12 and 13 are connected to each other through the via hole 22 provided in the dielectric layer 11-B₂. Herewith, the lead electrode 17b₂ provided on the rear main surface of the second core substrate 100b can be led out until the lead electrode 19b₂ on the same line as the lead electrode 19b₁ along the X direction.

The lead electrodes 17a₁ and 17a₂ are exposed on the facing main surface of the first core substrate 100a. The lead electrodes 17a₁ and 17a₂ are provided on one surface of the insulating layer 11-A₁. The insulating layer 11-A₁ is one of insulating layers 11 constituting the first core substrate 100a and located on the same line in the X direction where the lead electrodes 19b₁ and 19b₂. The lead electrode 17a₁ is arranged at a position facing the lead electrode 19b₁. The lead electrode 17a₂ is arranged at a position facing the lead electrode 19b₂. The internal conductive patterns 12 continuous to the respective lead electrodes 17a₁ and 17a₂ are provided on the one surface of the dielectric layer 11-A₁ where the lead electrodes 17a₁ and 17a₂ is provided. The lead electrodes 17a₁ and 17a₂ are thereby connected to each other via the internal conductive patterns 12.

After the foregoing constitution is prepared, the first and second core substrates 100a and 100b are laminated on each other. By doing this, the lead electrode 19b₁ of the second core substrate 100b and the lead electrode 17a₁ of the first core substrate 100a abut each other and thereby connected, and the lead electrode 19b₂ of the second core substrate 100b and the lead electrode 17a₂ of the first core substrate 100a abut each other and thereby connected. Herewith, the lead electrodes 19b₁ and 19b₂ of the second core substrate 100b are connected via the lead electrode 17a₁, internal conductive patterns, and lead electrode 17a₂ of the first core substrate 100a.

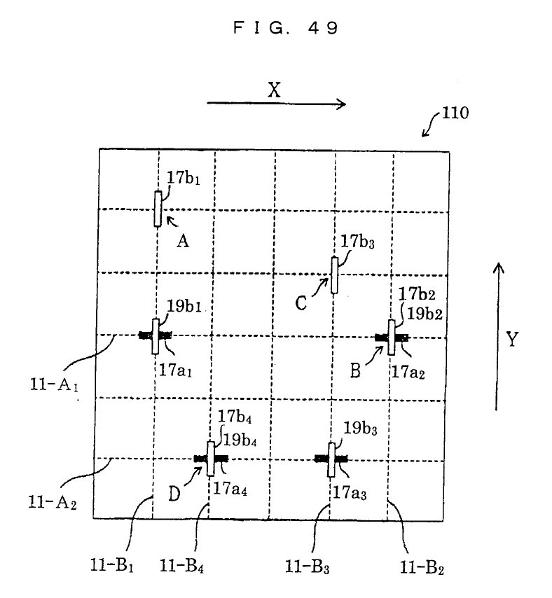

When the foregoing connection structure is adopted, the wirings, which may cross one another when formed on the substrate main surface, can be wired without any problem. Below is described the structure according to the present invention where the wirings can be freely provided referring to FIG. 49.

FIG. 49 is a plan view of the multi-layered wiring board 110 constituted by laminating the first and second core substrates 100a and 100b on each other that is shown in FIG. 47. The plurality of dielectric layers 11 formed in the first core substrate 100a is arranged in a direction shown by an arrow X, and the plurality of dielectric layers 11 formed in the second core substrate 100b is arranged in a direction shown by an arrow Y. Observing from the upper side of the wiring board 10B, these dielectric layers 11 are arranged in a lattice structure.

As shown in FIG. 49, the lead electrodes 17b₁ and 17b₂ exposed on the rear main surface of the second core substrate 100b (surface of the multi-layered wiring board 110 in this case) are respectively positioned at a lattice point A and a lattice point B. AS shown in FIG. 47, the lead electrodes 17b₁ and 17b₂ are connected to each other via the internal conductive patterns 12 and 13 housed in the first and second core substrates 100a and 100b.

In FIG. 49, the lead electrodes exposed on the facing main surface and the rear main surface of the second core substrate 100b are shown with white rectangular shapes. The lead electrodes exposed on the facing main surface and the rear main surface of the second core substrate 100a are shown with black rectangular shapes.

The lead electrodes 17b₃ and 17b₄ exposed on the rear main surfaces of the second core substrate 100b (surface of the multi-layered wiring board 110 in this case) are respectively positioned at a lattice point C and a lattice point D. Is thought an example in which the lead electrodes 17b₃ and 17b₄ at the lattice points C and D are connected. In the example, the wiring which connects the lattice points A and B and the wiring which connects the lattice points C and D intersect with each other if the wirings are formed on the substrate surface. The only conventional solution in order to avoid the intersection is to detour the wirings.

However, when the constitution according to the present invention is adopted, the lattice points A and B, and the lattice points C and D are connected without any detoured wiring. The case is described below.

As shown in FIG. 49, the lead electrode 17b₃ exposed on the rear main surface of the second core substrate 100b is led out until the lead electrode 19b₃ exposed on the facing main surface of the second core substrate 100b. The lead electrode 19b₃ is placed at a position on the same line as the lattice D (lead electrode 17b₄) located in the X direction shown in FIG. 49 and distantly from the lattice point D.

The lead electrodes 17b₃ and 19b₃ are respectively provided on the both surfaces (one surface and the other surface) of the same dielectric layer in the second core substrate 100b. Therefore, the lead electrodes 17b₃ and 19b₃ are provided distantly from each other on the same line as the lattice point C located in the Y direction shown in FIG. 49.

The structure for connecting the lead electrodes 17b₃ and 19b₃ (lead electrode leading-out structure) is adopted the one described referring to FIGS. 47 and 48. More specifically, the internal conductive pattern continuous to the lead electrode 17b₃ and the internal conductive pattern continuous to the lead electrode 19b₃ are connected to each other through the via hole 22 formed in the dielectric layer where the lead electrodes 17b₃ and 19b₃ is provided.

Next, the lead electrodes 17b₃ and 17b₄ are exposed on the facing main surface of the first core substrate 100a. The lead electrodes 17a₃ and 17a₄ are provided on the same surface of the same dielectric layer 11 in the first core substrate 100a. As the dielectric layer provided with the lead electrodes 17a₃ and 17a₄, the dielectric layer 11 located on the same line as the lead electrodes 19b₃ and 19b₄ along the X direction shown in FIGS. 47 and 49 is selected.

The lead electrode 17b₄ exposed on the rear main surface of the second core substrate 100b is led out to the lead electrode 19b₄ exposed on the facing main surface of the second core substrate 100b. Here, the lead electrode 19b₄ is provided on the dielectric layer 11 provided with the lead electrode 17b₄, however, the lead electrode 19b₄ is provided, not on one surface of the dielectric layer provided with the lead electrode 17b₄, but on the other surface on the rear side thereof. Further, the lead electrode 19b₄ is placed on the same line as the lead electrodes 17a₄ and 17a₃ along the X direction shown in FIG. 49. The lead electrodes 19b₄ and 17b₄ are connected to each other through the via hole 22 formed in the dielectric layer 11.

If the lead electrodes are constituted like this according to the foregoing constitution, the lead electrodes 17a₃ and 17a₄ exposed on the facing main surface of the first core substrate 100a, and the lead electrodes 19b₃ and 19b₄ exposed on the opposing main surface of the second core substrate 100a can be connected when the first and second core substrates 100a and 100b are laminated on each other as shown in FIG. 47.

As a result, the lead electrodes 17b₃ and 17b₄ provided on the rear main surface of the second core substrate 100b distantly from each other can be connected to each other via the internal conductive patterns incorporated in the first and second core substrates 100a and 100b.

According to the present preferred embodiment described above, the internal conductive patterns incorporated in the first and second core substrates 100a and 100b merely apparently have the lattice shape, and actually insulated from each other. Therefore, the lead electrodes provided on all of the lattice points can be connected to one another without any unnecessary detoured wiring.

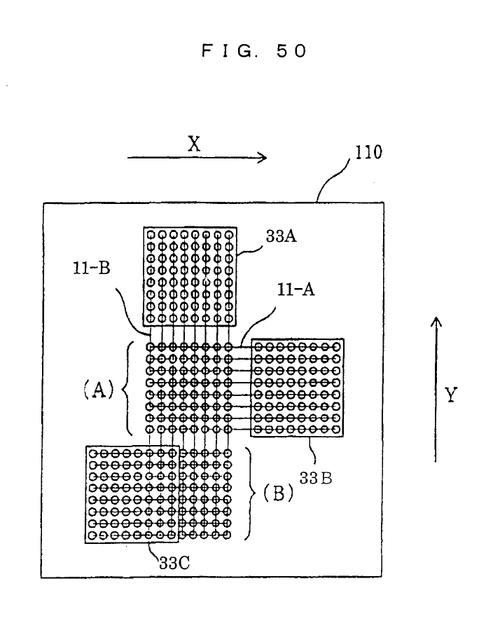

FIG. 50 shows a structure where three LSI chips (semiconductor devices) 33A, 33B and 33C are mounted on the multi-layered wiring board 110 according to the present invention. The multi-layered wiring board 110 comprises the first and second core substrates 100a and 100b laminated on each other. The first core substrate 100a has the dielectric layers 11-A (internal conductive patterns) arranged in parallel along the arrow-X direction, though not shown. The second core substrate 100b has the dielectric layers 11-B (internal conductive patterns) arranged in parallel along the arrow-Y direction. As well, in FIG. 50, a part of the dielectric layers 11-A and 11-B is shown by dotted lines. Because the dielectric layers are aligned the pitches of 4-5 μm, a dotted line actually corresponds to dielectric layers 11 comprising 10-100 layers.

In the case where package terminals of the respective LSI chips are arranged in the array shape, the lead electrodes (not shown) exposed on the rear main surface of the second core substrate 100b (surface of the multi-layered wiring board) are formed immediately below the respective terminals, and the terminals are respectively connected to the lead electrodes. The connection structure where the internal conductive patterns shown in FIG. 49 are used is provided in regions A and B where the internal conductive patterns connected to the lead electrodes (dielectric layers 11-A and 11-B) intersect with each other, so that the terminals of the respective chips are connected to one another.

As described above, in the multi-layered wiring board according to the present invention where the core substrate constituted as shown in FIG. 1 are laminated on each other, the wiring patterns can be hard-wired in any arbitrary direction. As a result, the wiring board can achieve the process capable of high-density mounting wherein the high-density wirings inherent of the core substrate is exerted at maximum.

In addition, according to the present invention, it is possible to eradicate the roundabout wirings in the multi-layered wiring board, and the parallel bus lines and transmission lines can be embedded in the wiring board, which achieves a high quality in the wiring board at the same time.

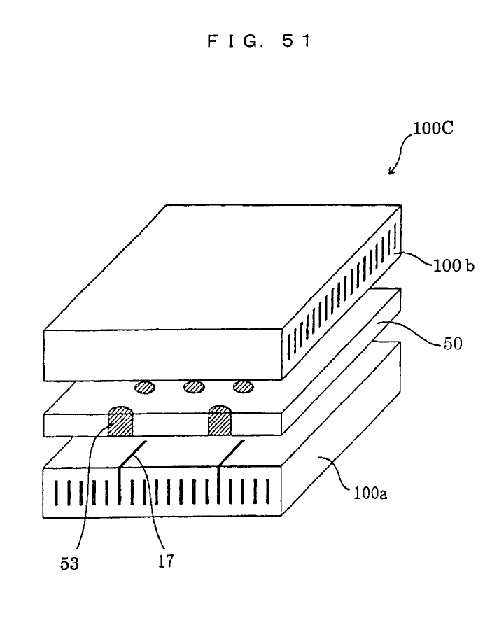

FIG. 51 shows a modification example of the multi-layered wiring board 110 according to the present preferred embodiment. A structure according to the modification example is different to that of the multi-layered wiring board 110 shown in FIG. 43 in a point that an inter-substrate connecting layer 50 is interposed between the first and second core substrates 100a and 100b.

The lead electrodes 17 exposed on the facing main surface of the first core substrate 100a and the lead electrodes 19 (not shown) exposed on the facing main surface of the second core substrate 100b are connected to each other through via holes 53 formed in the inter-substrate connecting layer 50. It is not possible to significantly increase an exposed area of the lead electrode because the wiring patterns themselves are exposed on the facing main surface. In order to connect the lead electrodes, therefore, high accuracy is required as the positioning accuracy of the lead electrodes.

In a wiring board 100C according to the modification example shown in FIG. 51, the inter-substrate connecting layer 50 comprising via holes 53 having an exposed area larger than that of the lead electrodes is interposed between the first and second core substrates 100a and 100b so that the lead electrodes are connected through the via holes 53. Herewith, the area of the via hole 53 can modify the positioning accuracy, which facilitates the connection.

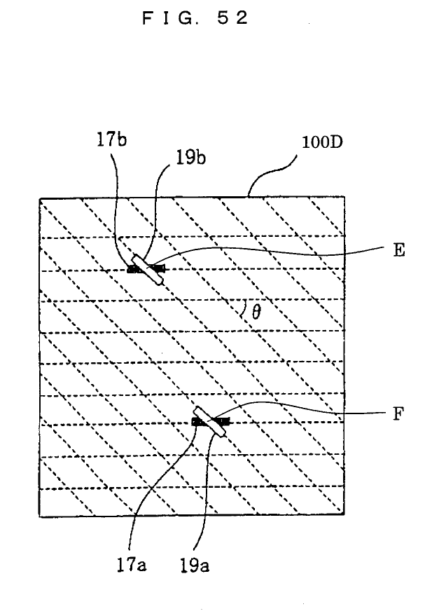

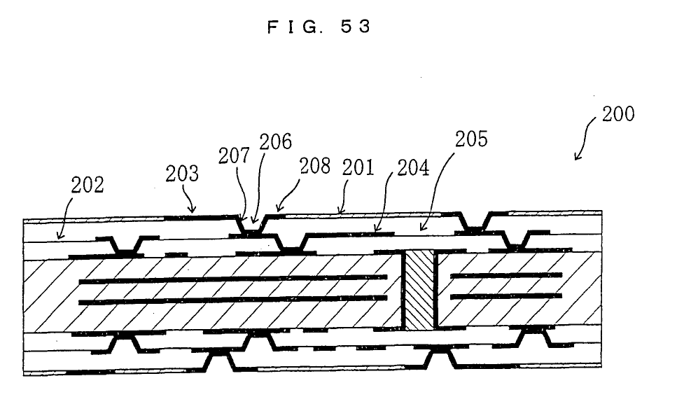

FIG. 52 shows a multi-layered wiring board 100D n wherein a direction of laminating the first and second core substrates on each other is set at an angle θ other than 90 degrees. More specifically, the alignment direction of the dielectric layers (internal conductive patterns) constituting the first core substrate 100a and the alignment direction of the dielectric layers (internal conducive patterns) constituting the second core substrate 100b intersect with each other at the angle θ other than 90 degrees. The constitution like this can be formed through folding the dielectric sheets in directions different to each other.

In the modification example shown in FIG. 52, the lead electrodes 17a and 17b exposed on the facing main surface of the first core substrate 100a, and the lead electrodes 19a and 19b exposed on the facing main surface of the second core substrate 100b are connected at the lattice points E and F. The angle θ may be any arbitrary angle, and may be 30 degrees, 45 degrees or 60 degrees other than 90 degrees.

The present invention was thus far described according to the preferred embodiments, however, the recitations of the embodiments do not limit the present invention and can be variously modified. For example, the description was given based on the example in which the number of the internal conductive patterns 12 and 13 respectively formed in the band shape between the mountain-side lines P-P′ and the valley-side lines Q-Q′ of the dielectric sheet 10 was one. By forming at least two of the internal conductive patterns, the wiring board can achieve a higher density in such a design scope that does not increase the wiring resistance. Further, the dielectric sheet 10 was continuously folded at the predetermined intervals in the description, however, the intervals at which the dielectric sheet 10 is folded may be changed in order to coordinate characteristic parameters of the signal wires or the like.

Further, the two core substrates were laminated on each other in the preferred embodiments described above, however, the multi-layered wiring board may comprise at least three core substrates laminated on one another.

What is claimed is:

1. A wiring board comprising:
a substrate wherein a plurality of dielectric layers are arranged along a direction where main surfaces of the substrate face each other and laminated on one another along a planar direction of the substrate; and
internal conducive patterns provided on surfaces of the dielectric layers, wherein
the adjacent dielectric layers are formed so as to interconnect in such a manner that layer ends thereof are continuously and integrally coupled with each other on any of the main surfaces of the substrate, and
the coupled sections of the adjacent dielectric layers are alternately provided on any of the main surfaces of the substrate, and the plurality of dielectric layers have a shape of a bent dielectric sheet.

2. The wiring board as claimed in claim 1, wherein
the internal conductive patterns are provided in a band shape along a ridge-line direction of the coupled sections.

3. The wiring board as claimed in claim 1, wherein
insulating adhesive layers which adhere the adjacent dielectric layers to each other are further provided.

4. The wiring board as claimed in claim 3, wherein
the internal conductive patterns are coated with the insulating adhesive layers.

5. The wiring board as claimed in claim 1, wherein
the adjacent dielectric layers are bonded by pressure to each other.

6. The wiring board as claimed in claim 1, wherein
the internal conductive patterns are provided on both surfaces of the dielectric layers.

7. The wiring board as claimed in claim 1, wherein
the internal conducive pattern is extended until the coupled section where the surface of the dielectric layer, on which the internal conductive pattern is formed, becomes an outer side of the coupling, and exposed on the main surface of the substrate.

8. The wiring board as claimed in claim 6, wherein
the internal conducive patterns provided on the both surfaces of the dielectric layer are extended until the coupled sections where the surfaces of the dielectric layer, on which the internal conductive pattern is formed, becomes an outer side of the coupling, and exposed on any of the main surfaces of the substrate, and
the internal conductive patterns provided on the both surfaces of the dielectric layer and facing each other are connected to each other by an inter-layer connecting conductor provided in the dielectric layer so as to penetrate in a thickness direction thereof.

9. The wiring board as claimed in claim 8, wherein
the inter-layer connecting conductor is a metal conductor.

10. The wiring board as claimed in claim 6, wherein
the internal conducive patterns provided on the both surfaces of the dielectric layer are extended until the coupled sections where the surfaces of the dielectric layer, on which the internal conductive pattern is formed, becomes an outer side of the coupling and exposed on any of the main surfaces of the substrate, and
the internal conductive patterns provided on one of the surfaces are connected to each other so as to constitute a ground wire or a power-supply wire.

11. The wiring board as claimed in claim 10, wherein
the internal conducive patterns provided on the one surfaces of the dielectric layers are formed continuously and integrally to be connected at the coupled sections where the internal conductive patterns are extended.

12. The wiring board as claimed in claim 7, wherein
an external connecting electrode abutting an end of the internal conductive pattern exposed on the main surface of the substrate so as to connect thereto, is provided on the main surface of the substrate.

13. The wiring board as claimed in claim 10, wherein
at least two of the internal conductive patterns are exposed on the main surface of the substrate, and
an external conductive pattern abutting and thereby connecting these exposed internal conductive patterns to each other is provided on the main surface of the substrate.

14. The wiring board as claimed in claim 1, wherein
the plurality of dielectric layers is formed by folding the dielectric sheet is alternately and continuously at certain intervals.

15. The wiring board as claimed in claim 3, wherein
the insulating adhesive layer includes thermosetting epoxy resin in its composition.

16. The wiring board as claimed in claim 5, wherein
the dielectric layers are formed from thermoplastic polyester or thermoplastic fluorocarbon resin.

17. An electronic component mounting structure comprising:
the wiring board as claimed in claim 12; and
an electronic component connected to the external connecting electrode of the wiring board.

18. A method of manufacturing a wiring board comprising:
a first step in which a dielectric sheet is prepared, and mountainside lines and valley-side lines respectively showing mountains and valleys in observing from one surface of the dielectric sheet are virtually set alternately and in parallel with each other at certain intervals;
a second step in which internal conductive patterns located between the adjacent mountainside lines and the valley-side lines and formed in a band shape in parallel with the mountainside and valley-side lines on at least the one surface of the dielectric sheet; and
a third step in which the dielectric sheet is alternately folded along the mountainside lines and the valley-side lines in such a manner that the mountain-side line forms a mountain shape and the valley-side line forms a valley shape in observing from the one surface so as to form a wiring board whose one main surface is an exposed surface of the mountain shape.

19. The method of manufacturing the wiring board as claimed in claim 18, wherein
the dielectric sheets folded and abutting each other are bonded to each other by means of an insulating adhesive in the third step.

20. The method of manufacturing the wiring board as claimed in claim 19, wherein
the internal conductive patterns are coated with the insulating adhesive in the third step.

21. The method of manufacturing the wiring board as claimed in claim 18, wherein
the dielectric sheets folded and abutting each other are bonded by pressure to each other in the third step.

22. The method of manufacturing the wiring board as claimed in claim 18, wherein
the internal conductive patterns are formed so as to substantially face each other on both surfaces of the dielectric sheet in the second step.

23. The method of manufacturing the wiring board as claimed in claim 22, wherein
the second step is implemented after an inter-layer connecting conductor, which connects the internal conductive patterns facing each other interleaving the dielectric sheet between them, is formed in the dielectric sheet.

24. The method of manufacturing the wiring board as claimed in claim 18, wherein
the internal conductive pattern is formed so as to extend across a substantially entire length thereof beyond the mountain-side line or the valley-side line in the second step.

25. The method of manufacturing the wiring board as claimed in claim 18, wherein
at least a part of the internal conductive patterns is formed so as to extend beyond the mountain-side line or the valley-side line so that the internal conductive pattern is exposed on the main surface of the substrate by folding the sheet in the second step.

26. The method of manufacturing the wiring board as claimed in claim 18, wherein
bending guide grooves are formed along the mountainside lines and the valley-side lines virtually set on the surface of the dielectric sheet in the first step.

27. The method of manufacturing the wiring board as claimed in claim 18, wherein
a semi-curable insulating sheet is formed on the surface of the dielectric sheet where the internal conductive patterns is formed after formation of the internal conductive patterns on the dielectric sheet, and the formed insulating sheet is removed except for at least the sheet on the internal conductive patterns in the second step.

28. The method of manufacturing the wiring board as claimed in claim 27, wherein
the semi-curable insulating sheet is thermally cured so that the folded dielectric sheets are bonded to each other in the third step.

29. A multi-layered wiring board comprising:
a core substrate; and
a wiring board provided on at least one of main surfaces of the core substrate, wherein
the core substrate comprises:
a core substrate main body comprising a plurality of dielectric layers arranged along a direction where the main surfaces of the core substrate face each other and laminated on another along a planar direction of the core substrate; and
internal conductive patterns provided on surfaces of the dielectric layers, and
the adjacent dielectric layers are formed to interconnect so as to be continuously and integrally coupled with each other at layer ends thereof on any of the main surfaces of the core substrate, and
the coupled sections of the adjacent dielectric layers are alternately provided on any of the main surfaces of the core substrate, and the plurality of dielectric layers have a shape of a bent dielectric sheet.

30. The multi-layered wiring board as claimed in claim 29, wherein
the wiring boards are provided on the both main surfaces of the core substrate.

31. The multi-layered wiring board as claimed in claim 29, wherein
the internal conductive patterns are provided in a band shape along a ridge-line direction of the coupled sections.

32. The multi-layered wiring board as claimed in claim 29, wherein
insulating adhesive layers for adhering the adjacent dielectric layers to each other are provided.

33. The multi-layered wiring board as claimed in claim 32, wherein
the internal conductive patterns are coated with the insulating adhesive layers.

34. The multi-layered wiring board as claimed in claim 29, wherein
the adjacent dielectric layers are bonded by pressure to each other.

35. The multi-layered wiring board as claimed in claim 29, wherein
the internal conductive patterns are provided on both surfaces of the dielectric layers.

36. The multi-layered wiring board as claimed in claim 29, wherein
the internal conducive pattern is extended to the coupled section where the surface of the dielectric layer, on which the internal conductive pattern provided, becomes an outer side of the coupling so as to be exposed on the main surface of the substrate.

37. The multi-layered wiring board as claimed in claim 36, wherein
an external connecting terminal abutting and connected to an exposed end of the internal conductive pattern is provided on the main surface of the core substrate.

38. The multi-layered wiring board as claimed in claim 36, wherein
at least two of the conductive patterns are exposed on the main surface of the core substrate, and an external conductive pattern abutting and thereby connecting the exposed internal conductive patterns is provided on the main surface of the core substrate.

39. The multi-layered wiring board as claimed in claim 36, wherein
the wiring board further comprises:
wiring patterns provided on an exposed surface thereof; and
the wiring patterns provided so as to penetrate the wiring board in a thickness direction thereof and connecting the wiring patterns to the exposed end of the internal conductive pattern.

40. The multi-layered wiring board as claimed in claim 39, wherein
the wiring boards comprising the wiring patterns and the connecting conductors are respectively provided on the both main surfaces of the core substrate.

41. The multi-layered wiring board as claimed in claim 39, wherein
the internal conductive patterns provided on the both surfaces of the dielectric layer and facing each other are connected by an inter-layer connecting conductor provided in the dielectric layer so as to penetrate in a thickness direction thereof.

42. The multi-layered wiring board as claimed in claim 41, wherein
external connecting terminals abutting and thereby connected to the exposed ends of the internal conductive patterns are provided on the both main surfaces of the core substrate, and
the wiring patterns are connected to the external connecting terminals via the connecting conductors.

43. The multi-layered wiring board as claimed in claim 36, wherein
the internal conductive patterns provided on the one surfaces of the dielectric layers are connected to each other so as to constitute ground wires or power-supply wires.

44. The multi-layered wiring board as claimed in claim 40, wherein
the internal conductive patterns provided on one of the surfaces of the dielectric layer are connected to each other, and
the wiring patterns connected to the internal conductive patterns connected to each other via the connecting conductor are connected to a ground terminal or a power-supply terminal.

45. The multi-layered wiring board as claimed in claim 39, wherein
the wiring board consists of build-up wiring layers formed on the core substrate.

46. The multi-layered wiring board as claimed in claim 29, wherein
a pitch at by which the internal conductive pattern is formed is smaller than a pitch at which the wiring pattern is formed.

47. A method of manufacturing a wiring board comprising:
a first step in which a dielectric sheet is prepared, and mountainside lines and valley-side lines respectively showing mountains and valleys in observing from one surface of the dielectric sheet are virtually set alternately and in parallel with each other at certain intervals;
a second step in which internal conductive patterns located between the adjacent mountain-side lines and the valley-side lines and having a band shape in parallel with the mountainside and valley-side lines are formed on at least the one surface of the dielectric sheet;
a third step in which the dielectric sheet is alternately folded along the mountainside lines and the valley-side lines in such a manner that the mountainside line forms a mountain shape and the valley-side line forms a valley shape in observing from the one surface so as to form a core substrate whose one main surface is an exposed surface of the mountain shape;
a fourth step in which an insulating layer is formed on a main surface of the core substrate; and
a fifth step in which wiring patterns are formed on the insulating layer.

48. The method of manufacturing the wiring board as claimed in claim 47, wherein
at least a part of the internal conductive patterns is formed so as to extend beyond the mountainside line or the valley-side line so that the internal conductive pattern is exposed on the main surface of the substrate by folding the sheet in the second step.

49. The method of manufacturing the wiring board as claimed in claim 48, wherein
an external connecting terminal abutting the internal conductive pattern exposed on the main surface of the core substrate is formed on the main surface of the core substrate before the insulating layer is formed.

50. The method of manufacturing the wiring board as claimed in claim 48, wherein
the wiring patterns are formed on the insulating layer, and
a connecting conductor which connects the formed wiring patterns to the internal conductive pattern exposed on the main surface of the core substrate is formed in the insulating layer in the fifth step.

51. An interposer comprising:
a substrate comprising a plurality of dielectric layers arranged along a direction where both main surfaces of the substrate face each other and laminated on one another along a planar direction of the substrate;
internal conductive patterns provided on at least one main surfaces of the dielectric layers,
an inter-layer connecting conductor provided in the dielectric layer on which the internal conductive patterns is formed so as to penetrate in a thickness direction thereof in order to abut and thereby connect the internal conductive patterns provided on the both surfaces of the dielectric layer to each other; and
external connecting terminals provided on the main surfaces of the substrate, wherein
the adjacent dielectric layers are formed so as to interconnect by being continuously and integrally coupled with each other at layer ends thereof on any of the both main surfaces of the substrate,
the coupled sections of the adjacent dielectric layers are alternately provided on any of the both main surfaces of the substrate, and the plurality of dielectric layers has a shape of a bent dielectric sheet,
the internal conducive patterns provided on the both surfaces of the dielectric layer are extended until the coupled sections where the surfaces of the dielectric layer, on which the internal conductive patterns is provided, is made an outer side of the coupling so as to constitute lead electrodes exposed on the main surfaces of the substrate, and
the lead electrodes are connected to the external connecting terminals.

52. The interposer as claimed in claim 51, wherein
the external connecting terminals provided on one of the main surfaces of the substrate are provided along a periphery of the relevant main surface, and the external connecting terminals provided on the other main surface of the substrate are provided on the relevant main surface in a two-dimensional array shape.

53. The interposer as claimed in claim 51, wherein
the external connecting terminals are provided on the both main surfaces of the substrate in a two-dimensional array shape.

54. The interposer as claimed in claim 51, wherein
a distance between the external connecting terminals provided on one of the main surfaces of the substrate is smaller than a distance between the external connecting terminals provided on the other main surface of the substrate.

55. The interposer as claimed in claim 51, wherein
insulating adhesive layers for adhering the adjacent dielectric layers to each other are provided.

56. The interposer as claimed in claim 55, wherein
the internal conductive patterns are coated with the insulating adhesive layers.

57. The interposer as claimed in claim 51, wherein
the adjacent dielectric layers are bonded by pressure to each other.

58. The interposer as claimed in claim 51, wherein
the internal conductive patterns are provided in a band shape along ridge-lien direction of the coupled sections.

59. The interposer as claimed in claim 51, wherein
the inter-layer connecting conductor is a metal conductor.

60. The interposer as claimed in claim 51, wherein
a plurality of lead electrodes is provided on the same main surface of the substrate, and
wiring patterns for abutting and thereby connecting the lead electrodes to each other are provided on the main surface of the substrate.

61. The interposer as claimed in claim 55, wherein
the dielectric layers consists of thermoplastic fluorocarbon resin or thermosetting epoxy resin.

62. The interposer as claimed in claim 55, wherein
the insulating adhesive layer includes thermosetting epoxy resin in its composition.

63. The interposer as claimed in claim 57, wherein
the dielectric layers are formed from thermoplastic polyester or thermoplastic fluorocarbon resin.

64. The interposer as claimed in claim 51, wherein
an outer shape of the interposer has a rectangular shape that is longer in a planar direction of the dielectric layers and shorter in a direction where the dielectric layers are laminated.

65. A method of manufacturing an interposer comprising:
a first step in which a dielectric sheet is prepared, and mountainside lines and valley-side lines respectively showing mountains and valleys in observing from one surface of the dielectric sheet are virtually set alternately and in parallel with each other at certain intervals;
a second step in which an inter-layer connecting conductor penetrating the dielectric sheet in a thickness direction thereof is formed at a predetermined position on the dielectric sheet.
a third step in which internal conductive patterns located between the adjacent mountainside lines and the valley-side lines and having a band shape in parallel with the mountainside and valley-side lines are formed at positions where the internal conductive patterns face each other interleaving the dielectric sheet between them, and the internal conductive patterns on the both surfaces of the sheet are made to abut the inter-layer connecting conductor and thereby connected to each other;
a fourth step in which the dielectric sheet is alternately folded along the mountainside lines and the valley-side lines in such a manner that the mountainside line forms a mountain shape and the valley-side line forms a valley shape in observing from the one surface so as to form an interposer whose one main surface is an exposed surface of the mountain shape; and
a fourth step in which an insulating layer is formed on a main surface of the core substrate, wherein
at least a part of the internal conductive patterns is formed so as to extend beyond the mountain-side line or the valley-side line so that the relevant internal conducive pattern is exposed on the main surface of the interposer by folding the sheet so as to constitute a lead electrode exposed on the main surface of the interposer, and an external connecting electrode abutting an end of the internal conductive pattern and thereby connected thereto is provided on the main surface of the interposer in the third step.

66. The method of manufacturing the interposer as claimed in claim 65, wherein
the dielectric layers folded and thereby abutting one another are bonded to one another by an insulating adhesive in the fourth step.

67. The method of manufacturing the interposer as claimed in claim 65, wherein
the dielectric layers sheets and thereby abutting one another are bonded by pressure one another in the fourth step.

68. A multi-layered wiring board comprising:
a first core substrate; and
a second core substrate laminated on the first core substrate, wherein
the first and second core substrates each comprises:
a substrate comprising a plurality of dielectric layers arranged along a direction where main surfaces of the substrate face each other and laminated on one another along a planar direction of the substrate; and
internal conductive patterns provided on surfaces of the dielectric layers, and wherein
the adjacent dielectric layers are formed so as to interconnect by being continuously and integrally coupled with each other at layer ends thereof on any of the main surfaces of the substrate,
the coupled sections of the adjacent dielectric layers are alternately provided on any of the main surfaces of the substrate, and the plurality of dielectric layers have a shape of a bent dielectric sheet,
the internal conductive patterns formed in at least one dielectric layer selected from the plurality of dielectric layers are provided on the both surfaces of the dielectric layer and extended until the coupled sections where the surfaces of the dielectric layer on which the internal conductive patterns is provided becomes an outer side of the coupling and then exposed on the main surface of the substrate so as to constitute lead electrodes,
an alignment direction of the dielectric layers provided in the first core substrate and an alignment direction of the dielectric layers provided in the second core substrate intersect with each other,
the first and second core substrates are laminated on each other in such a manner that the main surfaces where the lead electrodes are exposed face each other, and
the lead electrodes of the first core substrate and the second core substrate are connected to each other.

69. The multi-layered wiring board as claimed in claim 68, wherein
the alignment direction of the dielectric layers provided in the first core substrate and the alignment direction of the dielectric layers provided in the second core substrate intersect in orthogonal state with each other.

70. The multi-layered wiring board as claimed in claim 69, wherein
the internal conductive patterns of the first core substrate and the internal conductive patterns of the second core substrate are formed in a band shape in a direction where the internal conductive patterns intersect in orthogonal state with each other.

71. The multi-layered wiring board as claimed in claim 68, wherein
the first and second core substrates respectively have insulating adhesive layers which adhere the adjacent dielectric layers to each other, and
the internal conductive patterns are coated with the insulating adhesive layers.

72. The multi-layered wiring board as claimed in claim 68, wherein
an inter-substrate connecting layer is provided between the first and second core substrates,
the inter-substrate connecting layer has an inter-layer connecting conductor penetrating in a thickness direction thereof, and
the lead electrodes of the first core substrate and the second core substrate are connected to each other via the inter-layer connecting conductor.

73. The multi-layered wiring board as claimed in claim 68, wherein
the internal conductive patterns are provided on the both surfaces of the dielectric layers.

74. The multi-layered wiring board as claimed in claim 68, wherein
the second core substrate comprises first and second dielectric layers,
a first internal conductive pattern is provided on one surface of the first dielectric layer, and a third internal conductive pattern is provided on another surface of the first dielectric layer respectively,
a second internal conductive pattern is provided on one surface of the second dielectric layer, and a fourth internal conductive pattern is provided on another surface of the second dielectric layer respectively,
the first and second internal conductive patterns are respectively extended until coupled sections where the one surfaces of the first and second dielectric layers are made an outer side of the coupling and exposed on the main surface of the substrate, so that first and second lead electrodes are formed respectively,
the third and fourth internal conductive patterns are respectively extended until coupled sections where the another surfaces of the first and second dielectric layers are made an outer side of the coupling and exposed on the main surface of the substrate, so that third and fourth lead electrodes are formed respectively,
the first and third internal conductive patterns are connected by an inter-layer connecting conductor provided in the first dielectric layer so as to penetrate in a thickness direction thereof,
the second and fourth internal conductive patterns are connected by an inter-layer connecting conductor provided in the second dielectric layer so as to penetrate in a thickness direction thereof,
the first core substrate comprises third and fourth dielectric layers,
a fifth internal conductive pattern is provided on one surface of the third dielectric layer, and a seventh internal conductive pattern is provided on another surface of the third dielectric layer respectively,
a sixth internal conductive pattern is provided on one surface of the fourth dielectric layer, and an eighth internal conductive pattern is provided on another surface of the fourth dielectric layer,
the fifth and sixth internal conductive patterns are respectively extended until coupled sections where the one surfaces of the third and fourth dielectric layers are made an outer side of the coupling and exposed on the main surface of the substrate, so that fifth and sixth lead electrodes are formed respectively,
the seventh and eighth internal conductive patterns are respectively extended until coupled sections where the another surfaces of the third and fourth dielectric layers are made an outer side of the coupling and exposed on the main surface of the substrate, so that which seventh and fourth eighth electrodes are formed respectively
the fifth and seventh internal conductive patterns are connected by an inter-layer connecting conductor provided in the third dielectric layer so as to penetrate in a thickness direction thereof,
the sixth and eighth internal conductive patterns are connected by an inter-layer connecting conductor provided in the fourth dielectric layer so as to penetrate in a thickness direction thereof,
the second core substrate and the first core substrate are laminated on each other in such a manner that the main surface of the second core substrate where the third and fourth lead electrodes are exposed and the main surface of the first core substrate where the fifth and sixth lead electrodes are exposed face each other,
the third and fifth lead electrodes are connected to each other, and
the fourth and sixth lead electrodes are connected to each other.

75. A mounting structure for a semiconductor device comprising:
the multi-layered wiring board as claimed in claim 74;
a first semiconductor device; and
a second semiconductor device, wherein
the first and second semiconductor devices are mounted on the main surface of the second core substrate located on the rear side of the main surface where the third and fourth lead electrodes are exposed, wherein
the first semiconductor device is connected to the first lead electrode, and
the second semiconductor device is connected to the second lead electrode.

76. The mounting structure for the semiconductor device as claimed in claim 75, wherein
the first, second, third and fourth internal conductive patterns respectively constitute bus lines that connect the first and second semiconductor devices to each other.
